(19) United States
(12) Patent Application Publication
(10) Pub. No.: US 2026/0371711 A1
(43) Pub. Date: Nov. 19, 2026

(54) SEMICONDUCTOR STRUCTURE WITH ISOLATION FEATURE

(71) Applicant: Taiwan Semiconductor Manufacturing Company, Ltd., Hsinchu (TW)

(72) Inventors: Wei-Ting WANG, Taipei City (TW); Yi-Ruei JHAN, Keelung City (TW); Kuan-Ting PAN, Taipei City (TW); Kuo-Cheng CHIANG, Zhubei City (TW); Chih-Hao WANG, Baoshan Township (TW)

(73) Assignee: Taiwan Semiconductor Manufacturing Company, Ltd., Hsinchu (TW)

(21) Appl. No.: 19/751,296

(22) Filed: Jul. 23, 2026

Related U.S. Application Data
(63) Continuation of application No. 19/062,887, filed on Feb. 25, 2025.
(60) Provisional application No. 63/711,874, filed on Oct. 25, 2024.

(51) Int. Cl. H10D 84/83; H10D 30/00; H10D 30/01; H10D 30/43; H10D 62/10; H10D 62/13; H10D 84/01

(52) U.S. Cl. CPC H10D 84/832; H10D 30/014; H10D 30/0194; H10D 30/43; H10D 30/503; H10D 30/506; H10D 62/102; H10D 62/116; H10D 62/121; H10D 62/151; H10D 84/013; H10D 84/0151; H10D 84/8312

(57) ABSTRACT

Semiconductor structures and method for forming the same are provided. The semiconductor structure includes a substrate and a first channel layer and a second channel layer. The semiconductor structure further includes an isolation structure over the substrate and a first gate structure over the first channel layer and the isolation structure. The semiconductor structure further includes a second gate structure over the second channel layer and the isolation structure and an isolation feature laterally sandwiched between the first gate structure and the second gate structure and extending over the isolation structure. In addition, the isolation feature has a top width and a bottom width that is greater than the top width, and an interface between the isolation feature and the first gate structure comprises a curved profile.

### PRIORITY CLAIM AND CROSS-REFERENCE

This Application is a Continuation application Ser. No. 19,062,887, filed on Feb. 25, 2025, which claims priority to U.S. Provisional Application Ser. No. 63/711,874, filed on Oct. 25, 2024, the entirety of which are incorporated by reference herein.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A and 1B illustrate diagrammatic perspective views of intermediate stage of manufacturing a semiconductor structure in a first region and a second region, respectively, in accordance with some embodiments.

FIGS. 2A-1 to 2T-1, 2A-3 to 2T-3, and 2A-5 to 2T-5 illustrate the cross-sectional views of intermediate stages of manufacturing the semiconductor structure in the first region shown along the lines Y_{MG1}-Y_{MG1}′, X₁-X₁′, and Y_{SD1}-Y_{SD1}′ in FIG. 1A, respectively, in accordance with some embodiments.

FIGS. 2A-2 to 2T-2, 2A-4 to 2T-4, and 2A-6 to 2T-6 illustrate the cross-sectional views of intermediate stages of manufacturing the semiconductor structure in the second region shown along the lines Y_{MG2}-Y_{MG2}', X₂-X₂′, and Y_{SD2}-Y_{SD2}′ in FIG. 1B, respectively, in accordance with some embodiments.

FIGS. 2J-7 to 2T-7 and 2J-8 to 2T-8 illustrate the diagrammatic perspective views of the intermediate stages of the semiconductor structure in the first region and the second region in accordance with some embodiments.

FIG. 2T-9 illustrates an enlarge cross-sectional view of the semiconductor structure in the region R of FIG. 2T-1 in accordance with some embodiments.

FIGS. 3A and 3B illustrate layout of the semiconductor structure in the first region and the second region, respectively, in accordance with some embodiments.

FIGS. 4A and 4B illustrate cross-sectional views of the intermediate stages of manufacturing the semiconductor structure in accordance with some other embodiments.

FIGS. 5A and 5B illustrate cross-sectional views of the intermediate stages of manufacturing the semiconductor structure in accordance with some other embodiments.

FIGS. 6A-1, 6A-2, 6B-1, and 6B-2 illustrate cross-sectional views of intermediate stages of manufacturing a semiconductor structure in accordance with some embodiments.

FIG. 7 illustrates a cross-sectional view of a semiconductor structure in accordance with some embodiments.

FIG. 8 illustrates a cross-sectional view of a semiconductor structure in accordance with some embodiments.

FIG. 9 illustrates a cross-sectional view of a semiconductor structure in accordance with some embodiments.

FIG. 10 illustrates a cross-sectional view of a semiconductor structure in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistors (e.g. nanosheet transistors, nanowire transistors, multi-bridge channel transistors, nano-ribbon FET, and gate all around (GAA) transistors) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructures.

As the feature sizes continue to decrease in semiconductor devices, gate-all-around (GAA) transistors may be adopted. Generally, channel layers (e.g. nanostructures) in the GAA transistors are manufactured by forming a semiconductor stack including channel layers (e.g. Si layers) and semiconductor sacrificial layers (e.g. SiGe layers) alternately stacked. The semiconductor sacrificial layers may be removed so that the gate structure formed afterwards may wrap the channel layers.

However, during the formation of the semiconductor devices, Ge in the semiconductor sacrificial layers may diffuse into the channel layers during the manufacturing processes, such as thermal processes. The performance of the resulting devices may therefore be undermined due to the Ge diffusion. Accordingly, in some embodiments of the present disclosure, the semiconductor sacrificial layers are replaced with dielectric sacrificial features in a relatively early stage of the manufacturing process (e.g. before the high-temperature thermal processes are performed). Therefore, the issues of Ge diffusion may be reduced or avoided. In addition, since the channel layers and the dielectric sacrificial features have relatively high etching selectivity, the dielectric sacrificial features may be fully removed without too much overetching the channel layers. Therefore, the size of the channel layers in the resulting devices can be better controlled, and the performance of the resulting devices may be improved.

Furthermore, isolation features may be formed to separate the gate structures of the transistors of different types. The widths and shapes of the isolation features may be adjusted by performing additional trimming processes. For example, the isolation features may have a smaller top width and a larger bottom width, so that the conductive structure formed over the gate structure may have a greater forming window (i.e. the gate structure can have a greater top width, and therefore the space for forming the conductive structure over the gate structure can be relatively large.) Furthermore, by performing the trimming processes, the size of the isolation features may be adjusted without damaging the channel layers, and therefore the isolation features may be formed at the transistors having different sizes and/or spacings.

Moreover, when the channel layers have relatively greater widths, extending portions may be formed on the sidewalls of the isolation features and extending to the channel layers when the channel layers during the formation of the isolation features. The resulting structure with the extending portions may have reduced Cgd (gate-to-drain capacitance) due to the gate endcap reduction. On the other hand, when the channel layers have relatively small widths, the isolation features may be formed without forming the extending portions, and the channel layers may be wrapped by the gate structure (e.g. by four sides). That is, by having channel layers with different widths, different structures may be made without the need of additional complicated manufacturing processes.

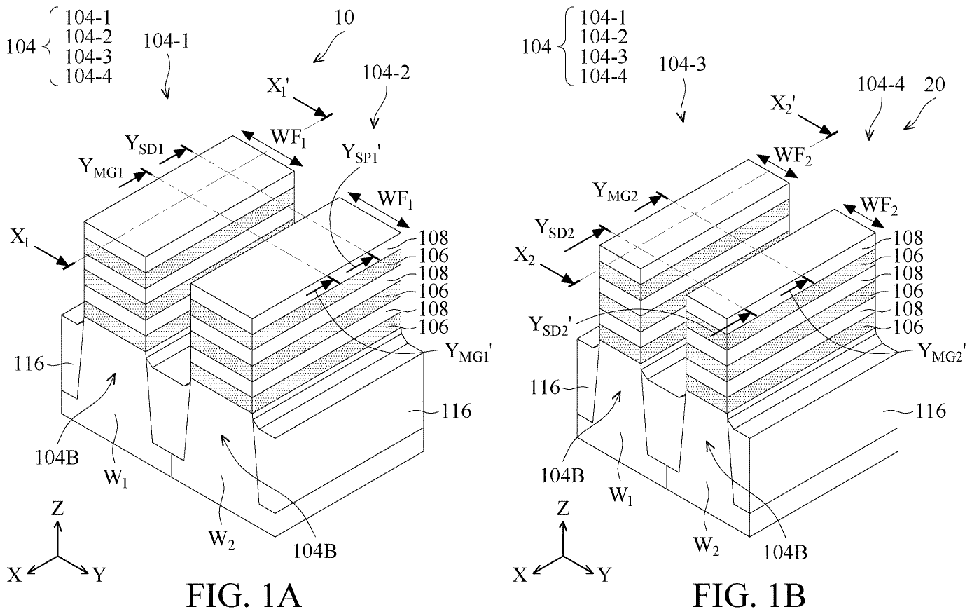

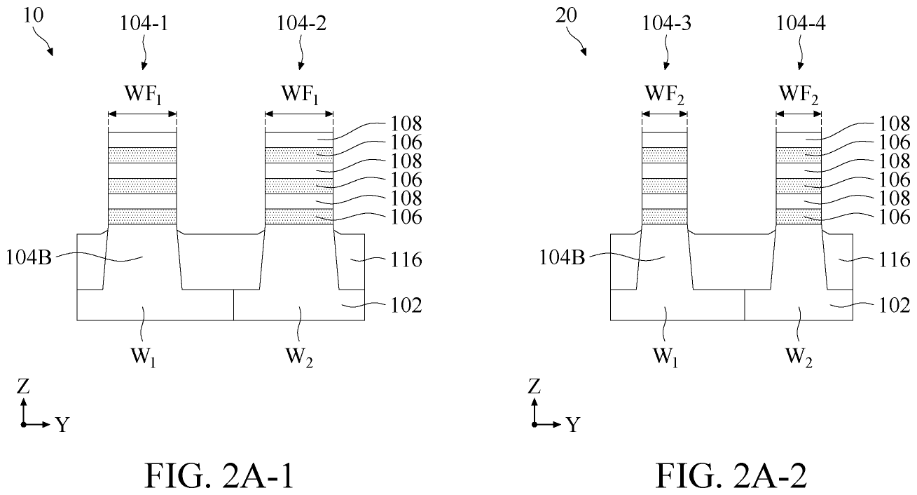

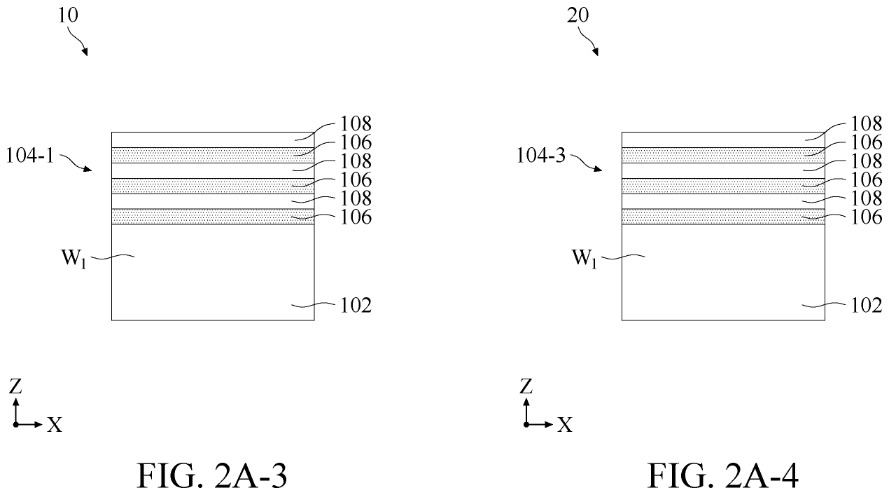

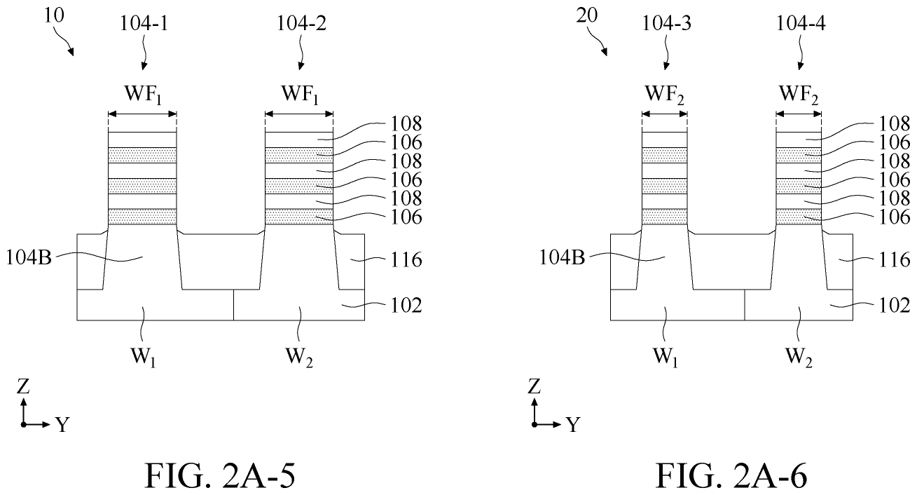

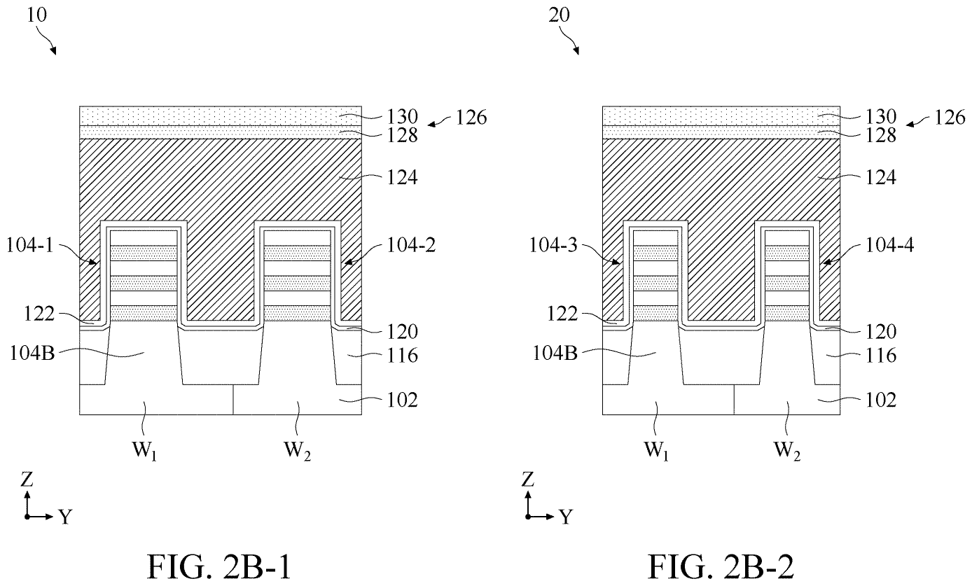

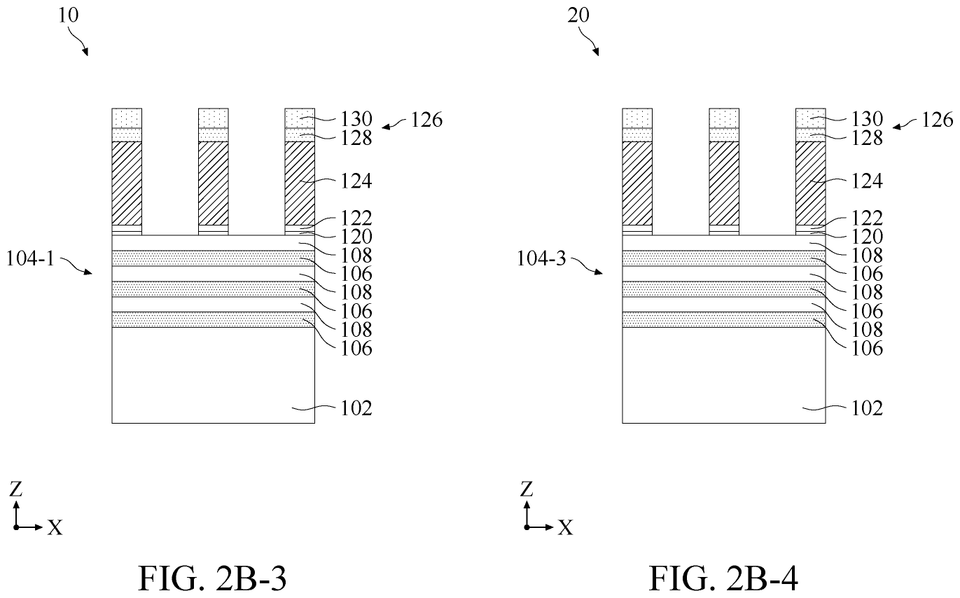

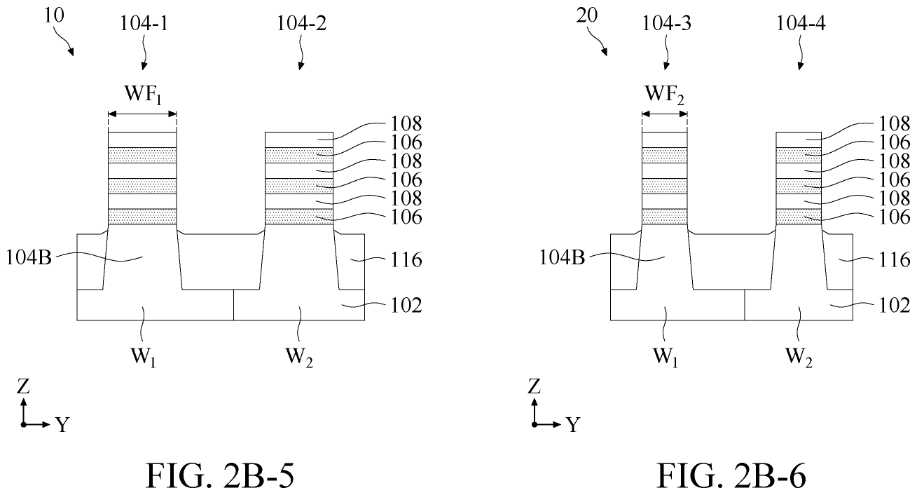

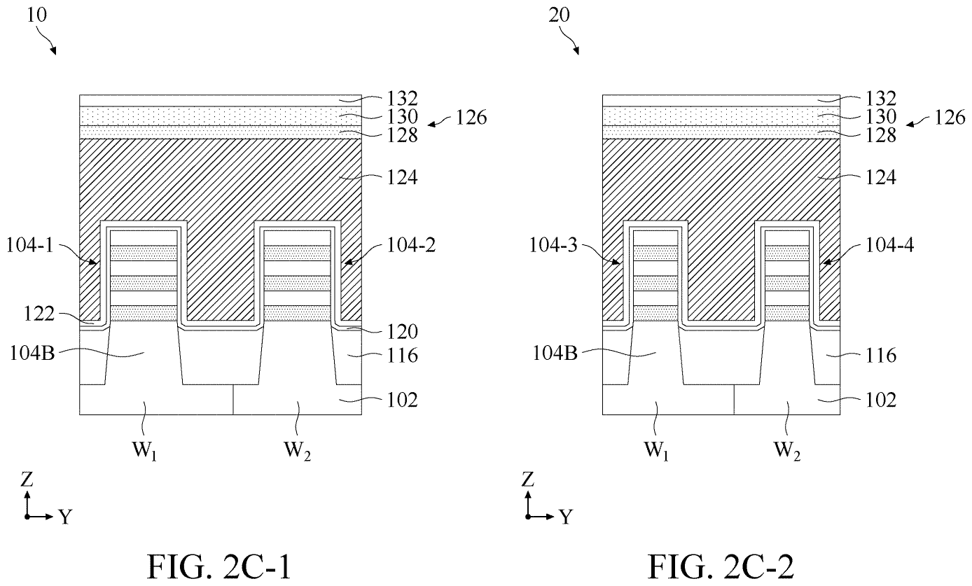

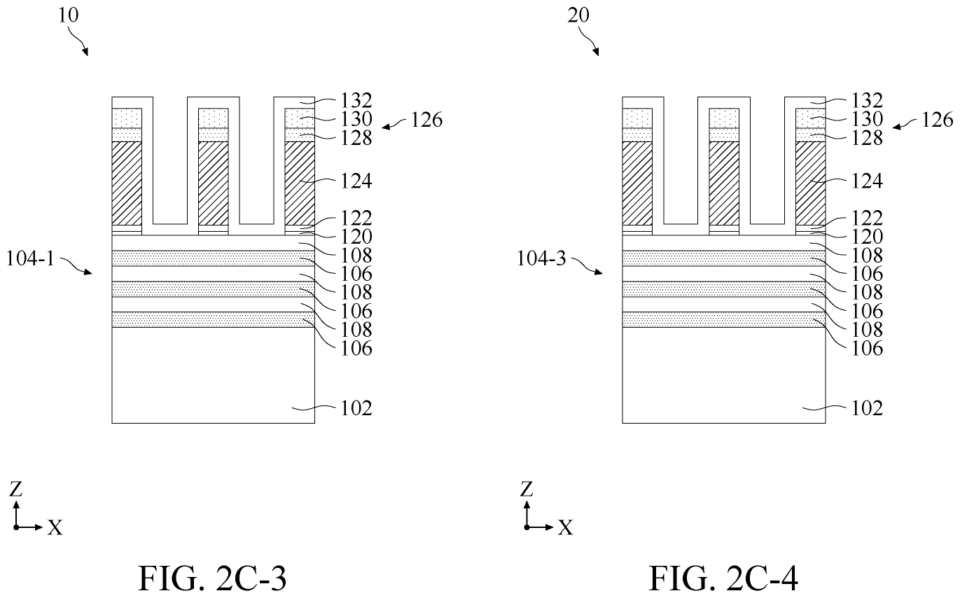

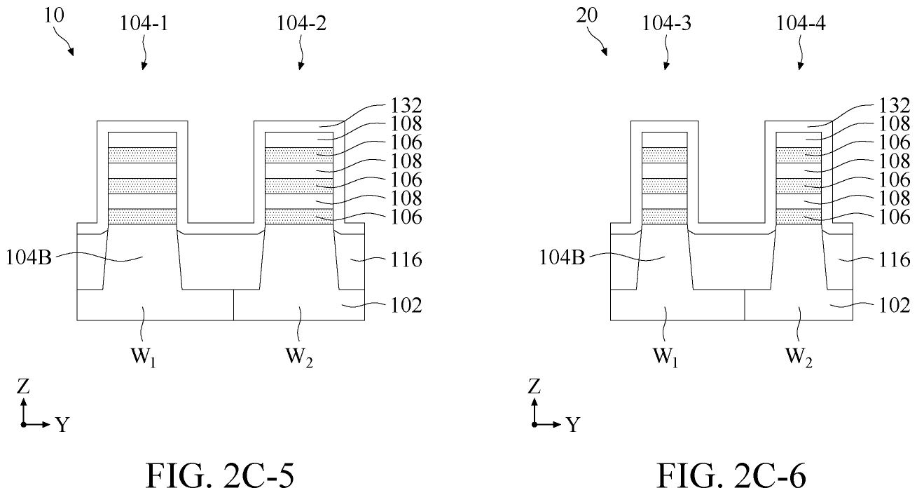

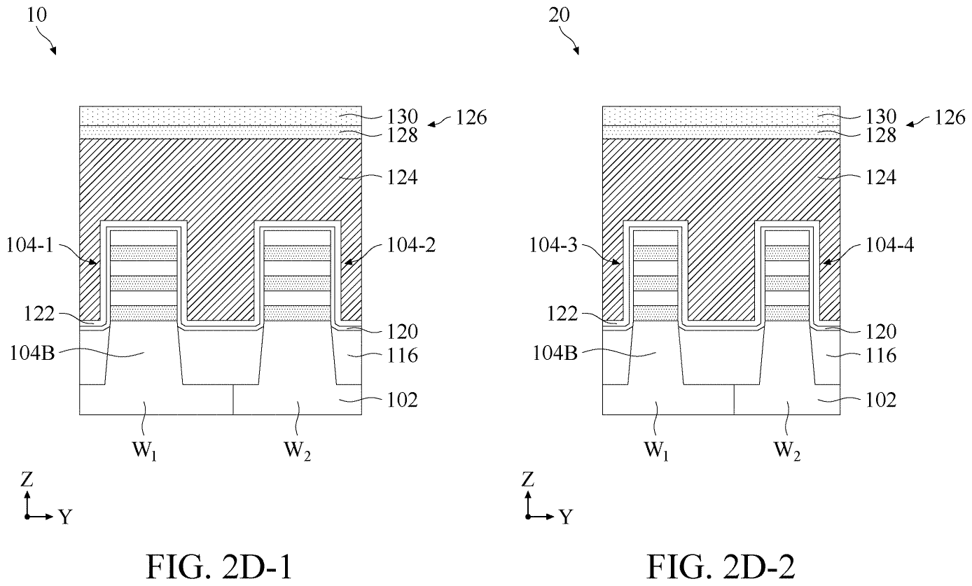

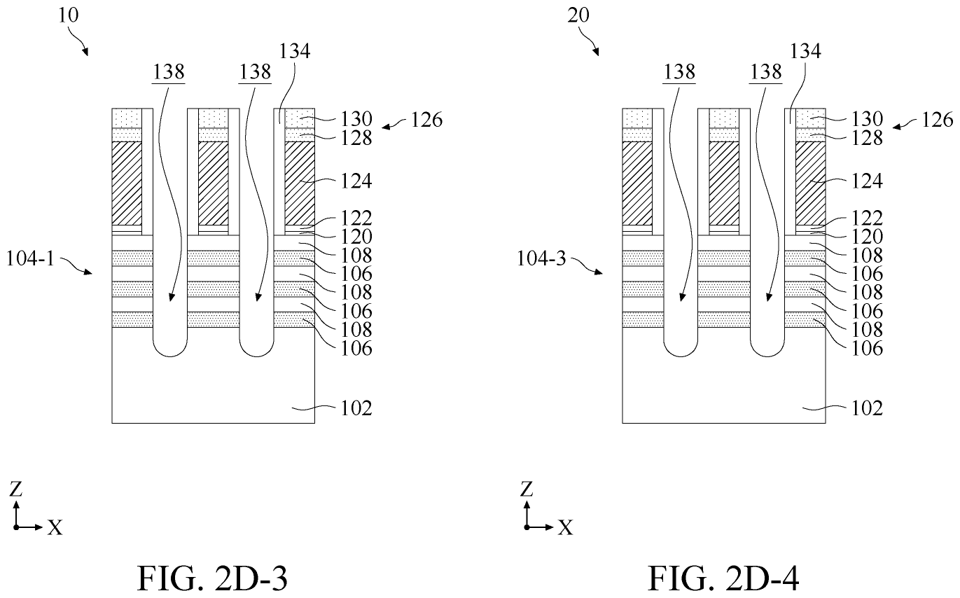

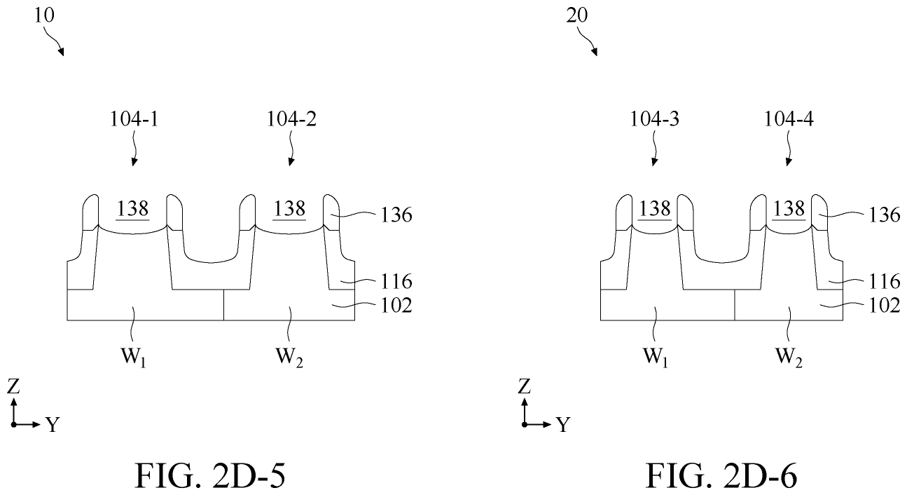

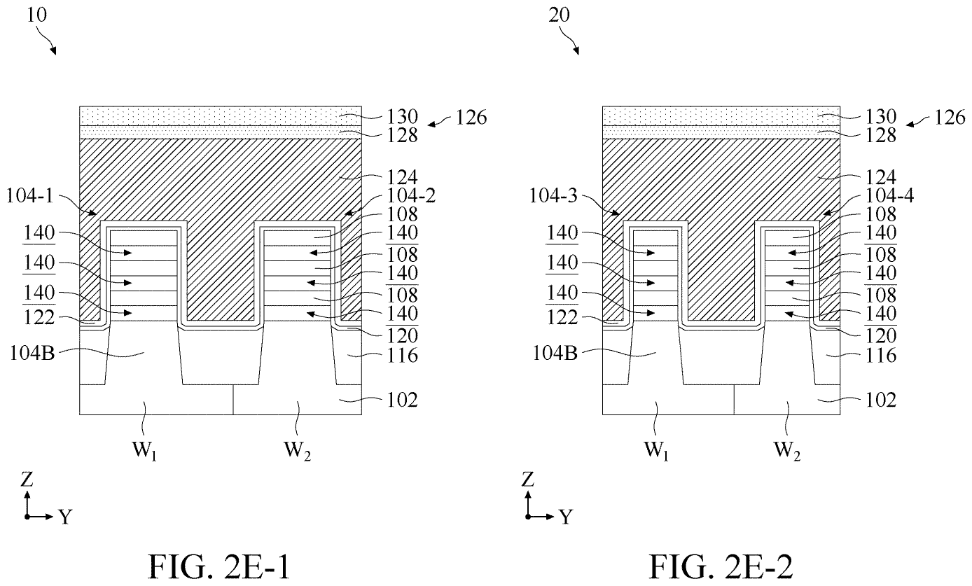

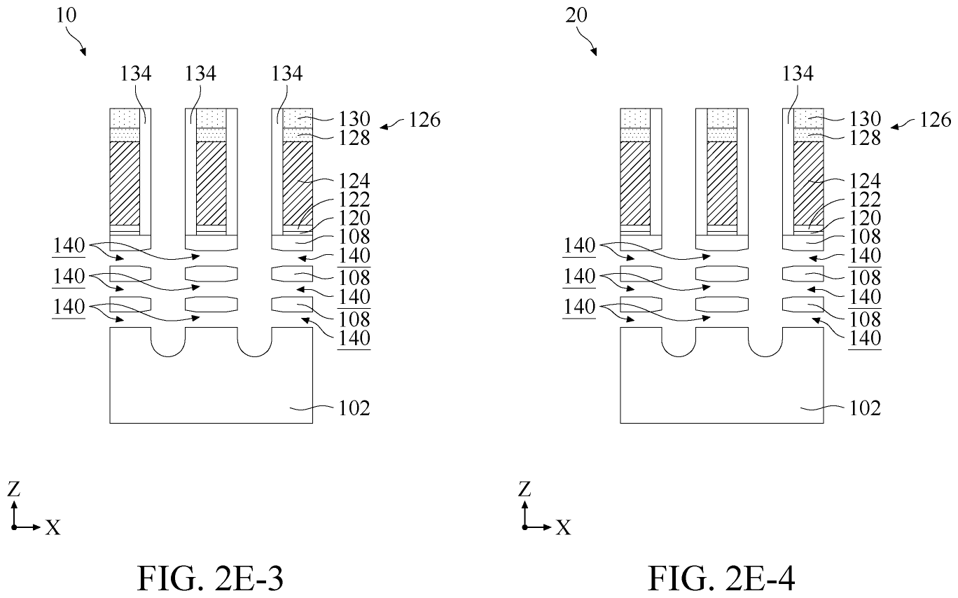

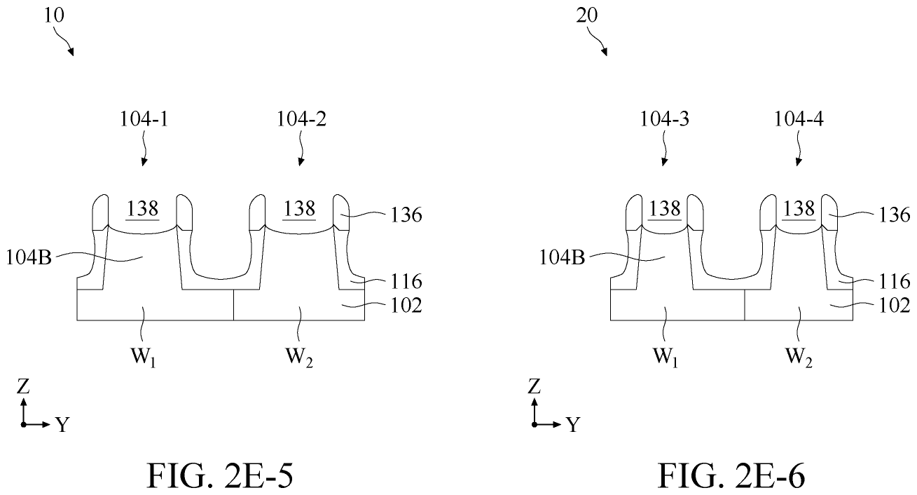

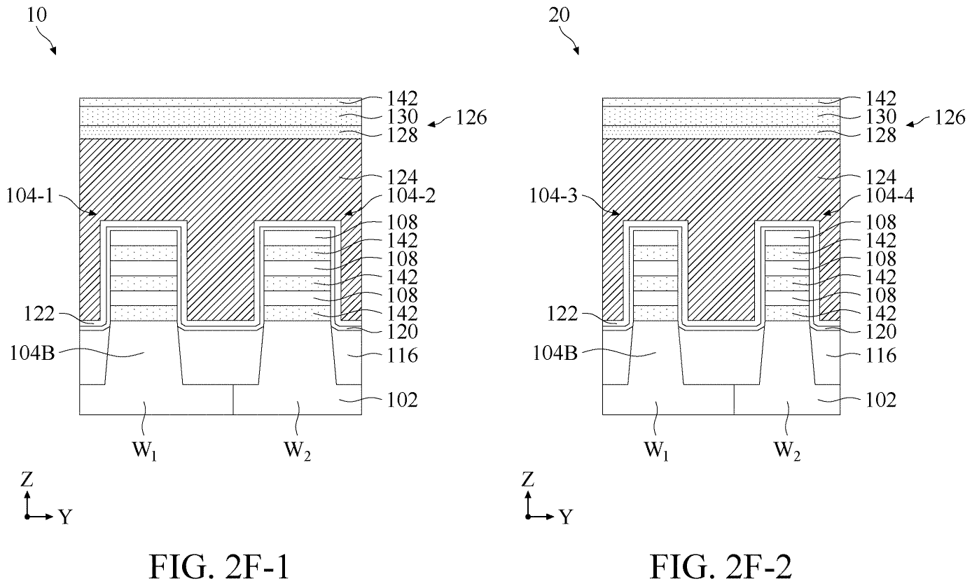

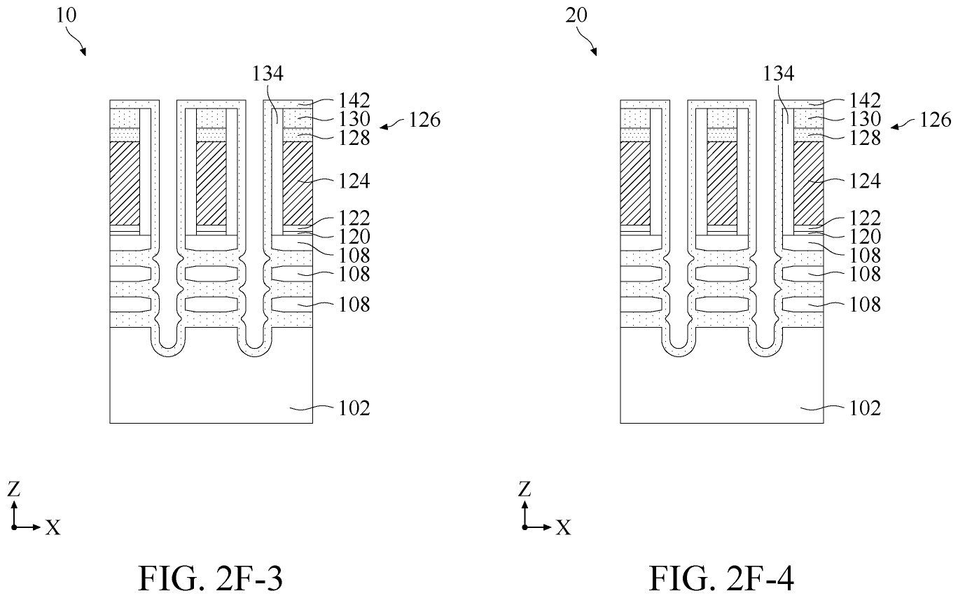

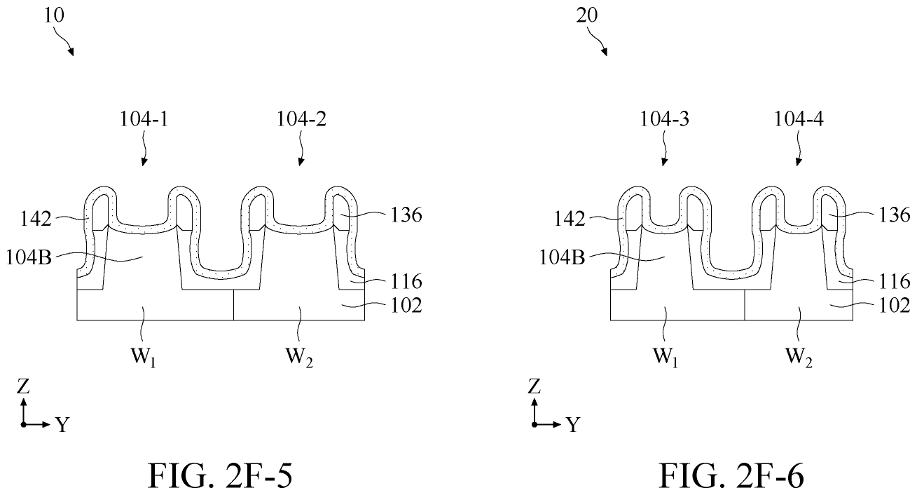

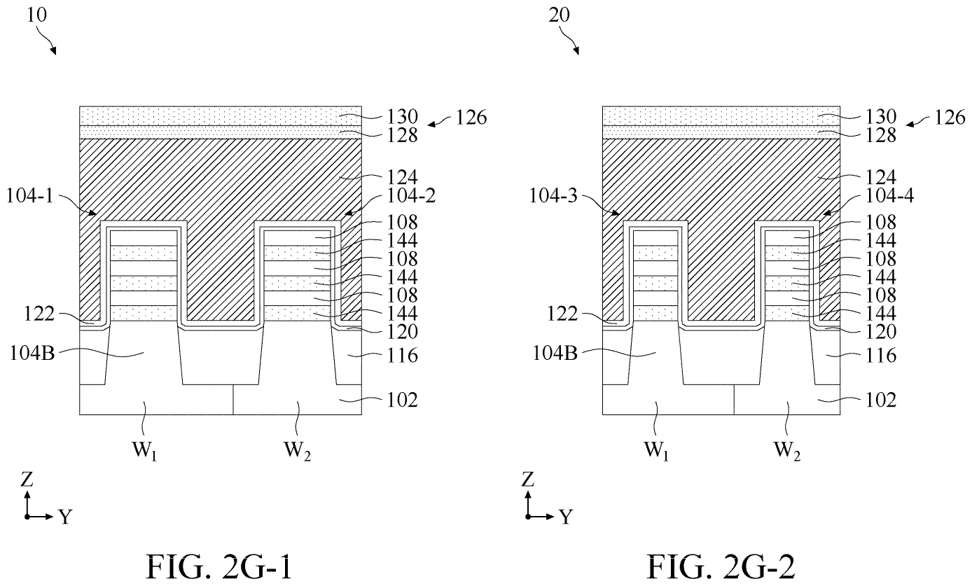

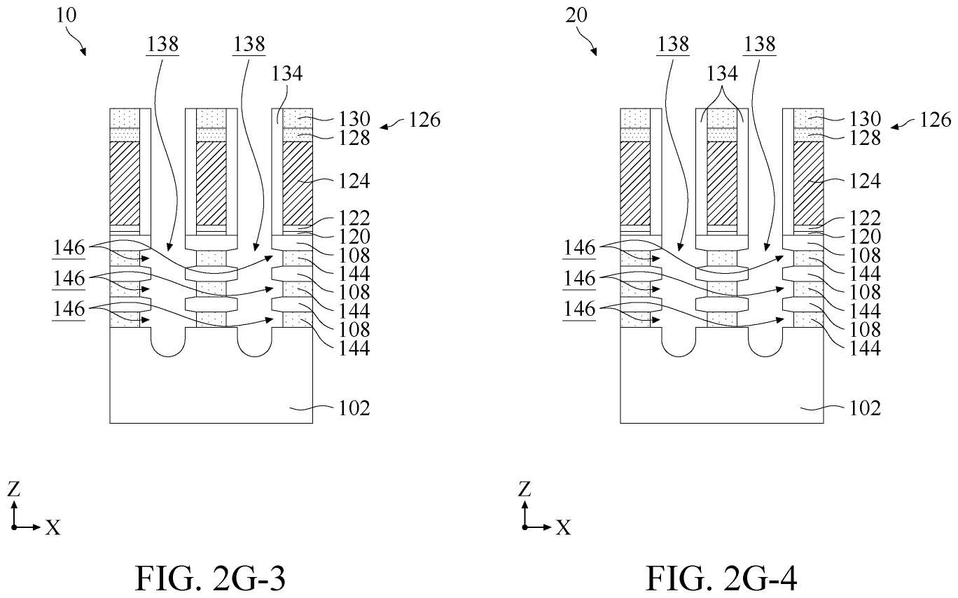

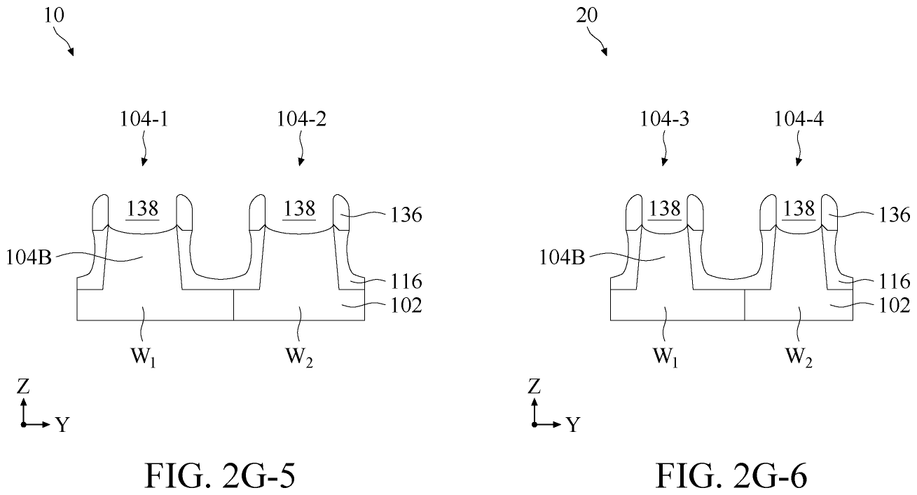

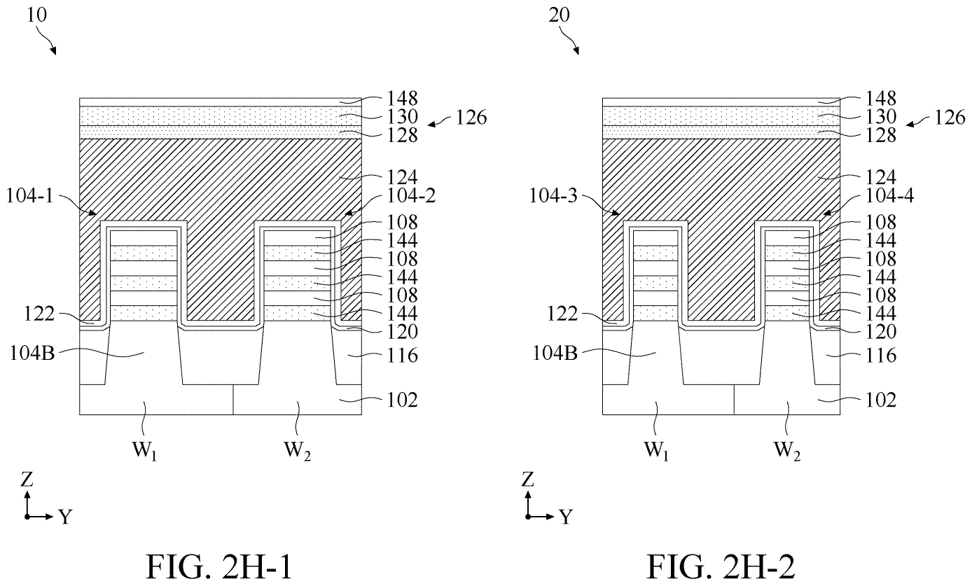

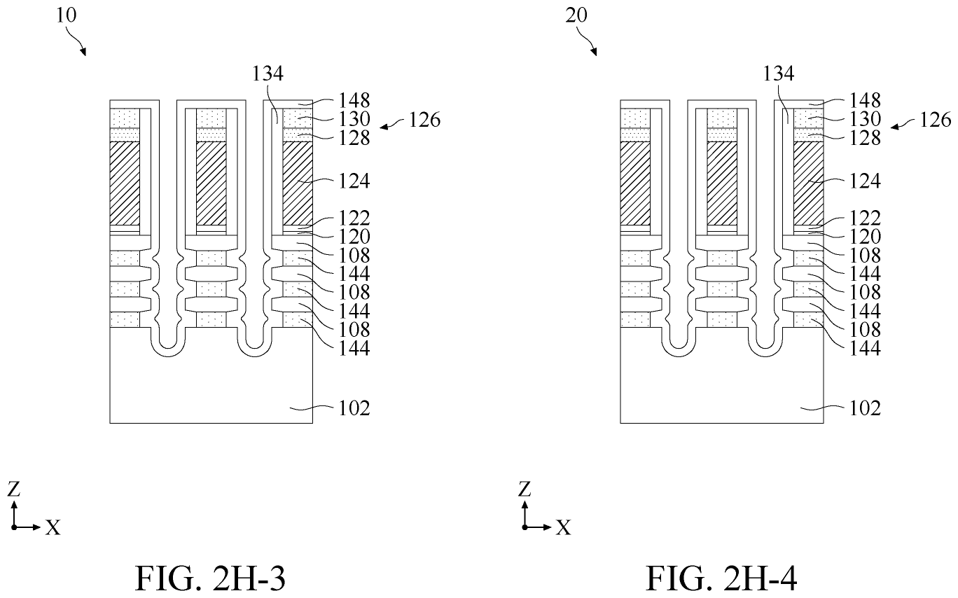

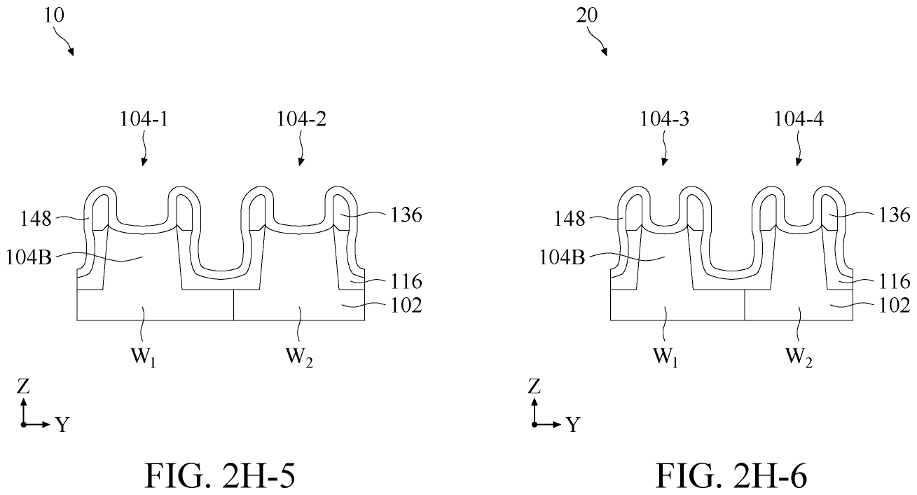

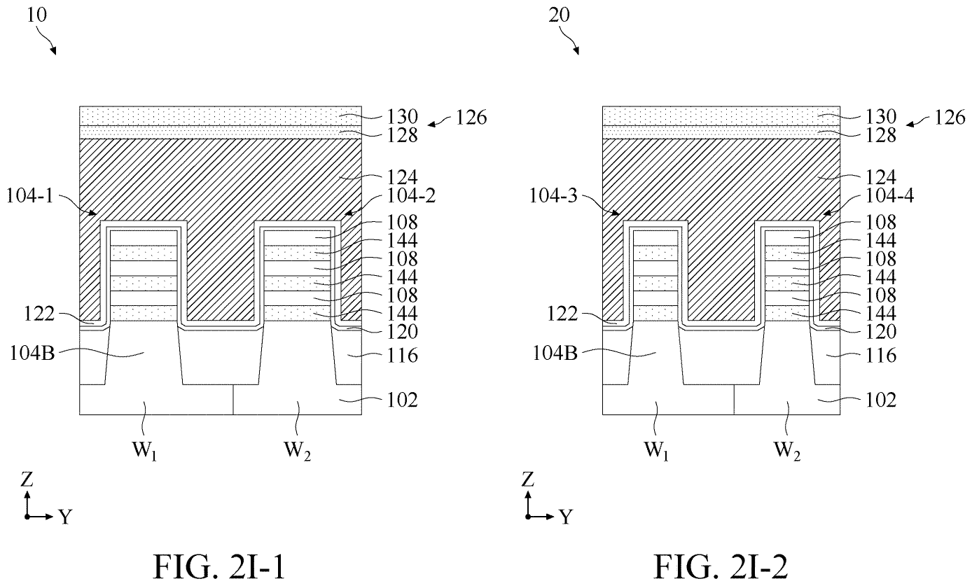

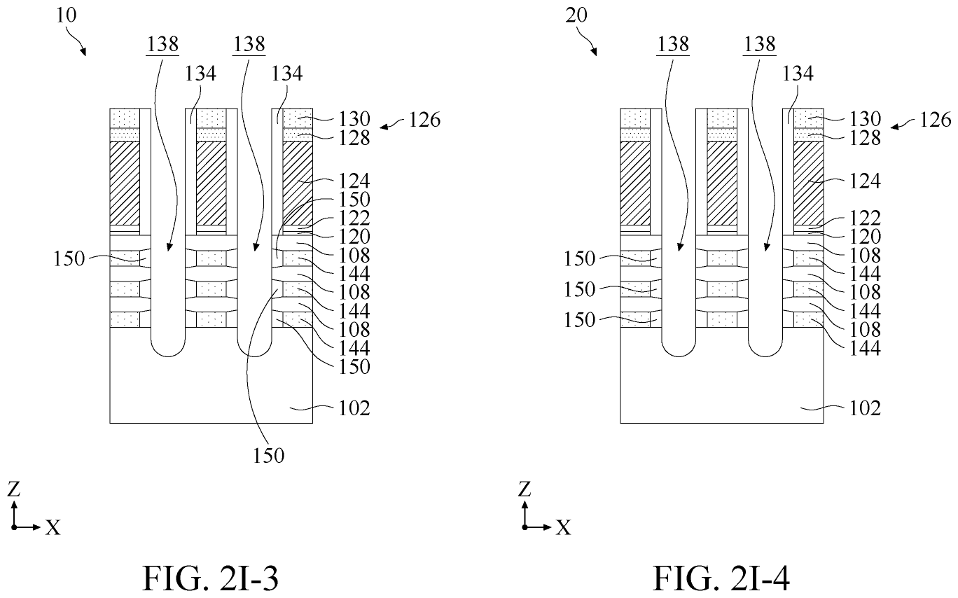

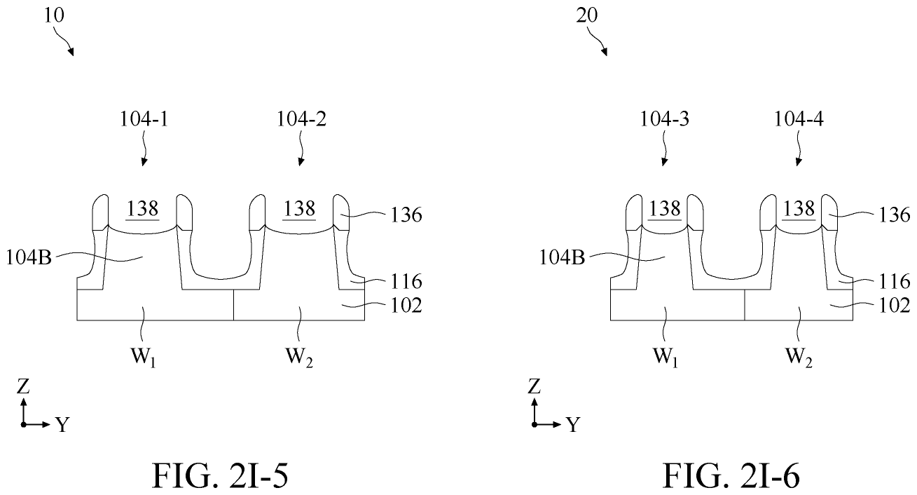

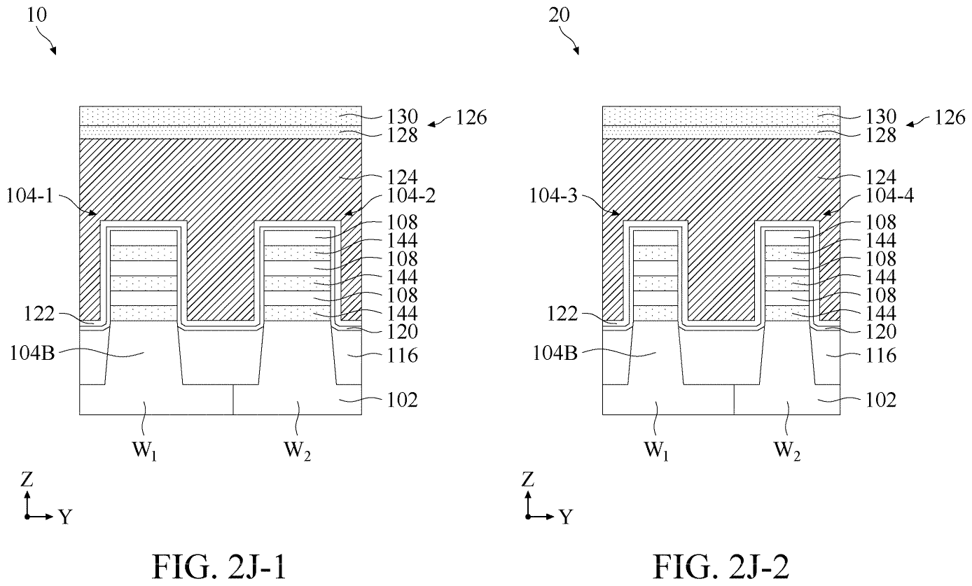

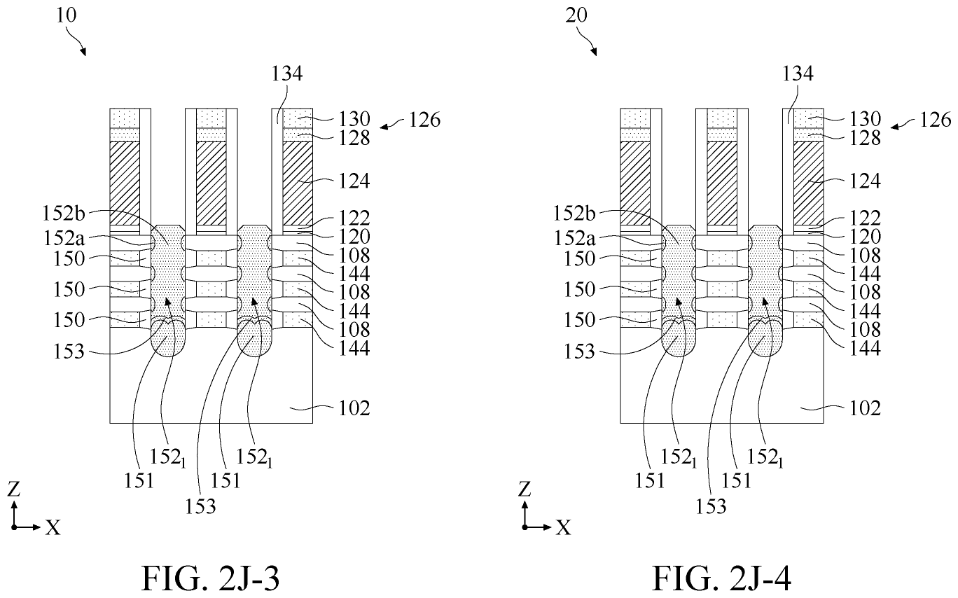

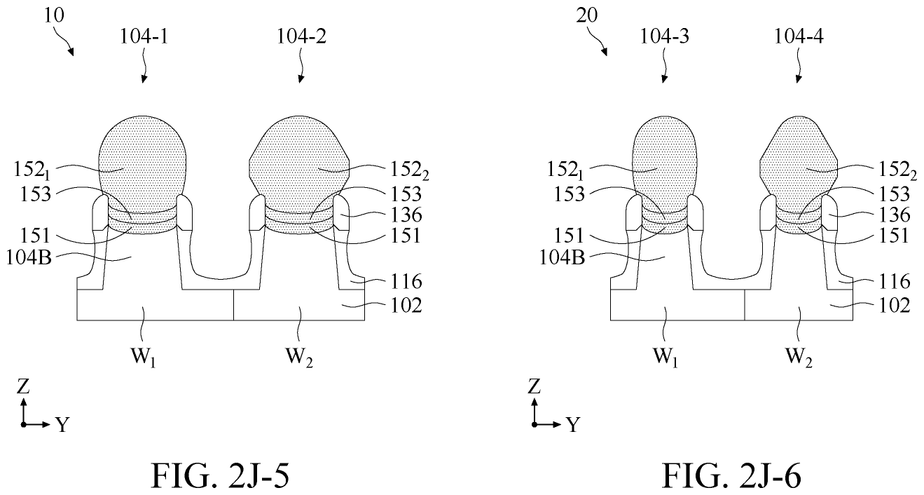

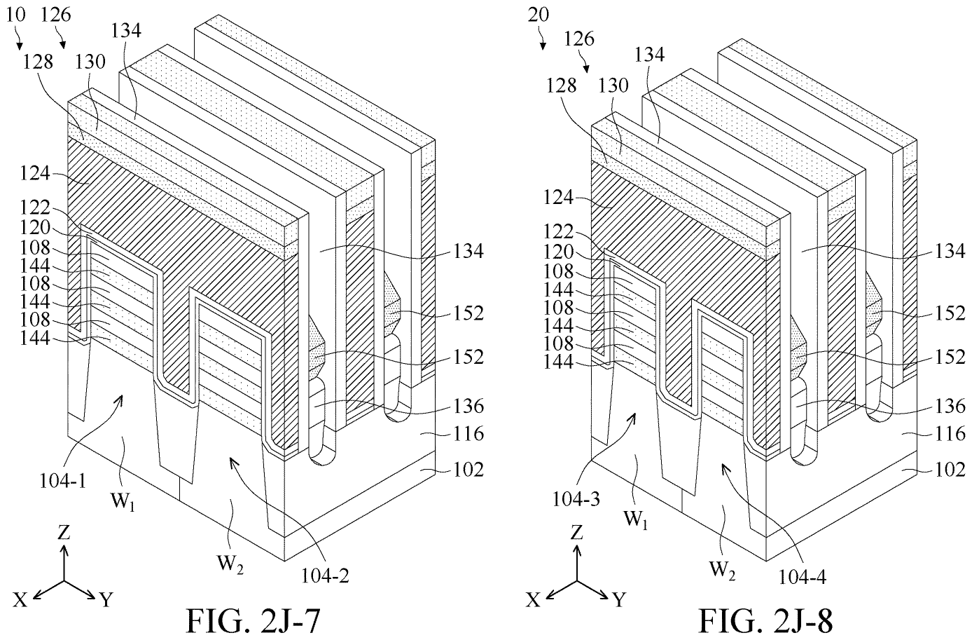

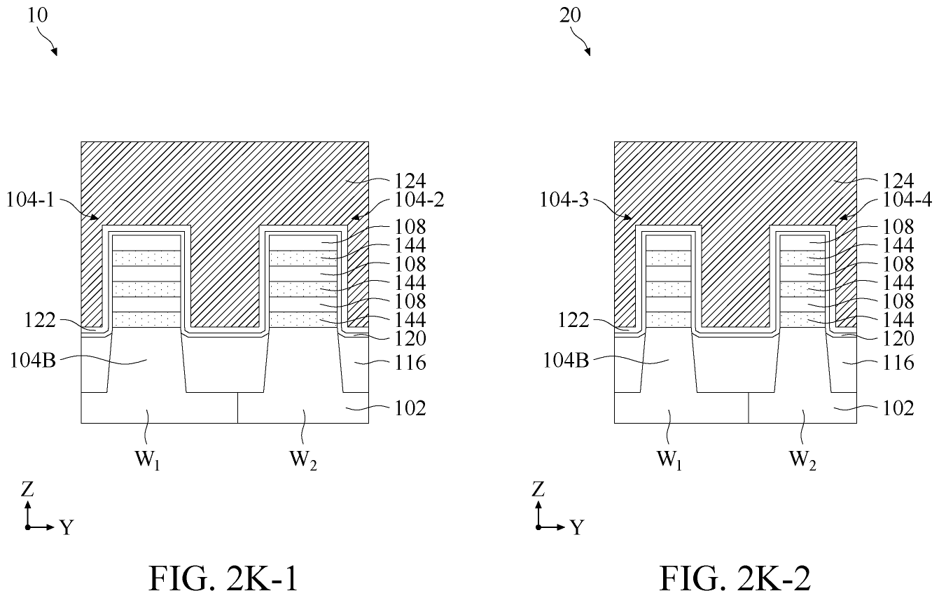

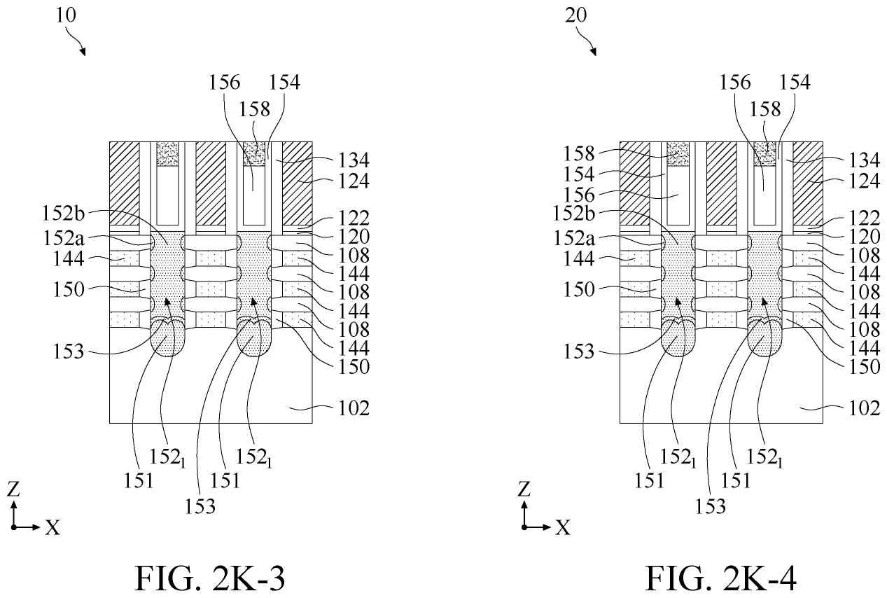

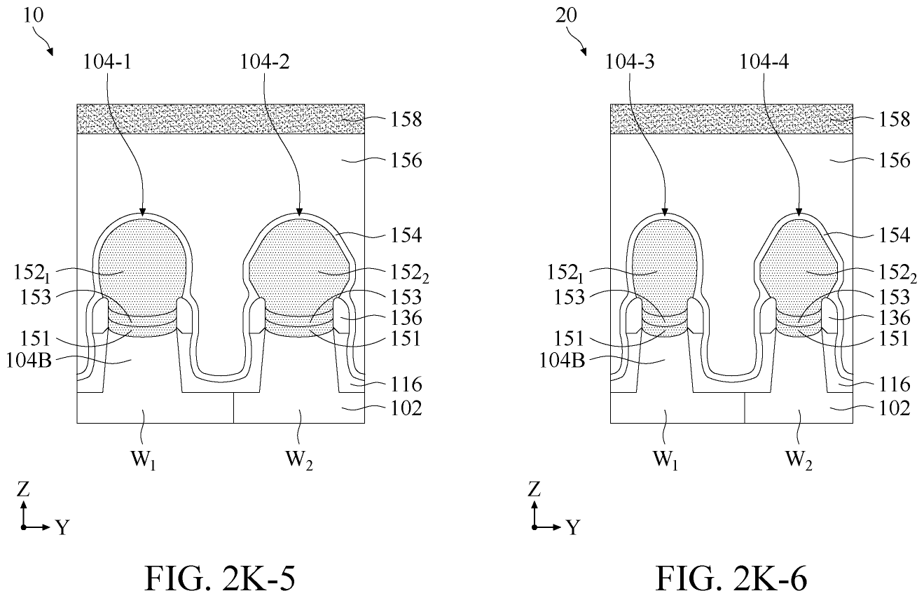

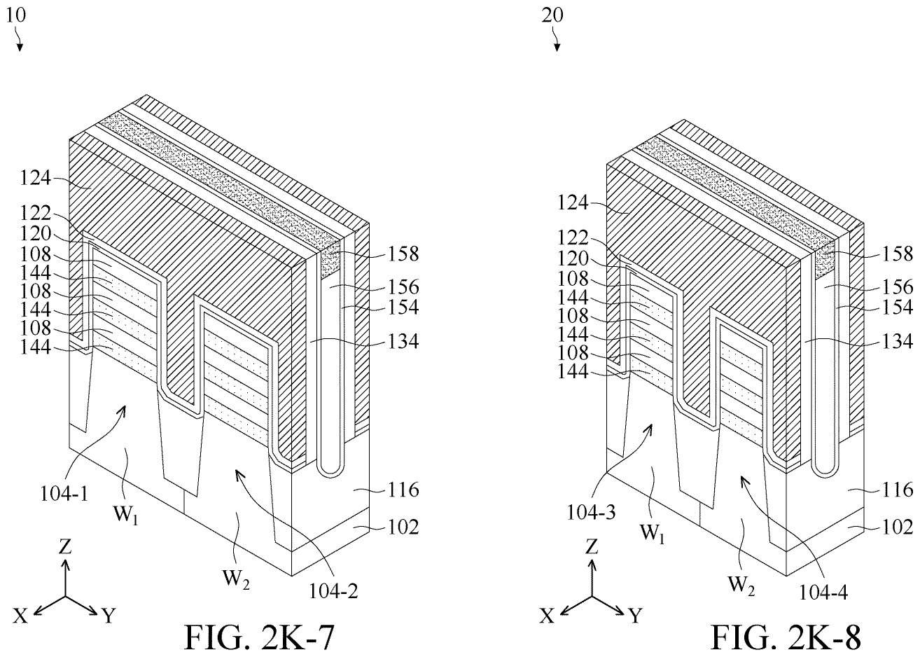

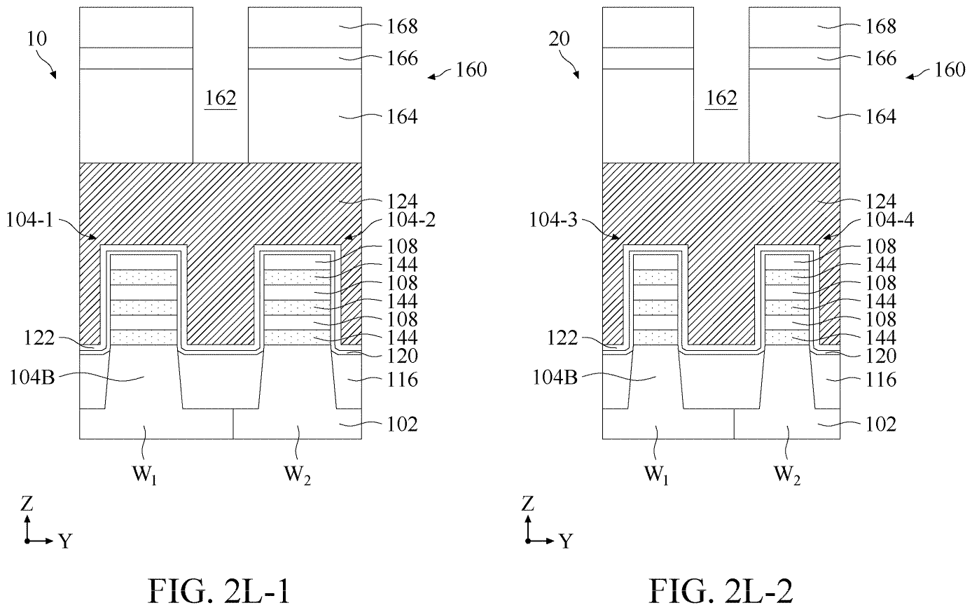

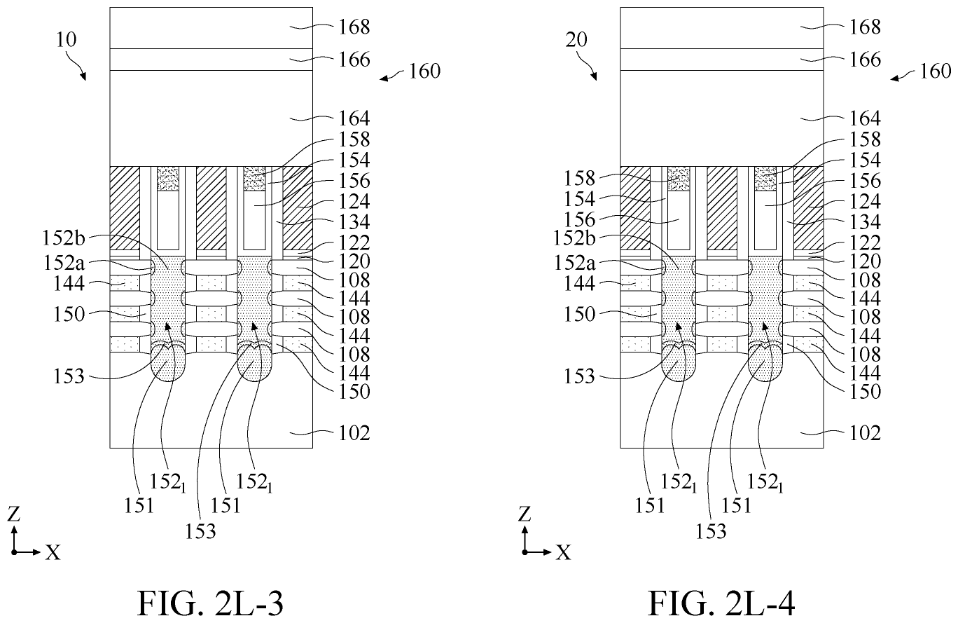

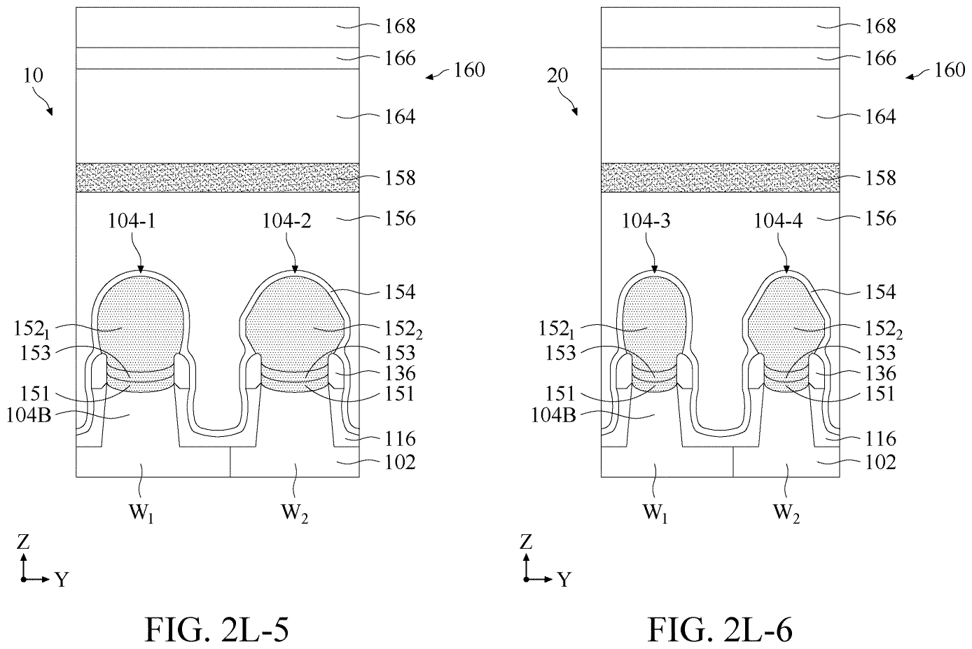

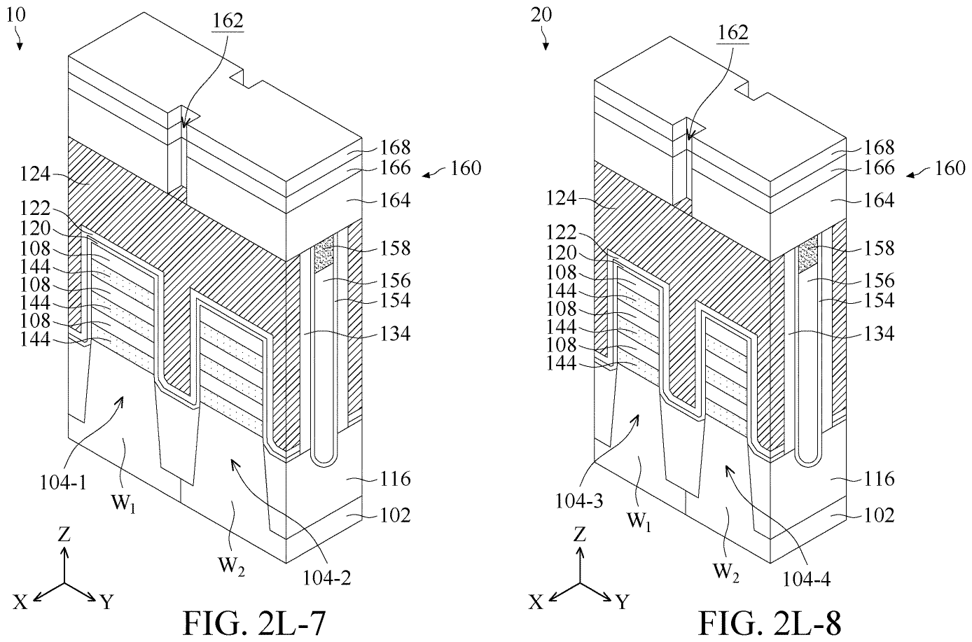

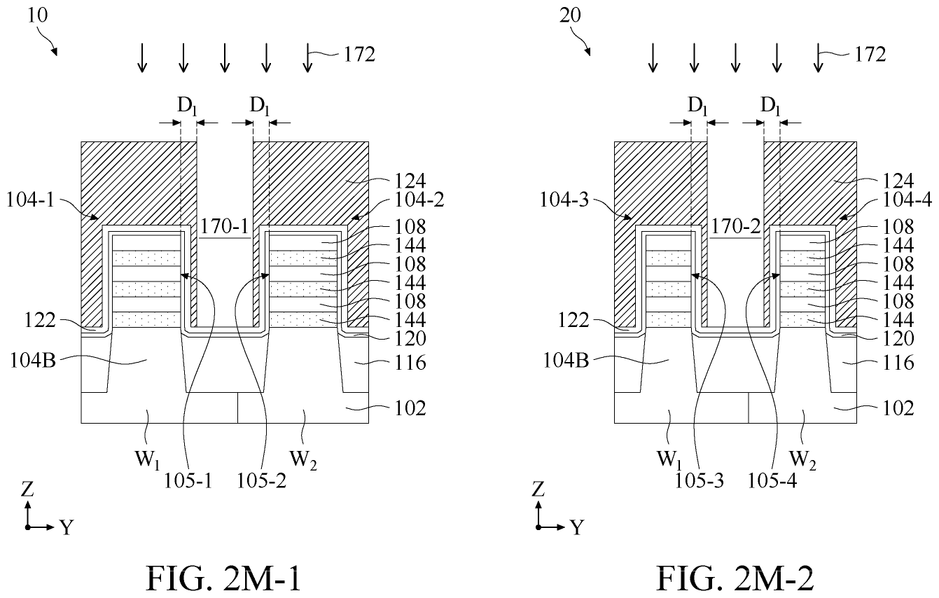

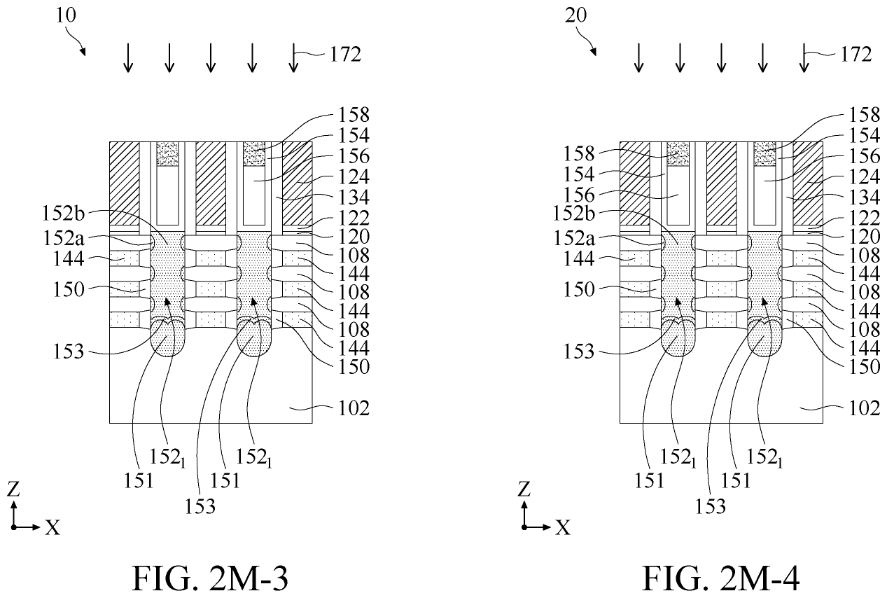

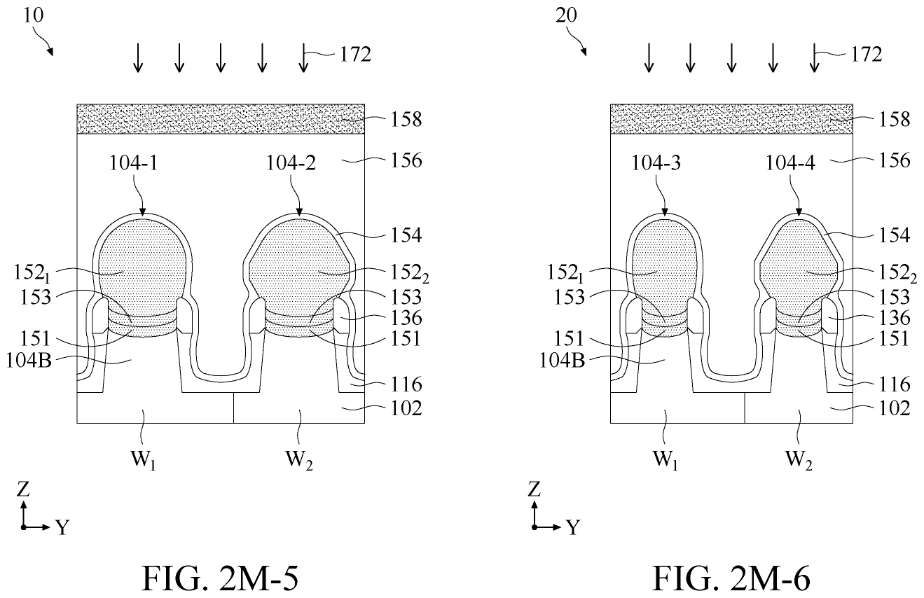

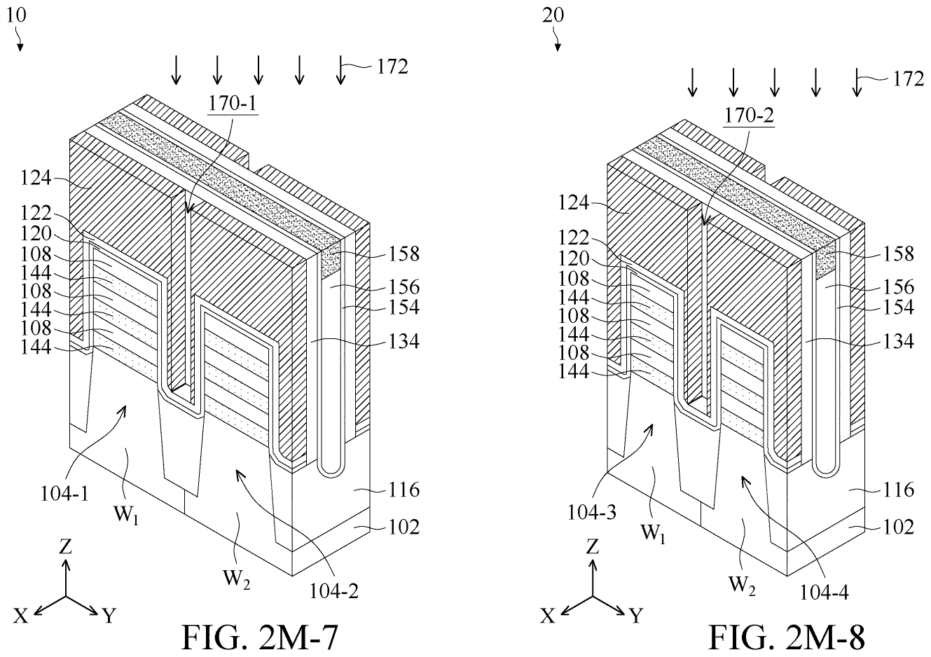

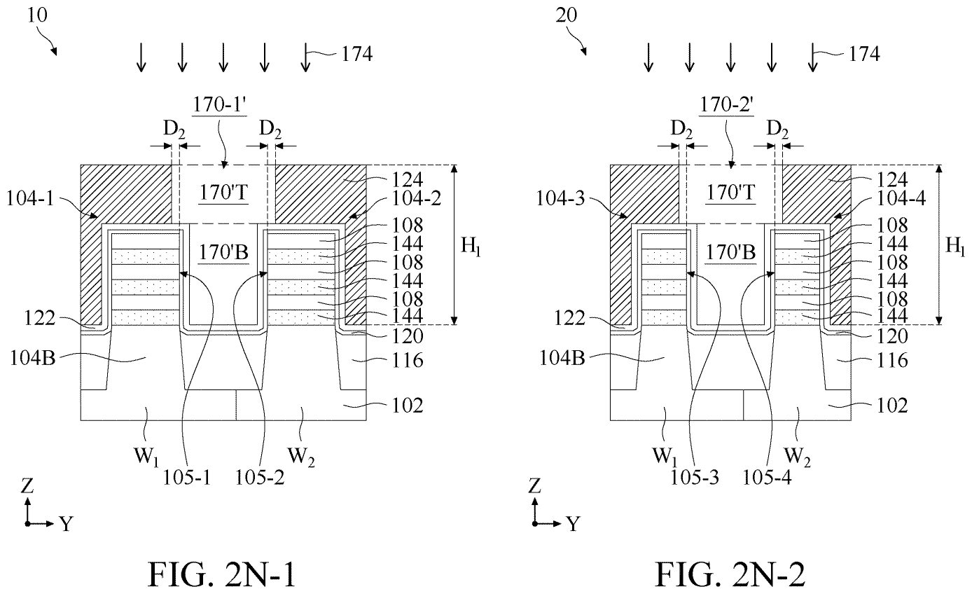

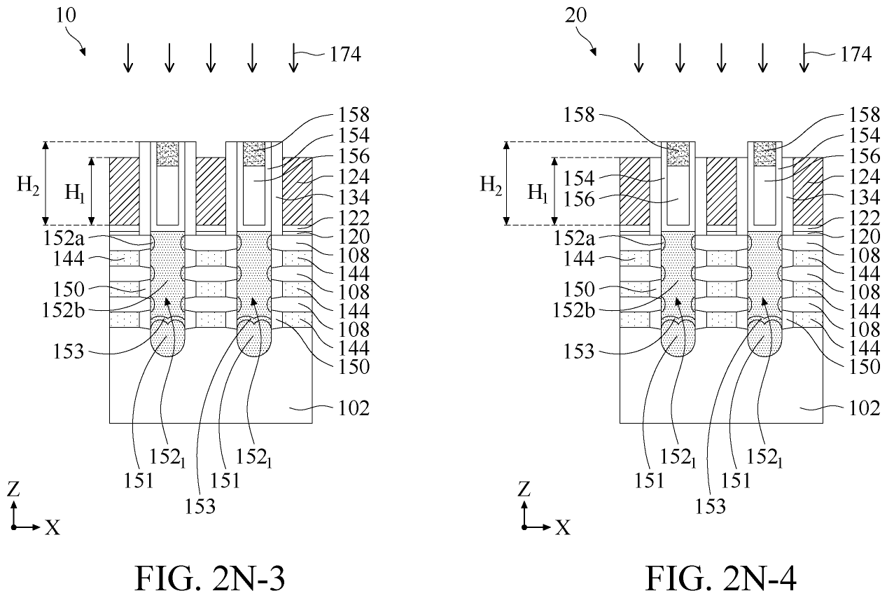

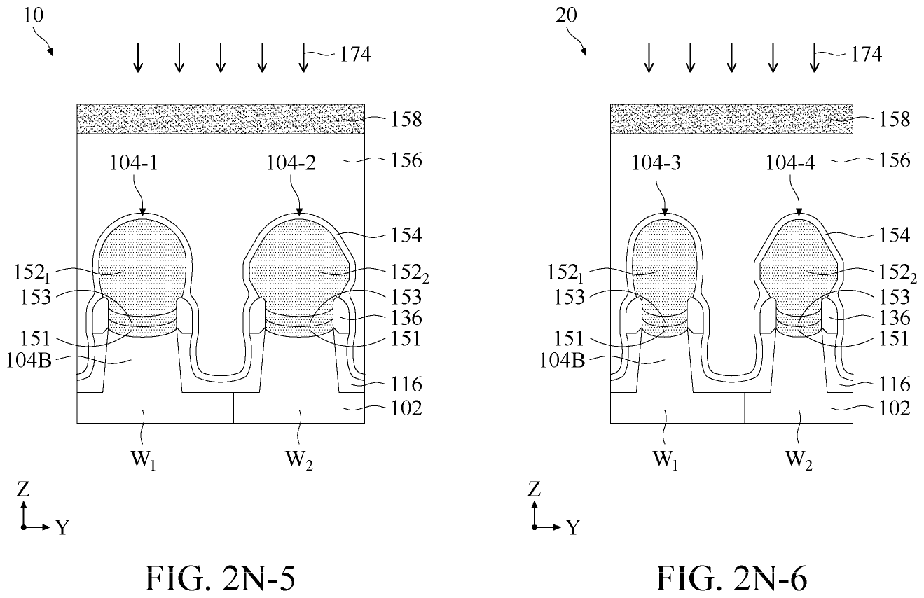

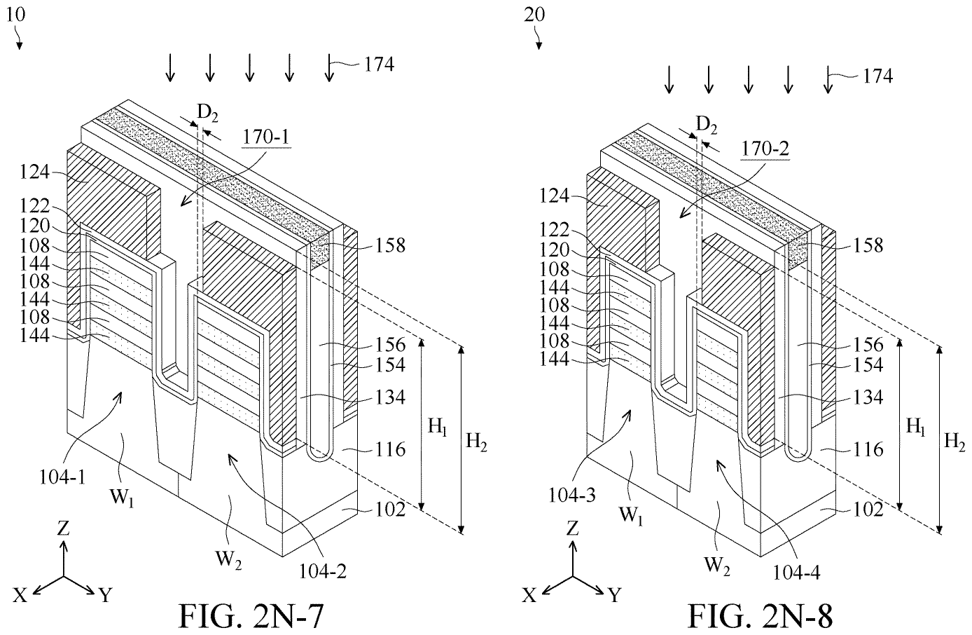

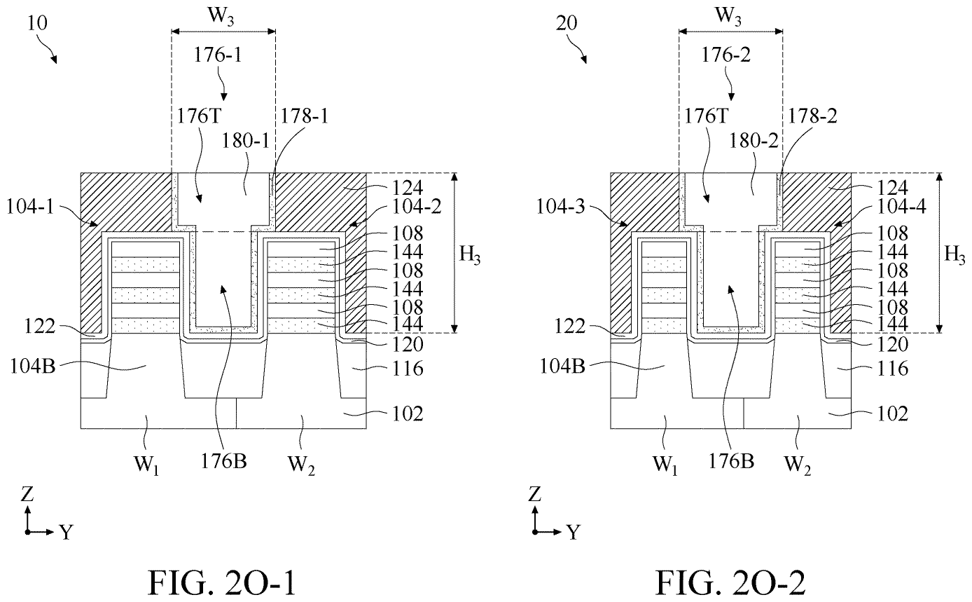

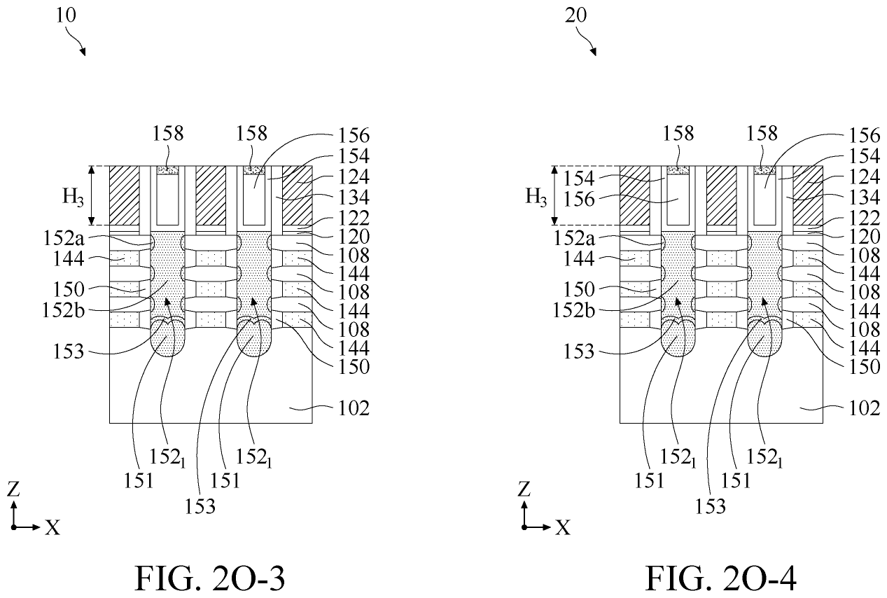

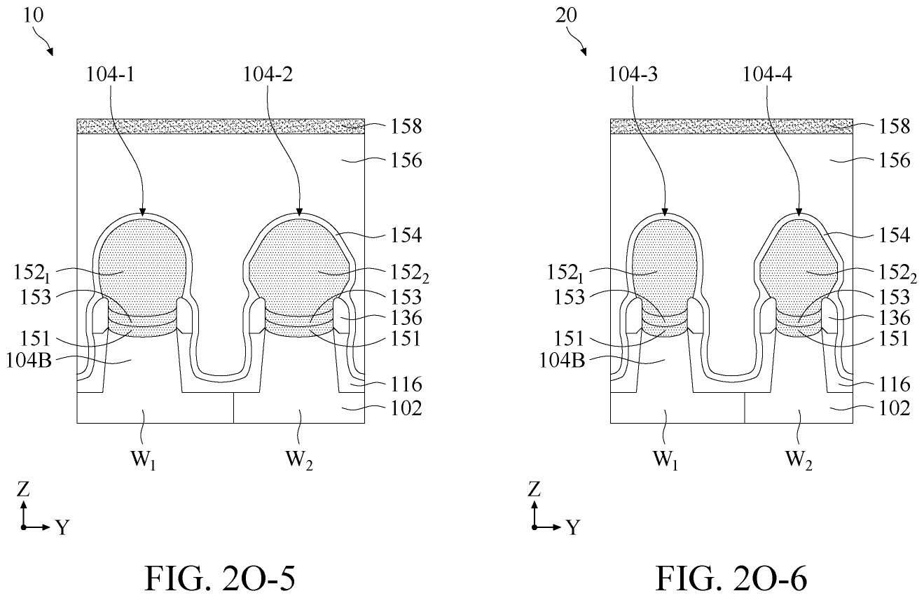

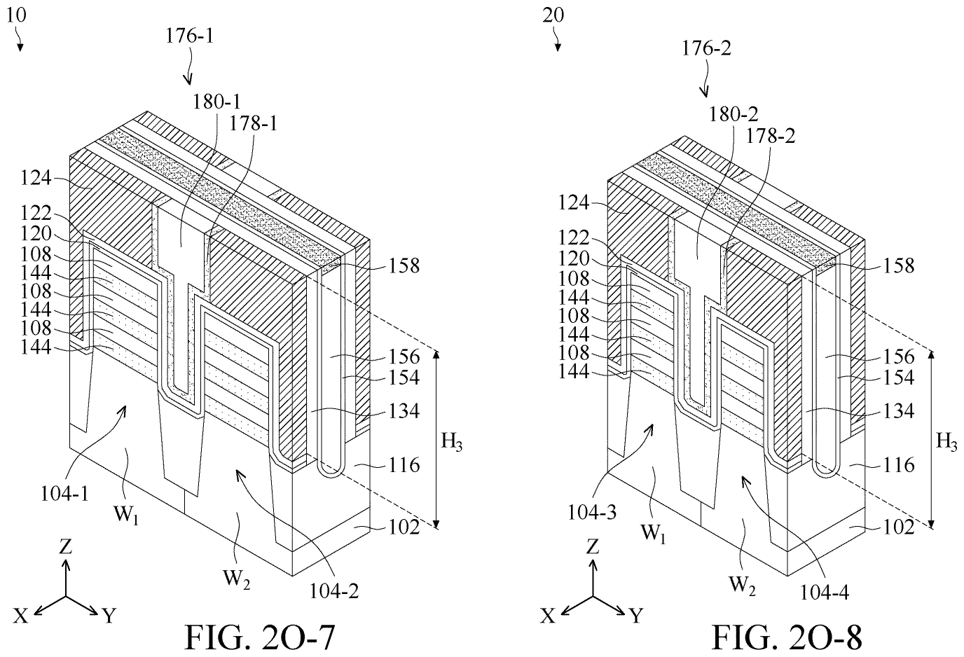

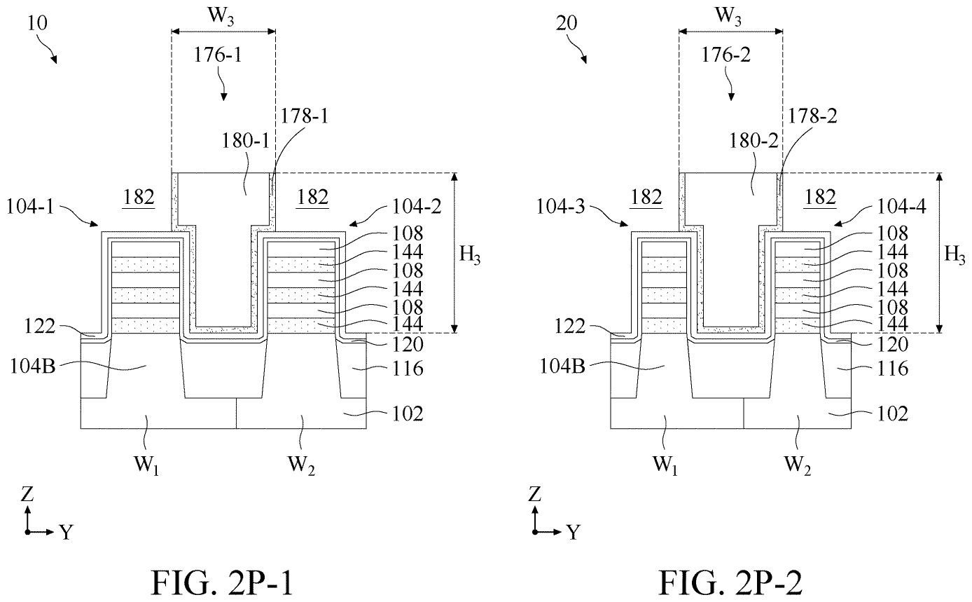

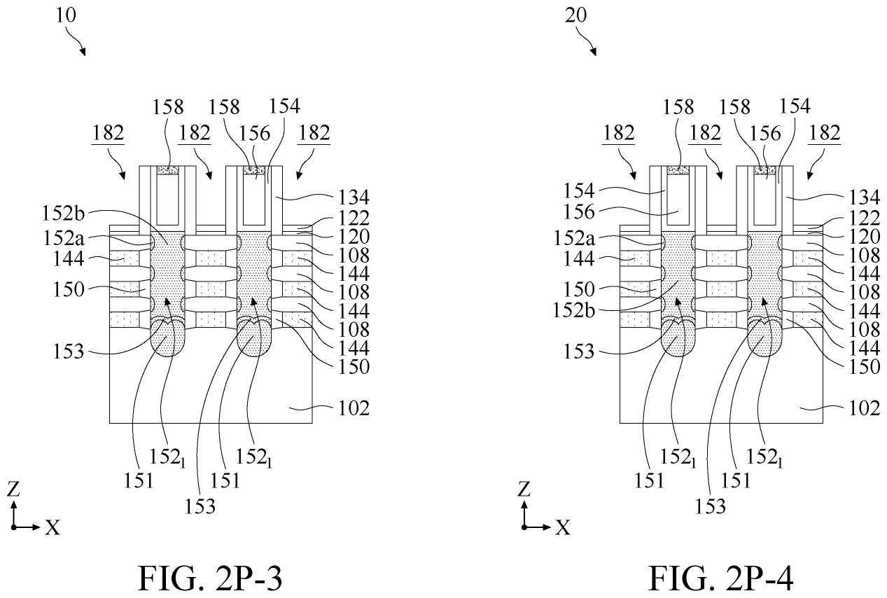

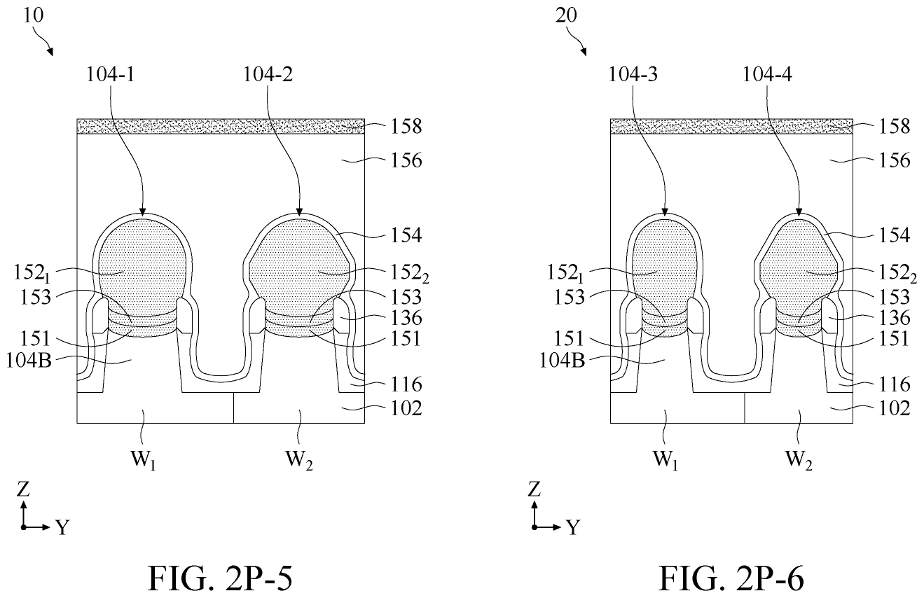

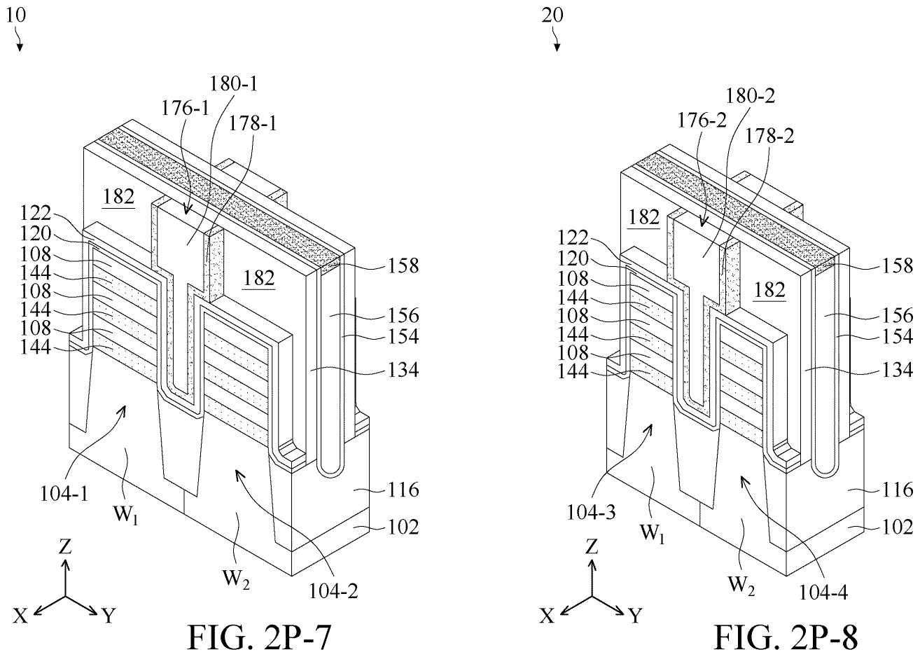

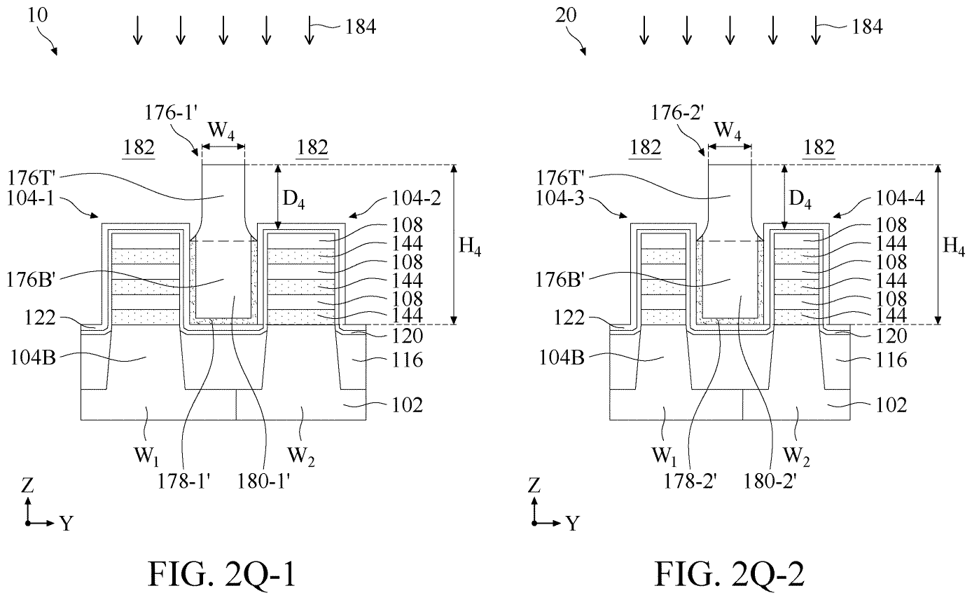

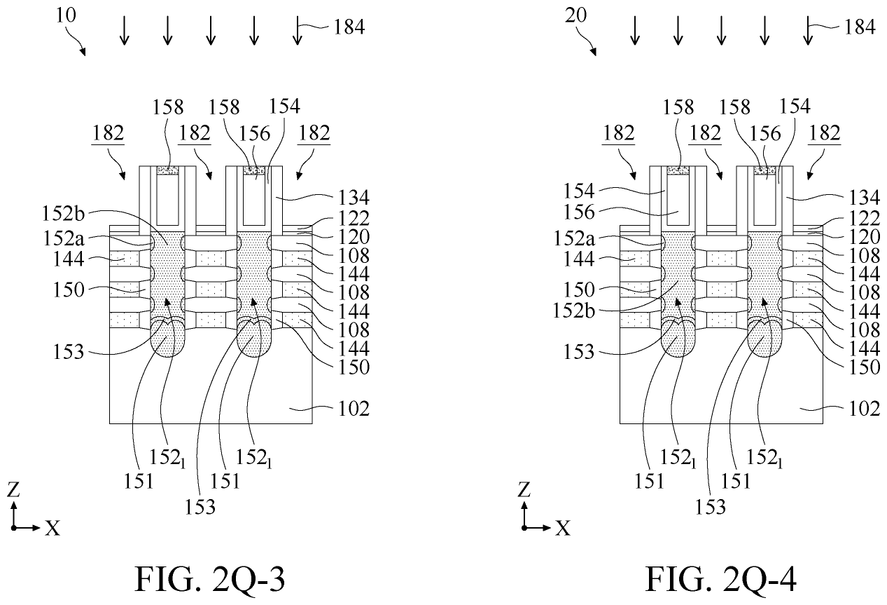

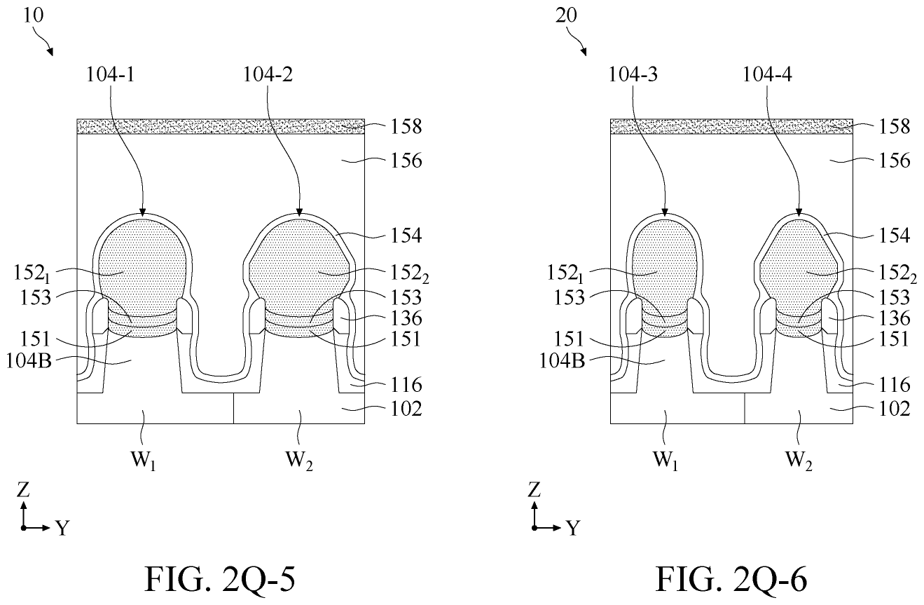

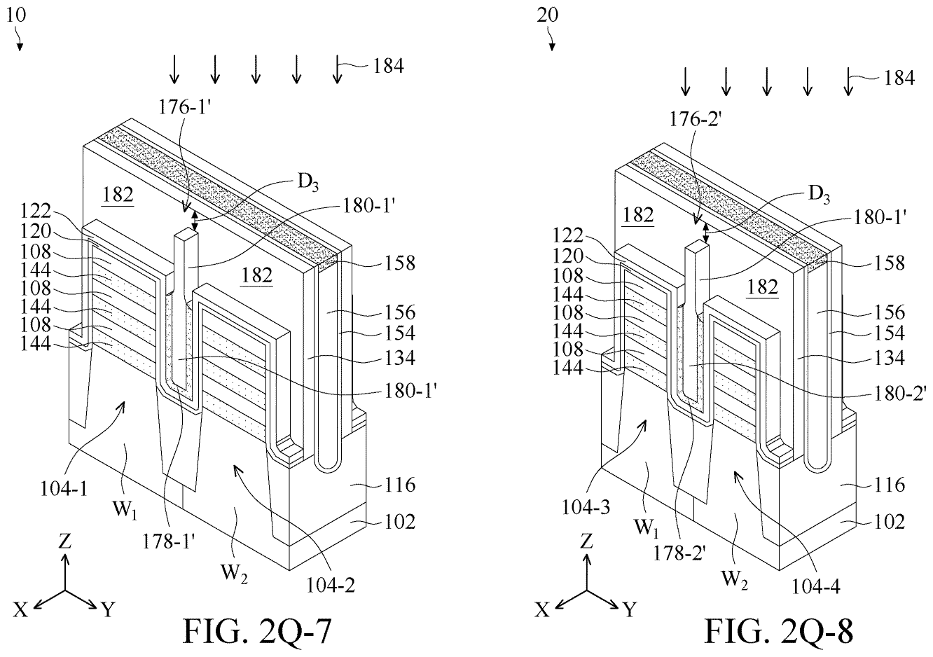

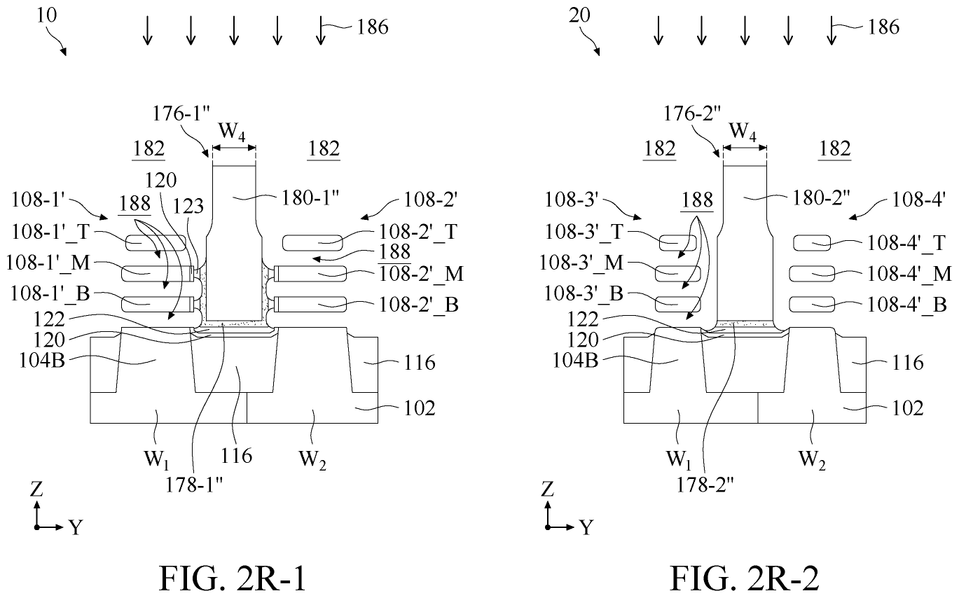

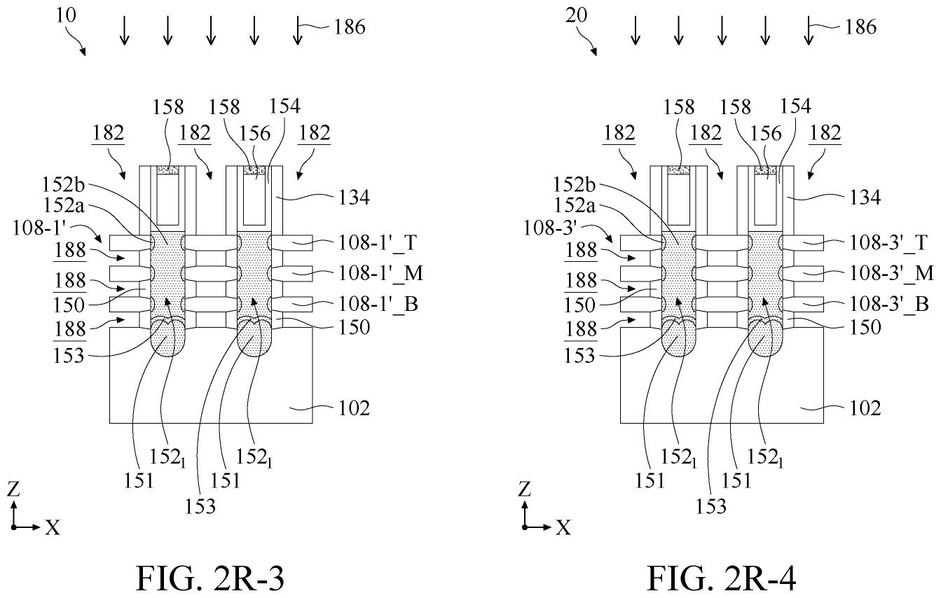

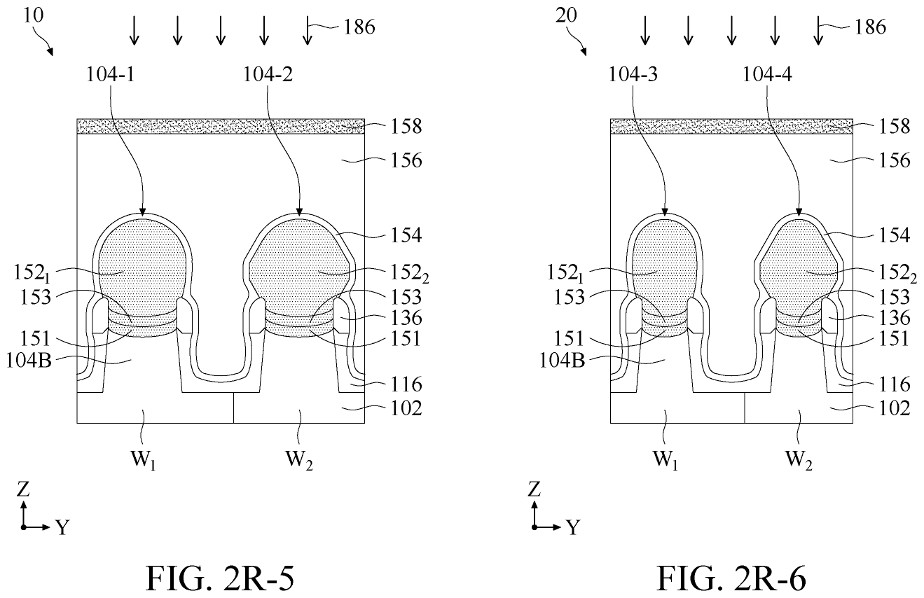

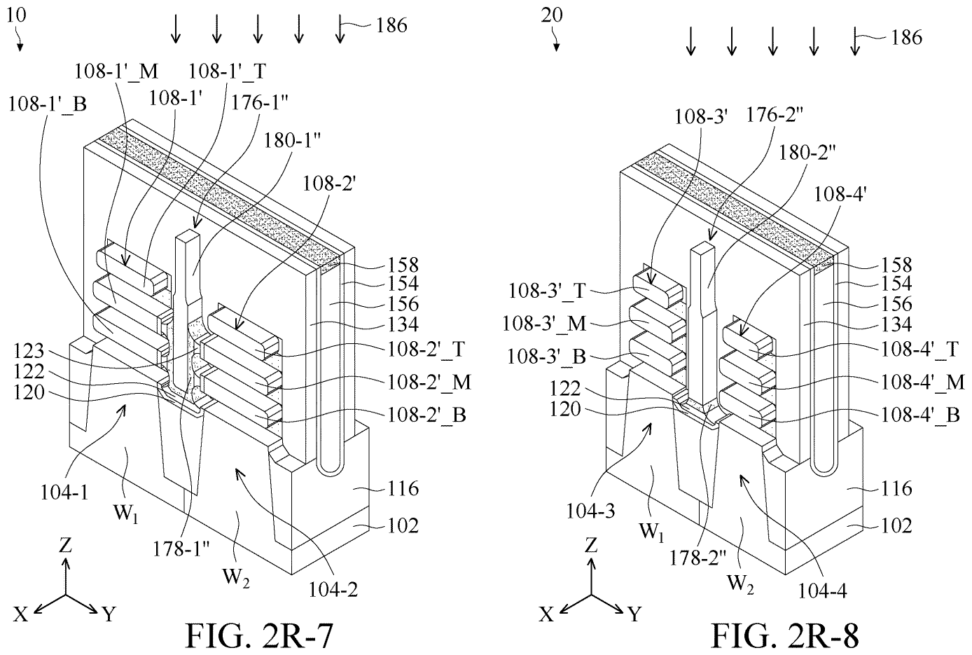

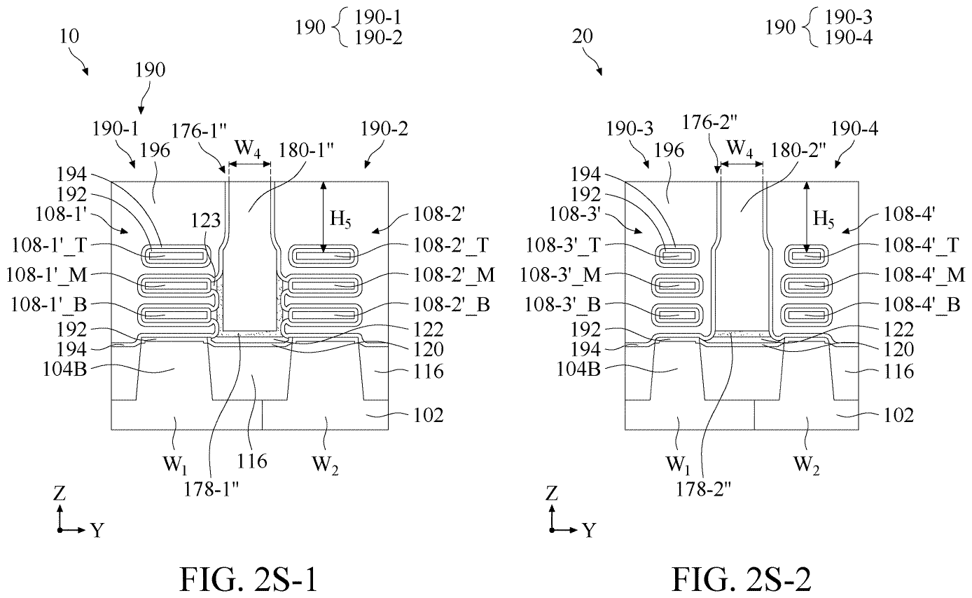

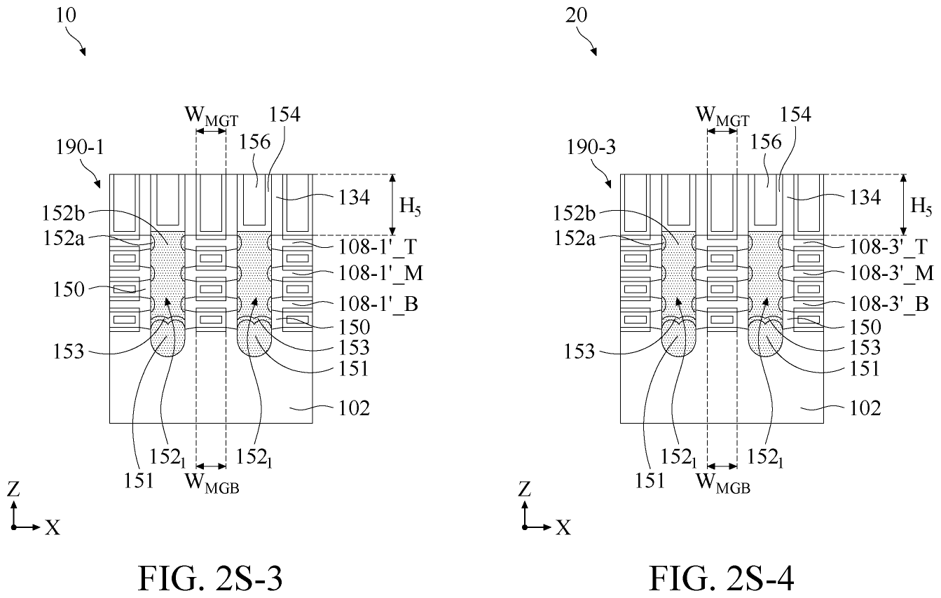

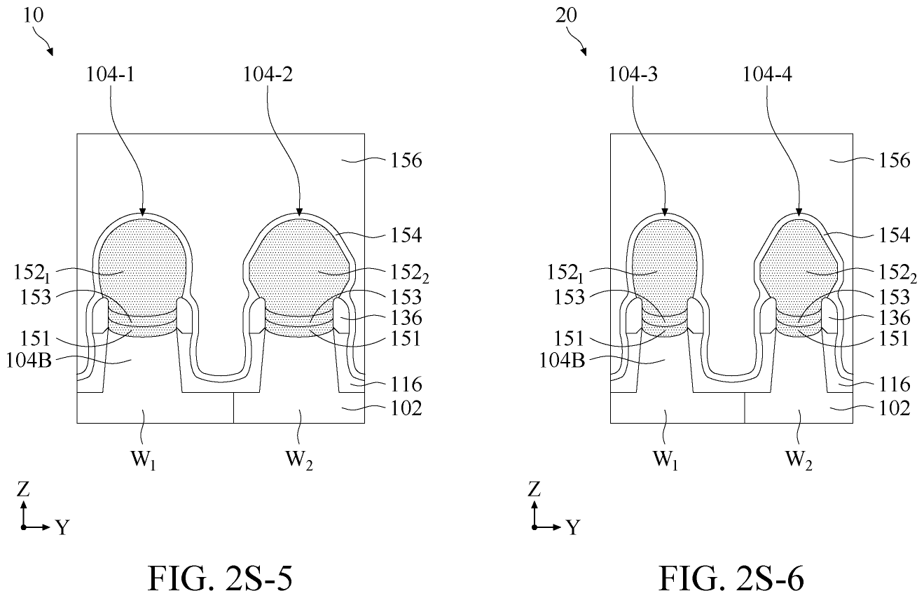

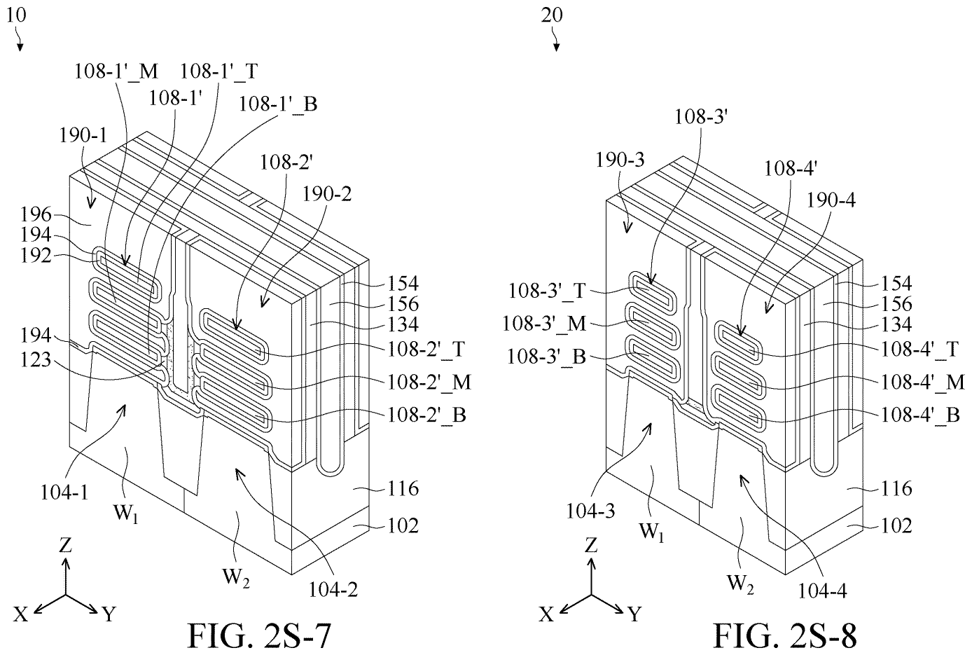

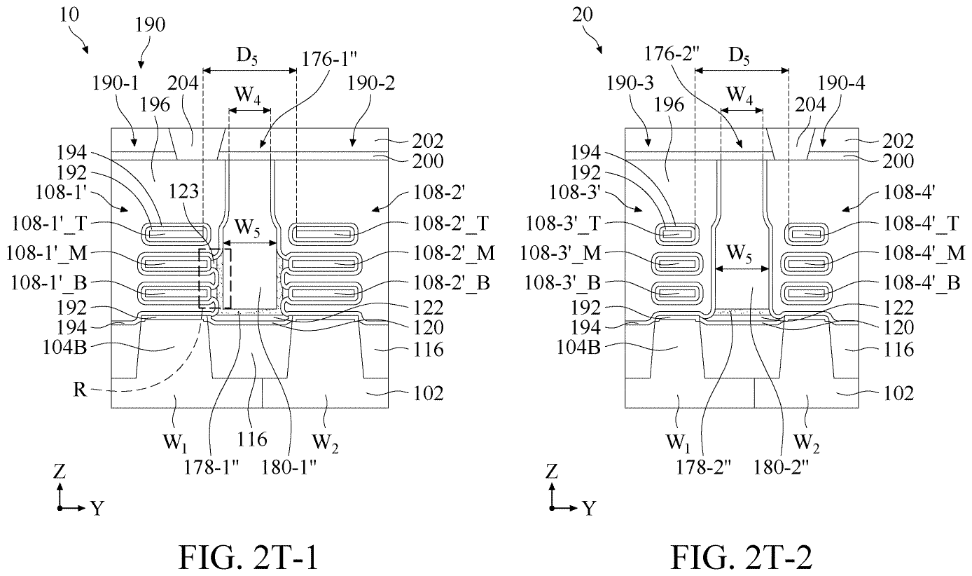

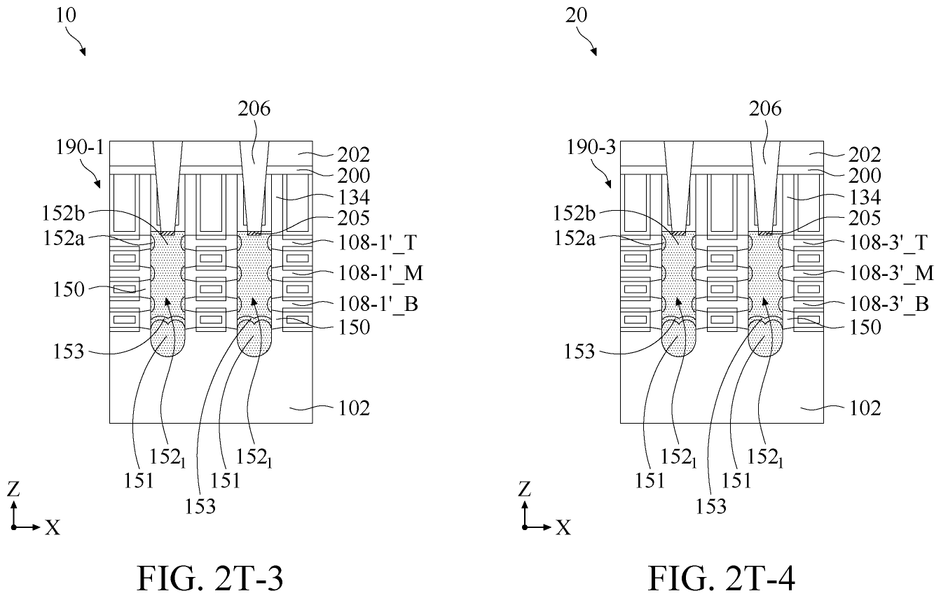

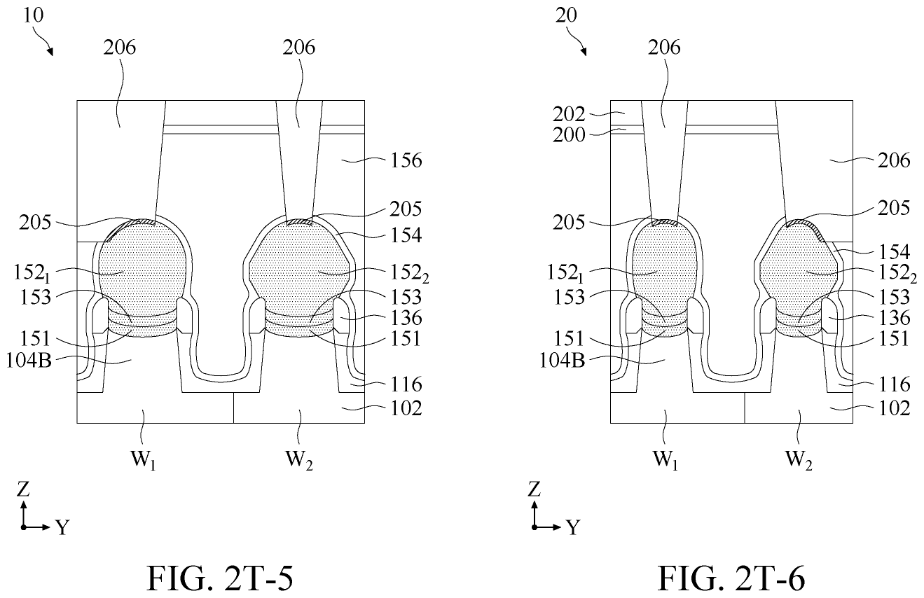

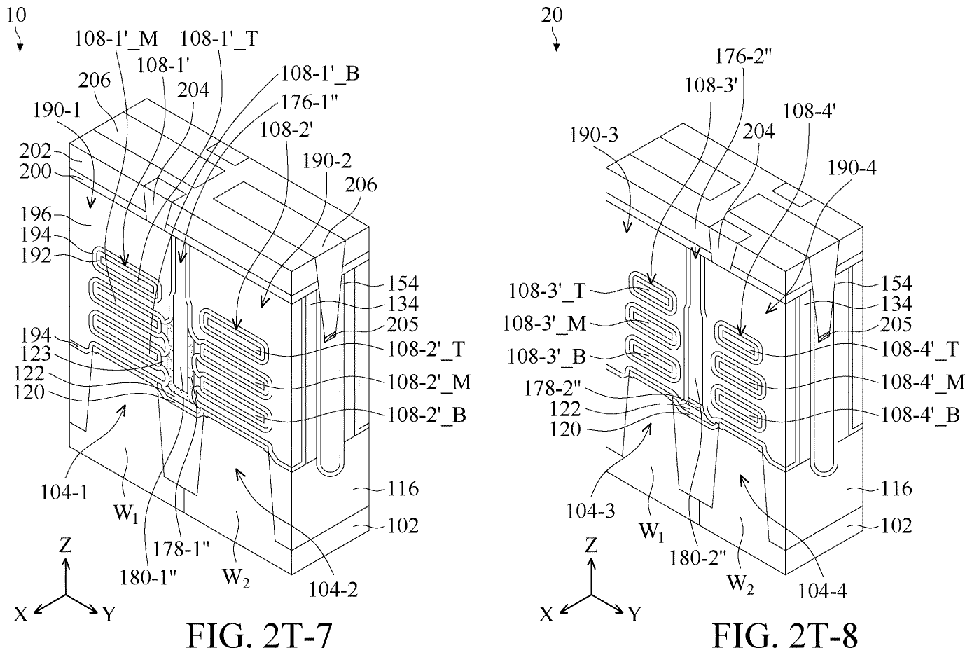

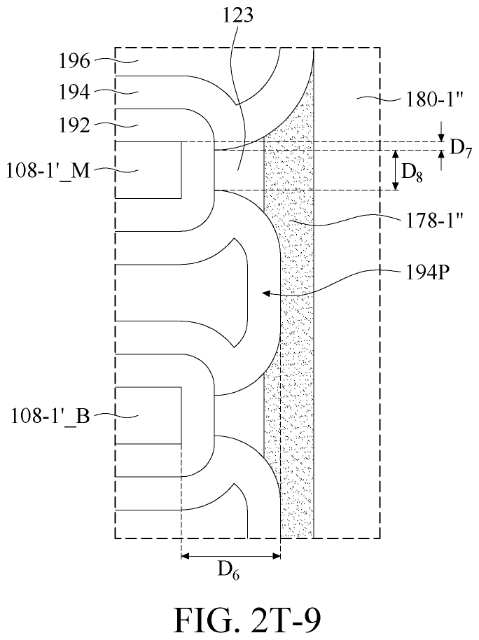

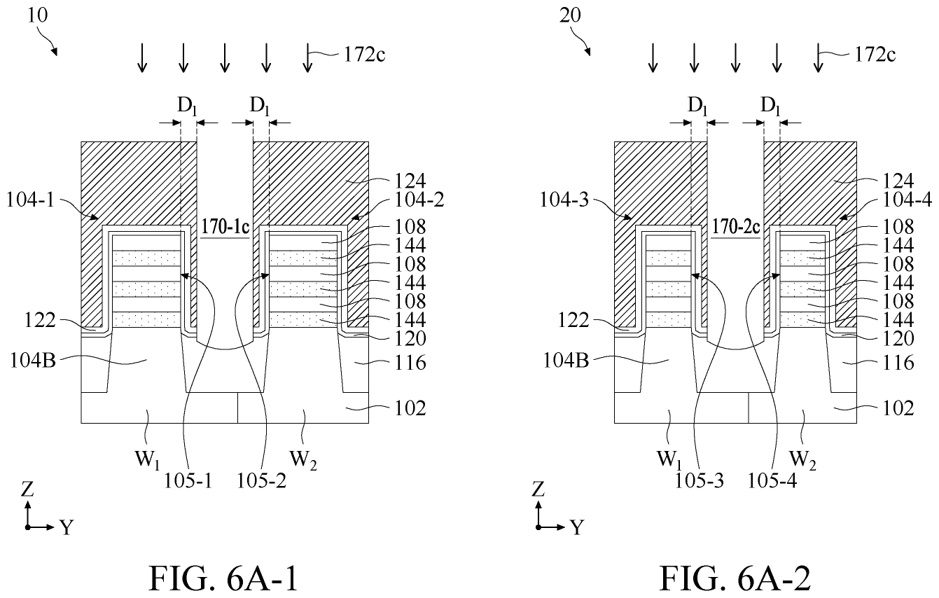

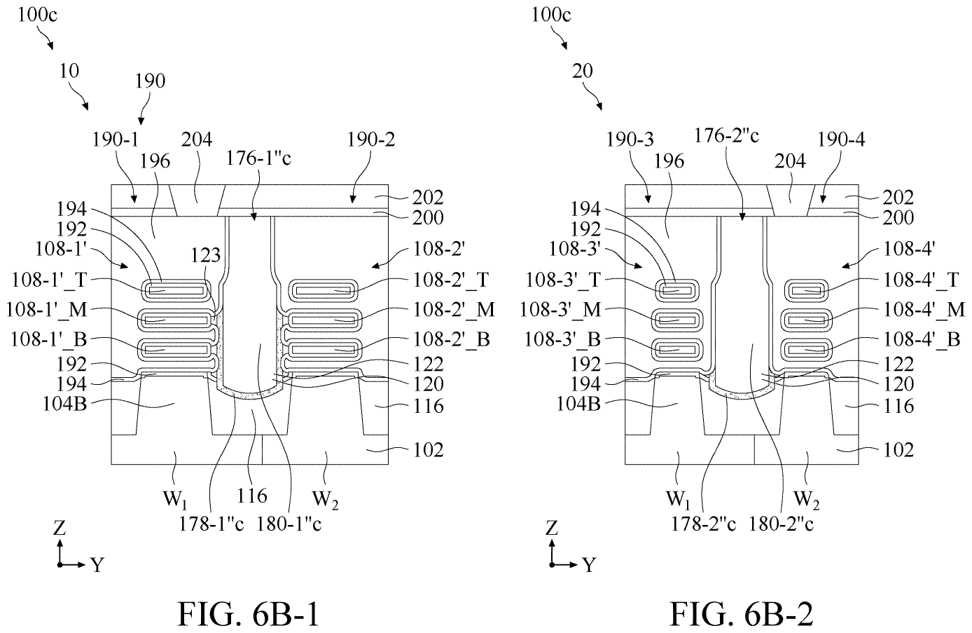

FIGS. 1A and 1B illustrate diagrammatic perspective views of intermediate stage of manufacturing a semiconductor structure 100 in a first region 10 and a second region 20, respectively, in accordance with some embodiments. FIGS. 2A-1 to 2T-1, 2A-3 to 2T-3, and 2A-5 to 2T-5 illustrate the cross-sectional views of intermediate stages of manufacturing the semiconductor structure 100 in the first region 10 shown along the lines Y_{MG1}-Y_{MG1}′ (i.e. in Y direction), X₁-X₁′ (i.e. in X direction), and Y_{SD1}-Y_{SD1}′ (i.e. in Y direction) in FIG. 1A, respectively, in accordance with some embodiments. FIGS. 2A-2 to 2T-2, 2A-4 to 2T-4, and 2A-6 to 2T-6 illustrate the cross-sectional views of intermediate stages of manufacturing the semiconductor structure 100 in the second region 20 shown along the lines Y_{MG2}-Y_{MG2}′ (i.e. in Y direction), X₂-X₂′ (i.e. in X direction), and Y_{SD2}-Y_{SD2}′ (i.e. in Y direction) in FIG. 1B, respectively, in accordance with some embodiments.

More specifically, FIGS. 2A-1, 2A-3, and 2A-5 illustrate the cross-sectional views of the intermediate stages of the semiconductor structure 100 in the first region 10 shown in FIG. 1A, and FIGS. 2A-2, 2A-4, and 2A-6 illustrate the cross-sectional views of the intermediate stages of the semiconductor structure 100 in the second region 20 shown in FIG. 1B, and FIGS. 2B-1 to 2T-1, 2B-2 to 2T-2, 2B-3 to 2T-3, 2B-4 to 2T-4, 2B-5 to 2T-5, and 2B-6 to 2T-6 illustrate the cross-sectional views of the intermediate stages of manufacturing the semiconductor structure 100 afterwards in accordance with some embodiments.

The semiconductor structure 100 may be formed over a substrate 102. For a better understanding of the semiconductor structures described herein, the X-Y-Z coordinate reference is provided in the figures of the present disclosure. The X-axis and the Y-axis are generally orientated along the lateral (or horizontal) direction that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

Well regions W₁ and W₂ are formed in the substrate 102 in the first region 10 and the second region 20 in accordance with some embodiments. The well regions W₁ and W₂ may be formed next to each other. In some embodiments, the well regions W₁ are P-type well regions, and N-type transistors are formed over the well regions W₁. In some embodiments, the well regions W₂ are N-type well regions, and P-type transistors are formed over the well regions W₂. In some other embodiments, the well regions W₁ are N-type well regions, and the well regions W₂ are P-type well regions, and transistors of opposite conductivity types are formed over the well regions W₁ and W₂.

After the well regions W₁ and W₂ are formed, a semiconductor stack including first semiconductor material layers 106 and second semiconductor material layers 108 is formed over both the first region 10 and the second region 20 of the substrate 102, as shown in FIGS. 1A, 1B, 2A-1, 2A-2, 2A-3, 2A-4, 2A-5, and 2A-6 in accordance with some embodiments.

In some embodiments, the first semiconductor material layers 106 and the second semiconductor material layers 108 are alternately stacked over the substrate 102 to form the semiconductor stack. The first semiconductor material layers 106 may also be called as sacrificial semiconductor layers since they will be removed afterwards. The second semiconductor material layers 108 may also be called as channel layers, since they will be function as the channel regions in the resulting transistors. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. In some embodiments, the Ge concentration in the first semiconductor material layers 106 is in a range from about 35 atm % to about 50 atm %.

It should be noted that although three first semiconductor material layers 106 and three second semiconductor material layers 108 are shown in the figures, the semiconductor stack may include less or more of the first semiconductor material layers 106 and the second semiconductor material layers 108 alternately stacked. For example, the semiconductor stack may include two to five of the first semiconductor material layers 106 and two to five of the second semiconductor material layers 108.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

After the first semiconductor material layers 106 and the second semiconductor material layers 108 are formed as the semiconductor stack over the substrate 102, the semiconductor stack is patterned to form fin structures 104, including fin structures 104-1, 104-2, 104-3, and 104-4, as shown in FIGS. 1A, 1B, 2A-1, 2A-2, 2A-3, 2A-4, 2A-5, and 2A-6 in accordance with some embodiments. The fin structures 104-1 to 104-4 may also be called as active regions. As shown in FIGS. 1A, 1B, 2A-1, 2A-2, 2A-5, and 2A-6, the widths WF₁ of the fin structures 104-1 and 104-2 are greater than the widths WF₂ of the fin structures 104-3 and 104-4 in Y direction in accordance with some embodiments. In some embodiments, the width WF₁ is greater than about 32 nm. In some embodiments, the width WF₂ is in a range from about 13 nm to about 32 nm.

The fin structures 104 may extend lengthwise in X direction, as shown in FIGS. 1A and 1B in accordance with some embodiments. In some embodiments, the fin structures 104 may be formed by performing a patterning process over the semiconductor material stack. The patterning process may include forming a mask structure over the semiconductor material stack and etching the semiconductor material stack and the underlying substrate 102 through the mask structure. In some embodiments, the mask structure is a multilayer structure including a pad oxide layer and a nitride layer formed over the pad oxide layer. The pad oxide layer may be made of silicon oxide, which is formed by thermal oxidation or CVD, and the nitride layer may be made of silicon nitride, which is formed by CVD, such as LPCVD or plasma-enhanced CVD (PECVD). In some embodiments, the fin structures 104 include base structures 104B and the semiconductor stacks, including the first semiconductor material layers 106 and the second semiconductor material layers 108, formed over the base structures 104B.

After the fin structures 104 are formed, an isolation structure 116 is formed around the fin structures 104, as shown in FIGS. 1A, 1B, 2A-1, 2A-2, 2A-5, and 2A-6 in accordance with some embodiments. The isolation structure 116 is configured to electrically isolate active regions (e.g. the fin structures 104) of the semiconductor structure 100 and is also referred to as shallow trench isolation (STI) feature in accordance with some embodiments. The isolation structure 116 may include multiple layers or an additional mask structure over its top portion, although they are not shown in the figures. In some embodiments, the isolation structure 116 is made of silicon-containing dielectric materials, such as silicon oxide (SiO₂), silicon nitride (SiN), silicon oxynitride (SiON), silicon carbon nitride (SiCN), silicon oxycarbonitride (SiOCN), and/or oxygen-doped silicon carbonitride (Si(O)CN). The isolation structure 116 may be formed by performing deposition processes to form a dielectric layer and performing an etching back process to remove the top portion of the dielectric layer so that the fin structures 104 are protruding from the top surface of the isolation structure 116. The deposition processes may be such as in situ steam generation (ISSG), thermal oxidation, CVD (such as low-pressure CVD (LPCVD), plasma-enhanced CVD (PECVD), high density plasma CVD (HDP-CVD), high aspect ratio process (HARP), or flowable CVD (FCVD)), atomic layer deposition (ALD), another suitable technique, and/or a combination thereof. The etching back process may be a wet etching process or a dry etching process.

In some embodiments, a portion of the isolation structure 116 is sandwiched between the base structures 104B of the fin structures 104-1 and 104-2 and interfaces the sidewall of the base structure 104B of the fin structure 104-1 and the sidewall of the base structure 104B of the fin structure 104-2. In some embodiments, a portion of the isolation structure 116 is sandwiched between the base structures 104B of the fin structures 104-3 and 104-4 and interfaces the sidewall of the base structure 104B of the fin structure 104-3 and the sidewall of the base structure 104B of the fin structure 104-4. In some embodiments, the isolation structure 116 has un-flat top surface, as shown in FIGS. 2A-1, 2A-2, 2A-4, and 2A-5.

After the isolation structure 116 is formed, cap layers 120, dielectric layers 122, and dummy gate electrodes 124 are formed across the fin structures 104, and the resulting structure is shown in FIGS. 2B-1, 2B-2, 2B-3, 2B-4, 2B-5, and 2B-6 in accordance with some embodiments. In some embodiments, the cap layers 120 are made of Si. In some other embodiments, the cap layers 120 are not formed. In some embodiments, the dielectric layers 122 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dielectric layers 122 are formed using thermal oxidation, CVD, ALD, physical vapor deposition (PVD), another suitable method, or a combination thereof.

The dummy gate electrodes 124 may be used to define the channel regions of the resulting semiconductor structure 100. The dummy gate electrodes 124 may be longitudinally oriented along Y direction and may be replaced with gate structures afterwards. In some embodiments, the dummy gate electrodes 124 are made of conductive material that includes polycrystalline-silicon (poly-Si), poly-crystalline silicon-germanium (poly-SiGe), or a combination thereof. In some embodiments, the dummy gate electrodes 124 are formed using CVD, PVD, or a combination thereof.

In some embodiments, hard mask structures 126 are formed over the dummy gate electrodes 124. In some embodiments, each of the hard mask structures 126 includes multiple layers, such as an oxide layer 128 and a nitride layer 130. In some embodiments, the oxide layer 128 is made of silicon oxide, and the nitride layer 130 is made of silicon nitride.

The formation of the structure described above may include conformally forming a cap layer, a dielectric material as the dielectric layers 122, a conductive material over the dielectric material as the dummy gate electrodes 124, and the hard mask structures 126 over the conductive material. Next, the cap layer, the dielectric material, and the conductive material may be patterned through the hard mask structure 126 to form the cap layer 120, the dielectric layer 122, and the dummy gate electrodes 124.

After the dummy gate electrodes 124 are formed, a spacer layer 132 is formed to cover the top surfaces and the sidewalls of the dummy gate electrodes 124 and the fin structures 104, as shown in FIGS. 2C-1, 2C-2, 2C-3, 2C-4, 2C-5, and 2C-6 in accordance with some embodiments. In addition, the spacer layer 132 also covers the top surfaces of the isolation structure 116 and the hard mask structure 126 in accordance with some embodiments. In some embodiments, the spacer layer 132 include one or multiple dielectric layers. The dielectric materials for forming the spacer layer 132 may include silicon oxide (SiO₂), silicon nitride (SiN), silicon carbide (SiC), silicon oxynitride (SiON), silicon carbon nitride (SiCN), silicon oxide carbonitride (SiOCN), silicon oxycarbide (SiOC), or a combination thereof. The thickness of the spacer layer 132 is in a range from about 4 nm to about 6 nm.

After the spacer layer 132 is formed, an etching process is performed to form gate spacers 134 and fin spacers 136 with the spacer layer 132 and to form source/drain recesses 138 in the fin structures 104, and the resulting structure is shown in FIGS. 2D-1, 2D-2, 2D-3, 2D-4, 2D-5, and 2D-6 in accordance with some embodiments. The gate spacers 134 may be configured to separate source/drain structures (formed afterwards) from the dummy gate electrodes 124, and the fin spacers 136 may be configured to confine the growth of the source/drain structures formed therein.

More specifically, the spacer layer 132 is etched to form the gate spacers 134 on opposite sidewalls of the dummy gate electrodes 124, the dielectric layers 122, and the cap layers 120 and to form the fin spacers 136 covering the sidewalls of the fin structures 104 in accordance with some embodiments. In addition, the portions of the fin structures 104 not covered by the dummy gate electrodes 124 and the gate spacers 134 are etched to form the source/drain recesses 138 during the etching process in accordance with some embodiments. The etching process may be an anisotropic etching process, such as dry plasma etching, and the dummy gate electrode 124 (or the mask structures 126) and the gate spacers 134 may be used as etching masks during the etching process. In some embodiments, the isolation structure 116 is also etched during the etching process, such that the isolation structure 116 has curved and recessed top surfaces, as shown in FIGS. 2D-5 and 2D-6.

After the source/drain recesses 138 are formed, the first semiconductor material layers 106 are removed through the source/drain recesses 138, and the resulting structure is shown in FIGS. 2E-1, 2E-2, 2E-3, 2E-4, 2E-5, and 2E-6 in accordance with some embodiments. In some embodiments, an etching process is performed to remove the first semiconductor layers 106, thereby forming gaps 140. The etching processes may be an isotropic etching process, such as dry chemical etching, remote plasma etching or wet chemical etching, or a combination thereof. In some embodiments, the isolation structure 116 is also partially etched during the etching process.

After the gaps 140 are formed, a dielectric sacrificial layer 142 is formed, as shown in FIGS. 2F-1, 2F-2, 2F-3, 2F-4, 2F-5, and 2F-6 in accordance with some embodiments. More specifically, the dielectric sacrificial layer 142 is deposited to fill the gaps 140 and to cover the dummy gate electrodes 124 and the gate spacers 134, as shown in FIGS. 2F-1, 2F-2, 2F-3, and 2F-4 in accordance with some embodiments. In addition, the fin spacers 136, the isolation structure 116, and the source/drain recesses 138 are also covered by the dielectric sacrificial layer 142, as shown in FIGS. 2F-5 and 2F-6 in accordance with some embodiments.

The dielectric sacrificial layer 142 may be a single or multiple dielectric material layers. In some embodiments, the dielectric sacrificial layer 142 is made of silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the dielectric sacrificial layer 142 is formed by performing a deposition process, such as ALD, CVD (such as PECVD, LPCVD or HARP), another suitable technique, or a combination thereof.

After the dielectric sacrificial layer 142 is formed, an etching process is performed to form dielectric sacrificial features 144 with the dielectric sacrificial layer 142, and the resulting structure is shown in FIGS. 2G-1, 2G-2, 2G-3, 2G-4, 2G-5, and 2G-6 in accordance with some embodiments. More specifically, an etching process may be performed to etch away the dielectric sacrificial layer 142 outside the gaps 140. In some embodiments, dielectric sacrificial layer 142 in the gaps 140 are also partially etched during the etching process, so that the sidewalls of the dielectric sacrificial features 144 are recessed from the sidewalls of the second semiconductor material layers 108, as shown in FIGS. 2G-3 and 2G-4 in accordance with some embodiments. That is, notches 146 are formed between the second semiconductor material layers 108 and between the bottommost one of the second semiconductor material layers 108 and the base structures 104B in accordance with some embodiments. In some embodiments, the etching process includes an anisotropic etching process such as dry plasma etching, an isotropic etching process such as dry chemical etching, remote plasma etching or wet chemical etching, or a combination thereof.

As shown in FIGS. 2G-1, 2G-2, 2G-3, and 2G-4, the first semiconductor layers 106 are now replaced with the dielectric sacrificial features 144, and therefore the Ge diffusion due to the first semiconductor material layers 106 in subsequent manufacturing processes (e.g. the annealing processes for forming source/drain structures) may be prevented. In addition, the etching selectivity (e.g., greater than 10000) between the dielectric sacrificial features 144 (e.g., SiOx) and the second semiconductor material layers 108 (e.g., Si) may be much greater than the etching selectivity (e.g., about 170) between the first semiconductor material layers 106 (e.g., SiGe) and the second semiconductor material layers 108 (e.g., Si). Therefore, the loss of the channel layers (i.e. the second semiconductor material layers 108) in the following channel-releasing process can be reduced.

Afterwards, an inner spacer layer 148 is formed, as shown in FIGS. 2H-1, 2H-2, 2H-3, 2H-4, 2H-5, and 2H-6 in accordance with some embodiments. More specifically, the inner spacer layer 148 is deposited to fill the notches 146 and to cover the dummy gate electrodes 124 and the gate spacers 134, as shown in FIGS. 2H-1, 2H-2, 2H-3, and 2H-4 in accordance with some embodiments. In addition, the fin spacers 136, the isolation structure 116, and the source/drain recesses 138 are also covered by the inner spacer layer 148, as shown in FIGS. 2H-5 and 2H-6 in accordance with some embodiments.

The inner spacer layer 148 may be a single or multiple dielectric material layers. In some embodiments, the inner spacer layer 148 is made of dielectric material, such as silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the inner spacer layer 148 and the dielectric sacrificial layer 142 are made of different dielectric materials. In some embodiments, the inner spacer layer 148 is formed by performing a deposition process, such as ALD, CVD (such as PECVD, LPCVD or HARP), another suitable technique, or a combination thereof.

After the inner spacer layer 148 is formed, an etching process is performed to form inner spacers 150 with the inner spacer layer 148, and the resulting structure is shown in FIGS. 2I-1, 2I-2, 2I-3, 2I-4, 2I-5, and 2I-6 in accordance with some embodiments. More specifically, an etching process may be performed to etch away the inner spacer layer 148 outside the notches 146. In some embodiments, the etching process includes an anisotropic etching process such as dry plasma etching, an isotropic etching process such as dry chemical etching, remote plasma etching or wet chemical etching, or a combination thereof.

The inner spacers 150 are formed to abut the recessed sidewall surfaces of the dielectric sacrificial features 144 in accordance with some embodiments. In some embodiments, the inner spacers 150 are located directly below the gate spacers 134. The inner spacers 150 may prevent the source/drain structures and the gate structure formed afterwards from being in direct contact with each other and may be configured to reduce the parasitic capacitance between the gate structures and the source/drain structures (i.e., Cgs and Cgd). In some embodiments, the inner spacers 150 have a thickness (in X direction) in a range from about 3 nm to about 6 nm.

As described previously, the inner spacer layer 148 and the dielectric sacrificial layer 142 are made of different materials, and therefore the inner spacers 150 and the dielectric sacrificial features 144 are made of different materials in accordance with some embodiments. Accordingly, when the dielectric sacrificial features 144 are removed during the subsequent processes, the inner spacers 150 may remain.

After the inner spacers 150 are formed, semiconductor isolation features 151, dielectric isolation features 153, source/drain structures 152 are formed in the source/drain recesses 138, and the resulting structure is shown in FIGS. 2J-1, 2J-2, 2J-3, 2J-4, 2J-5, and 2J-6 in accordance with some embodiments. In addition, FIGS. 2J-7 to 2T-7 and 2J-8 to 2T-8 illustrate the diagrammatic perspective views of the intermediate stages of the semiconductor structure 100 in the first region 10 and the second region 20 in accordance with some embodiments. More specifically, FIGS. 2J-7 and 2J-8 illustrate the diagrammatic perspective views of the structure shown in FIGS. 2J-1 to 2J-6 in accordance with some embodiments.

More specifically, an interposing layer, for example, the semiconductor isolation features 151, are formed in bottom portions of the source/drain recesses 138 in accordance with some embodiments. In some embodiments, the semiconductor isolation features 151 are made of an epitaxial semiconductor material such as non-doped silicon, formed by MBE, MOCVD, or VPE, another suitable technique, or a combination thereof.

After the semiconductor isolation features 151 are formed, the dielectric isolation features 153 are formed over the semiconductor isolation features 151 in accordance with some embodiments. The dielectric isolation features 153 are configured to reduce the parasitic capacitance of the resulting transistors. In some embodiments, the dielectric isolation features 153 are made of a dielectric material, such as silicon oxide (SiO₂), silicon nitride (SiN), silicon carbide (SiC), silicon oxynitride (SiON), silicon carbon nitride (SiCN), silicon oxycarbonitride (SiOCN), SiOC, Si, SiO₂, and/or oxygen-doped silicon carbonitride (Si(O)CN), or a combination thereof. In some embodiments, the dielectric isolation features 153 are deposited using a technique such as ALD, CVD (such as HDP-CVD, LPCVD or PECVD), another suitable technique, or a combination thereof, followed by an etching-back process. In some embodiments, the dielectric isolation features 153 have a thickness of about 2 nm to about 6 nm.

In some embodiments, the source/drain structures 152 are formed by performing epitaxial growth processes, such as MBE, MOCVD, or VPE, another suitable technique, or a combination thereof. In some embodiments, the source/drain structures 152 are in-situ doped during the epitaxial processes. In some embodiments, the source/drain structures 152 may be multilayered structures, e.g., including sequentially formed layers 152a and 152b (as shown in FIGS. 2J-3 and 2J-4). In some embodiments, the concentration of the dopants in the layer 152b is higher than the concentration of the dopant in the layer 152a.

In some embodiments, the source/drain structures 152 include source/drain structures 152₁ and 152₂. In some embodiments, the source/drain structures 152₁ and the source/drain structures 152₂ include different types of dopants. In some embodiments, the source/drain structures 152₁ include P-type dopants (such as B) and the source/drain structures 152₂ include N-type dopants (such as P). In some embodiments, the source/drain structures 152₁ and the source/drain structures 152₂ are made of different epitaxial materials. For example, the source/drain structures 152₁ are P-type source/drain structures made of SiGe, and the source/drain structures 152₂ are N-type source/drain structures made of SiP. As shown in FIGS. 2J-5 and 2J-6, the source/drain structures 152₁ and the source/drain structures 152₂ may have different shapes and sizes.

The source/drain structures 152₁ and the source/drain structures 152₂ may be formed separately. For example, a patterned mask layer (such as a photoresist layer and/or a hard mask layer) may be formed to cover the semiconductor structure over the well regions W₂, and then the source/drain structure 152₁ are grown. Afterwards, the patterned mask layer may be removed. Similarly, a patterned mask layer (such as a photoresist layer and/or a hard mask layer) may be formed to cover the semiconductor structure over the well regions W₁, and then the source/drain structures 152₂ are grown. Afterward, the patterned mask layer may be removed. Once the source/drain structures 152₁ and 152₂ are formed, an annealing process may be performed to activate the dopants in the source/drain structure 152₁ and 152₂ in accordance with some embodiments.

As described previously, since the first semiconductor material layers 106 have been replaced with the dielectric sacrificial features 144 before the formation of the source/drain structures 152, Ge diffusion into the second semiconductor material layers 108 due to the annealing process can be prevented.

In some embodiments, the source/drain structures 152 further include additional semiconductor isolation features (not shown) in the bottom portions of the source/drain recesses 138 in accordance with some embodiments. In some embodiments, the semiconductor isolation features are made of an epitaxial semiconductor material such as non-doped silicon, formed by MBE, MOCVD, or VPE, another suitable technique, or a combination thereof.

After the source/drain structures 152 are formed, and a contact etch stop layer (CESL) 154 is conformally formed to cover the source/drain structures 152, and an interlayer dielectric (ILD) layer 156 and a mask layer 158 are formed over the contact etch stop layers 154, and the resulting structure is shown in FIGS. 2K-1, 2K-2, 2K-3, 2K-4, 2K-5, 2K-6, 2K-7, and 2K-8 in accordance with some embodiments.

In some embodiments, the contact etch stop layer 154 is made of a dielectric material, such as silicon nitride, silicon oxide, silicon oxynitride, another suitable dielectric material, or a combination thereof. The dielectric material for the contact etch stop layers 154 may be conformally deposited over the semiconductor structure by performing CVD, ALD, other application methods, or a combination thereof.

The interlayer dielectric layer 156 may include multilayers made of multiple dielectric materials, such as silicon oxide, silicon nitride, silicon oxynitride, phosphosilicate glass (PSG), borophosphosilicate glass (BPSG), or other applicable low-k dielectric materials. The interlayer dielectric layer 156 may be formed by chemical vapor deposition (CVD), physical vapor deposition, (PVD), atomic layer deposition (ALD), or other applicable processes.

After the contact etch stop layer 154 and the interlayer dielectric layer 156 are deposited, a planarization process such as CMP or an etch-back process is performed until the dummy gate electrode 124 is exposed in accordance with some embodiments. That is, the hard mask structure 126 may be removed during the planarization process. Next, the interlayer dielectric layer 156 is recessed to form recesses, and the mask layer 158 is formed in the recesses, as shown in FIGS. 2K-3, 2K-4, 2K-5, 2K-6, 2K-7, and 2K-8 in accordance with some embodiments. The mask layer 158 is made of a dielectric material, such as SiN, SiCN, SiOC, SiOCN, HfO₂, ZrO₂, HfAlOₓ, HfSiOₓ, Al₂O₃, or the like. In some embodiments, the mask layer 158 has a thickness in a range of about 23 nm to about 30 nm.

Next, a mask structure 160 is formed to cover the dummy gate electrodes 124, the gate spacers 134, the contact etch stop layer 154, and the mask layer 158, as shown in FIGS. 2L-1, 2L-2, 2L-3, 2L-4, 2L-5, 2L-6, 2L-7, and 2L-8 in accordance with some embodiments. In addition, the mask structure 160 includes openings 162 partially exposing the dummy gate electrodes 124 in accordance with some embodiments. In some embodiments, the openings 162 are not vertically overlapped with any of the fin structures 104. In some embodiments, a width of the opening 162 is smaller than the distance between the sidewalls of two neighboring fin structures 104 facing each other (i.e. the distance between the fin structures 104-1 and 104-2 and the distance between the fin structures 104-3 and 104-4).

In some embodiments, the mask structure 160 include multiple material layers, such as a first mask layer 164, a second mask layer 166 over the first mask layer 164, and a photoresist layer 168 over the second mask layer 166. In some embodiments, the first mask layer 164 is made of titanium nitride (TiN), carbon-doped silicon dioxide (e.g., SiO2:C), titanium oxide (TiO), boron nitride (BN), or the like. In some embodiments, the second mask layer 166 is made of silicon nitride (SiN), silicon oxynitride (SiON), or the like.

After the mask structure 160 is formed, an etching process 172 is performed to form trenches 170-1 and 170-2, in the dummy gate electrodes 124, and then the mask structure 160 is removed, as shown in FIGS. 2M-1, 2M-2, 2M-3, 2M-4, 2M-5, 2M-6, 2M-7, and 2M-8 in accordance with some embodiments. More specifically, during the etching process 172, the portions of the dummy gate electrodes 124 exposed by the openings 162 are etched, so that the dielectric layers 122 are partially exposed by the trenches 170-1 and 170-2 in accordance with some embodiments. In addition, the trench 170-1 is located between the fin structures 104-1 and 104-2 in the first region 10 and is laterally spaced apart from the fin structures 104-1 and 104-2 in accordance with some embodiments. Similarly, the trench 170-2 is located between the fin structures 104-3 and 104-4 in the second region 20 and is laterally spaced apart from the fin structures 104-3 and 104-4 in accordance with some embodiments. The etching process 172 may be a wet etching process or a dry etching process. The mask structure 160 may be removed after the etching process is performed.

As described previously, the widths of the openings 162 are smaller than the distances between the neighboring fin structures 104, and therefore the width of the trench 170-1 is smaller than the distances between a sidewall 105-1 of the fin structure 104-1 and a sidewall 105-2 of the fin structure 104-2, as shown in FIG. 2M-1 in accordance with some embodiments. Similarly, the width of the trench 170-2 is smaller than the distances between a sidewall 105-3 of the fin structure 104-3 and a sidewall 105-4 of the fin structure 104-4, as shown in FIG. 2M-2 in accordance with some embodiments. Therefore, the trenches 170-1 and 170-2 can be formed between two neighboring fin structures 104 without exposing the fin structures 104. Therefore, the risk of damaging the fin structures 104 during the etching process 172 for forming the trenches 170-1 and 170-2 can be reduced.

In some embodiments, the shortest distance D₁ between the sidewall of the trench 170-1/170-2 and the closest sidewall (e.g. the sidewalls 105-1, 105-2, 105-3, and 105-4) of the fin structure 104 is in a range from about 8 nm to about 14 nm. In some embodiments, portions of the dummy gate electrodes 124 remain at opposite sidewalls of each of the fin structures 104.

After the trenches 170-1 and 170-2 are formed, a trimming process 174 is performed to enlarge the widths of the trenches 170-1 and 170-2, and the resulting structure is shown in FIGS. 2N-1, 2N-2, 2N-3, 2N-4, 2N-5, 2N-6, 2N-7, and 2N-8 in accordance with some embodiments. As described above, before the trimming process 174 is performed, the widths of the trenches 170-1 and 170-2 are smaller than the distances between two neighboring fin structures 104, so that the damage of the fin structures 104 during the etching process 172 may be avoided. Next, the sizes of the trenches 170-1 and 170-2 are adjusted (i.e. enlarged) to make sure that the dummy gate electrodes 124 laterally sandwiched between the sidewalls of the neighboring fin structures 104 are completely removed by performing the trimming process 174, as shown in FIGS. 2N-1, 2N-2, 2N-7, and 2N-8 in accordance with some embodiments.

More specifically, the sidewalls portions of the dummy gate electrodes 124 exposed by the trenches 170-1 and 170-2 are partially removed (e.g. etched), so that enlarged trenches 170-1′ and 170-2′ are formed in accordance with some embodiments. The trimming process 174 may be an etching process, such as a dry etching process, a wet etching process, or a combination thereof. In some embodiments, the etching selectivity between the dielectric layer 122 and the dummy gate electrode 124 in the trimming process 174 is greater than the etching selectivity between the dielectric layer 122 and the dummy gate electrode 124 in the etching process 172, so that the fin structures 104 can be protected by the dielectric layers 122 during the trimming process 174, and the risk of damaging the fin structures 104 may be prevented.

Each of the enlarged trenches 170-1′ and 170-2′ has a top portion 170′T and a bottom portion 170′B under the top portion 170′T, and the top portion 170′T is wider than the bottom portion 170′B, as shown in FIGS. 2N-1, 2N-2, 2N-7, and 2N-8 in accordance with some embodiments.

In some embodiments, the top portion 170′T of the enlarged trench 107-1′ vertically overlaps the sidewall 105-1 of the fin structure 104-1 and the sidewall 105-2 of the fin structure 104-2. In some embodiments, the top portion 170′T of the enlarged trench 107-2′ vertically overlaps the sidewall 105-3 of the fin structure 104-3 and the sidewall 105-4 of the fin structure 104-4. In some embodiments, the top portion 170′T of the enlarged trench 107-1′ also overlaps the top surfaces of the fin structure 104-1 and the fin structure 104-2. In some embodiments, the top portion 170′T of the enlarged trench 107-2′ also overlaps the top surfaces of the fin structure 104-3 and the fin structure 104-4. In some embodiments, the distance D2 between the sidewall (e.g. the sidewalls 105-1, 105-2, 105-3, and 105-4) and the closest sidewall of the top portion 170′T over the fin structure 104 (e.g. the fin structures 104-1, 104-2, 104-3, and 104-4) is less than about 4 nm.

In addition, the portion of the dummy gate electrodes 124 laterally sandwiched between the sidewall 105-1 of the fin structure 104-1 and the sidewall 105-2 of the fin structure 104-2 and the portion of the dummy gate electrodes 124 laterally sandwiched between the sidewall 105-3 of the fin structure 104-3 and the sidewall 105-4 of the fin structure 104-4 are completely removed during the trimming process 174 in accordance with some embodiments.

Furthermore, the top portions of the dummy gate electrodes 124 are also partially removed during the trimming process 174 in accordance with some embodiments. Accordingly, the height H₁ of the dummy gate electrode 124 is lower than the height H₂ of the gate spacers 134 after the trimming process 174 is performed, as shown in FIGS. 2N-3, 2N-4, 2N-7, and 2N-8 in accordance with some embodiments.

After the enlarged trenches 170-1′ and 170-2′ are formed, isolation features 176-1 and 176-2 are formed in the enlarged trenches 170-1′ and 170-2′, respectively, and the resulting structure is shown in FIG. 2O-1, 2O-2, 2O-3, 2O-4, 2O-5, 2O-6, 2O-7, and 2O-8 in accordance with some embodiments. Since the isolation features 176-1 and 176-2 are formed in the enlarged trenches 170-1′ and 170-2′, the isolation features 176-1 and 176-2 include top portions 176T and bottom portions 176B that are narrower than the top portions 176T in accordance with some embodiments.

In some embodiments, the top portion 176T of the isolation feature 176-1 partially overlaps the fin structure 104-1 and 104-2, and the bottom portion 176B of the isolation feature 176-1 is laterally sandwiched between the fin structures 104-1 and 104-2 in accordance with some embodiments. In some embodiments, the top portion 176T of the isolation feature 176-2 partially overlaps the fin structure 104-3 and 104-4, and the bottom portion 176B of the isolation feature 176-2 is laterally sandwiched between the fin structures 104-3 and 104-4 in accordance with some embodiments. In some embodiments, the widths W₃ of the top portions 176T of the isolation features 176-1 and 176-2 are greater than the distance between the fin structures 104-1 and 104-2 and the distance between the fin structures 104-3 and 104-4.

The isolation features 176-1 and 176-2 may include multiple isolation materials. In some embodiments, the isolation feature 176-1 includes a shell layer 178-1 and a core material 180-1 surrounded by the shell layer 178-1. Similarly, the isolation feature 176-2 includes a shell layer 178-2 and a core material 180-2 surrounded by the shell layer 178-2 in accordance with some embodiments. The formation of the isolation features 176-1 and 176-2 may include forming the shell layers 178-1 and 178-2 lining the enlarged trenches 170-1′ and 170-2′, the dummy gate electrode 124, the gate spacers 134, the contact etch stop layer 154, and the mask layer 158, and then forming core materials 180-1 and 180-2 over the shell layers 178-1 and 178-2. After the core materials 180-1 and 180-2 are formed, a polishing process may be performed to remove the core materials 180-1 and 180-2 and the shell layers 178-1 and 178-2 over the dummy gate electrode 124, the gate spacers 134, the contact etch stop layer 154, and the mask layer 158, so that the isolation features 176-1 and 176-2 may be formed in the enlarged trenches 170-1′ and 170-2′. In addition, during the polishing process (e.g. CMP process), the top portions of the dummy gate electrode 124, the gate spacers 134, the contact etch stop layer 154, and the mask layer 158 are also partially removed in accordance with some embodiments. Therefore, the height H₃ of the dummy gate electrode 124 after the isolation features 176-1 and 176-2 are formed shown in FIG. 2O-1 and 2O-2 is smaller than the height H₁ of the dummy gate electrode 124 before the isolation features 176-1 and 176-2 are formed shown in FIGS. 2N-1 and 2N-2 in accordance with some embodiments. In addition, the isolation features 176-1and 176-2 also have the height H₃ in accordance with some embodiments.

In some embodiments, each of the shell layers 178-1 and 178-2 has a thickness in a range from about 1 nm to about 2 nm. The thickness of the shell layers 178-1 and 178-2 may decide the size and shapes of the extending portions formed afterwards (the details will be described later). In some embodiments, the shell layers 178-1 and 178-2 are made of a dielectric material that is formed under a relatively low temperature (e.g. less than 550 °C). In some embodiments, the shell layers 178-1 and 178-2 are made of SiN formed under low temperature (e.g. about 500 °C). In some embodiments, the core materials 180-1 and 180-2 are made of oxide formed under low temperature. In some embodiments, the core materials 180-1 and 180-2 are made of a dielectric material that is formed under a relatively high temperature (e.g. more than 550 °C). In some embodiments, the core materials 180-1 and 180-2 are made of SiN or SiCN formed under high temperature. In some embodiments, the shell layers 178-1 and 178-2 and the core materials 180-1 and 180-2 are made of SiN formed under different temperature. The shell layers 178-1 and 178-2 may be removed (e.g. etched) more easily than the core materials 180-1 and 180-2 in subsequent processes.

After the isolation features 176-1 and 176-2 are formed, the dummy gate electrodes 124 are removed to form gate trenches 182, and the resulting structure is shown in FIGS. 2P-1, 2P-2, 2P-3, 2P-4, 2P-5, 2P-6, 2P-7, and 2P-8 in accordance with some embodiments. The removal process may include one or more etching processes. For example, when the dummy gate electrodes 124 are made of polysilicon, a wet etchant such as a tetramethylammonium hydroxide (TMAH) solution may be used to selectively remove the dummy gate electrodes 124. As shown in FIGS. 2P-1, 2P-2, 2P-7, and 2P-8, the portions of the dielectric layers 122 not covered by the isolation features 176-1 and 176-2 are exposed by the gate trenches 182 in accordance with some embodiments.

After the dummy gate electrodes 124 are removed, a trimming process 184 is performed to narrow down the top portions of the isolation features 176-1 and 176-2, and the resulting structure is shown in FIGS. 2Q-1, 2Q-2, 2Q-3, 2Q-4, 2Q-5, 2Q-6, 2Q-7, and 2Q-8 in accordance with some embodiments. More specifically, the trimming process 184 is configured to reduce the widths of the top portions of the isolation features 176-1 and 176-2, so that the gate structures formed afterwards can have larger top widths, and therefore there will be more spaces for contacts formed afterwards to land onto the gate structures. In some embodiments, the trimming process 184 is a dry etching process, a wet etching process, or a combination thereof.

During the trimming process 184, the isolation features 176-1 and 176-2 are laterally etched from the sidewalls exposed by the gate trenches 182 and are vertically etched from the top surfaces, so that isolation features 176-1″ and 176-2″ (including shell layers 178-1″ and 178-2″ and core materials 180-1′ and 180-2′) with smaller top widths are formed in accordance with some embodiments. Each of the isolation features 176-1″ and 176-2″ has a top portion 176T′ and a bottom portion 176B′, and the bottom portion 176B′ is wider than the top portion 176T′ in accordance with some embodiments. In some embodiments, the top portions 176T′ of the isolation features 176-1″ and 176-2″ have the widths W₄, and the width W₄ of the of the top portion 176T′ is smaller than the width W₃ of the top portion 176T shown in FIGS. 2P-1 and 2P-2. In addition, a difference between the width W₄ and the width W₃ is in a range from about 15 nm to about 24 nm. The width W₄ is relatively small, so that there will be more space for forming contacts in subsequent processes. In some embodiments, the top portions 176T′ of the isolation features 176-1″ and 176-2″ have curved sidewalls, as shown in FIGS. 2Q-1 and 2Q-2.

As shown in FIGS. 2Q-1, 2Q-2, 2Q-7, and 2Q-8, the top surfaces of the fin structures 104 are not covered by the isolation features 176-1″ and 176-2″ in accordance with some embodiments. As shown in FIGS. 2Q-1, 2Q-2, 2Q-7, and 2Q-8, the upper portions of the shell layers 178-1 and 178-2 are removed, so that the resulting shell layers 178-1″ and 178-2″ surround the bottom portions of the core materials 180-1′ and 180-2′ but not the top portions of the core materials 180-1′ and 180-2′ in accordance with some embodiments. In some embodiments, the top surfaces of the shell layers 178-1″ and 178-2″ are lower than the top surfaces of the topmost ones of the second semiconductor material layers 108.

In addition, since the isolation features 176-1 and 176-2 are also etched from their top surfaces during the trimming process 184, the top surfaces of the isolation features 176-1″ and 176-2″ are lower than the top surfaces of the gate spacers 134, as shown in FIGS. 2Q-7 and 2Q-8 in accordance with some embodiments. In some embodiments, a height difference D₃ of the isolation features 176-1″ and 176-2″ and the gate spacers 134 is in a range from about 7 nm to about 12 nm. In some embodiments, the height H₄ of the isolation features 176-1″ and 176-2″ shown in FIGS. 2Q-1 and 2Q-2 is less than the height H₃ of the isolation features 176-1 and 176-2 shown in FIGS. 2P-1 and 2P-2. In some embodiments, the height difference D₄ between the isolation features 176-1″ and 176-2″ and the fin structures 104-1, 104-2, 104-3, and 104-4, as shown in FIGS. 2Q-1 and 2Q-2, is in a range of about 20 nm to about 28 nm. The height difference D₄ may be substantially equal to the height of the gate structures formed over the channel regions formed in subsequent processes, and therefore the height difference D₄ should not be too small, or the gate structures formed afterwards may not have enough height.

After the trimming process 184 is performed, and an etching process 186 is performed to etch the dielectric layers 122, the cap layers 120, and the dielectric sacrificial features 144, and the resulting structure is shown in FIGS. 2R-1, 2R-2, 2R-3, 2R-4, 2R-5, 2R-6, 2R-7, and 2R-8 in accordance with some embodiments. More specifically, the dielectric layers 122 and the cap layers 120 exposed by the gate trenches 182 are removed, so that the sidewalls of the dielectric sacrificial features 144 are exposed by the gate trenches 182 during the etching process 186 in accordance with some embodiments. Then, the dielectric sacrificial features 144 are etched from their exposed sidewalls, until the dielectric sacrificial features 144 are completely removed to form gate gaps 188. The second semiconductor material layers 108 of the fin structures 104-1, 104-2, 104-3, and 104-4 can then be served as channel layers 108-1′, 108-2′, 108-3′, and 108-4′, as shown in FIGS. 2R-1, 2R-2, 2R-3, 2R-4, 2R-7, and 2R-8 in accordance with some embodiments. In some embodiments, the channel layers 108-1′, 108-2′, 108-3′, and 108-4′ are vertically suspended over the substrate 102 and spaced apart from each other by the gate gaps 188 in Z direction in accordance with some embodiments. In addition, the channel layers 108-1′, 108-2′, 108-3′, and 108-4′ laterally extend between and interposing the source/drain structures 152 respectively in X direction in accordance with some embodiments.

In addition, since the fin structures 104-1, 104-2, 104-3, and 104-4 in the first region 10 and the second region 20 have different widths, the dielectric sacrificial features 144 in the first region 10 and the second region 20 also have different widths, resulting in different structures after the etching process 186 is performed.

More specifically, in the second region 20, the dielectric sacrificial features 144 have smaller widths, and therefore the dielectric sacrificial features 144 in the second region 20 will be removed faster than the dielectric sacrificial features 144 in the first region 10. After the dielectric sacrificial features 144, the etchant may further etch through the shell layer 178-2″ and reach the dielectric layers 122, and the cap layer 120. Accordingly, in the second region 20, the shell layer 178-2″, the dielectric layers 122, and the cap layer 120 on sidewalls of the core material 180-2 are also etched and removed during the etching process 186, as shown in FIGS. 2R-2 and 2R-8 in accordance with some embodiments. After the etching process 186 is performed, an isolation feature 176-2″ is formed, and the isolation feature 176-2″ includes the core material 180-2′ and a shell layer 178-2″ under the bottom surface of the core material 180-2′ in accordance with some embodiments. In addition, portions of the dielectric layer 122 and the cap layer 120 remain under the isolation feature 176-2″ and are vertically sandwiched between the isolation feature 176-2″ and the isolation structure 116 in accordance with some embodiments.

On the other hand, in the first region 10, the dielectric sacrificial features 144 have greater widths, and therefore it will take more time to remove the dielectric sacrificial features 144 in the first region 10. Accordingly, the shell layers 178-1″, the dielectric layers 122, and the cap layer 120 on sidewalls of the core material 180-1′ are only partially etched during the etching process 186, as shown in FIGS. 2R-1 and 2R-7 in accordance with some embodiments. That is, the dielectric layer 122, the cap layer 120, and the shell layer 178-1″ laterally sandwiched between the channel layers 108-1′ and 108-2′ and the core material 180-1′ are not completely removed during the etching process 186 in accordance with some embodiments. After the etching process 186 is performed, an isolation feature 176-1″ is formed, and the isolation feature 176-1″ includes the core material 180-1″ and the shell layer 178-1″ at the sidewalls and the bottom surface of the bottom portion of the core material 180-1″ in accordance with some embodiments.

In addition, extending portions 123 are formed of the dielectric layer 122, and the extending portions 123 laterally extending to the channel layers 108-1′ and 108-2′ in accordance with some embodiments. In some embodiments, portions of the cap layer 120 remain between the extending portions 123 and the channel layers 108-1′ and 108-2′. In some embodiments, portions of the dielectric layer 122 and the cap layer 120 remain under the isolation feature 176-1″ and are vertically sandwiched between the isolation feature 176-1″ and the isolation structure 116 in accordance with some embodiments. Furthermore, a portion of the shell layer 178-1″ is vertically sandwiched between the core material 180-1″ and the dielectric layer 122 and some portions of the shell layer 178-1″ are laterally sandwiched between the core material 180-1″ and the extending portions 123 in accordance with some embodiments. The profile of extending portions 123 and core material 180-1″ may be better controlled due to the shell layer 178-1″.

Furthermore, since the isolation features 176-1″ and 176-2″ have narrower top portions, during the etching process 186, the topmost ones of the channel layers 108-1′, 108-2′, 108-3′, 108-4′ are etched from their opposite sidewalls and their top surfaces after the dielectric layer 122 and the cap layer 120 are removed. Therefore, the topmost ones of the channel layers 108-1′, 108-2′, 108-3′, 108-4′ may be etched more than those channel layers under them in accordance with some embodiments.

In some embodiments, the channel layers 108-1′ includes a topmost channel layer 108-1′_T, a middle channel layer 108-1′_M under the topmost channel layer 108-1′_T, and a bottommost channel layer 108-1′_B under the middle channel layer 108-1′_M. In addition, the width of the topmost channel layer 108-1′_T is smaller than the width of the middle channel layer 108-1′_M and the width of the bottommost channel layer 108-1′_B in accordance with some embodiments. In addition, the extending portions 123 are formed between the isolation feature 176-1″ and the channel layers 108-1′_M and 180-1′_B but not between the isolation feature 176-1″ and the channel layers 108-1′_T.

Similarly, the channel layers 108-2′ includes a topmost channel layer 108-22′_T, a middle channel layer 108-2′_M under the topmost channel layer 108-2′_T, and a bottommost channel layer 108-2′_B under the middle channel layer 108-2′_M in accordance with some embodiments. In addition, the width of the topmost channel layer 108-2′_T is smaller than the width of the middle channel layer 108-2′_M and the width of the bottommost channel layer 108-2′_B in accordance with some embodiments. In addition, the extending portions 123 are formed between the isolation feature 176-1″ and the channel layers 108-2′_M and 180-2′_B but not between the isolation feature 176-1″ and the channel layers 108-2′_T.

The channel layers 108-3′ includes a topmost channel layer 108-3′_T, a middle channel layer 108-3′_M under the topmost channel layer 108-3′_T, and a bottommost channel layer 108-3′_B under the middle channel layer 108-3′_M in accordance with some embodiments. In addition, the width of the topmost channel layer 108-3′_T is smaller than the width of the middle channel layer 108-3′_M and the width of the bottommost channel layer 108-3′_B in accordance with some embodiments. The channel layers 108-4′ includes a topmost channel layer 108-4′_T, a middle channel layer 108-4′_M under the topmost channel layer 108-4′_T, and a bottommost channel layer 108-4′_B under the middle channel layer 108-4′_M in accordance with some embodiments. In addition, the width of the topmost channel layer 108-4′_T is smaller than the width of the middle channel layer 108-4′_M and the width of the bottommost channel layer 108-4′_B in accordance with some embodiments. As shown in FIGS. 2R-1 and 2R-2, the topmost channel layers 108-1′_T, 108-2′_T, 108-3′_T, and 108-4′_T have rounded corners.

The etching process 186 may include one or more etching processes. For example, the etching process 186 may include a plasma dry etching, a dry chemical etching, and/or a wet etching. As described previously, since the dielectric sacrificial features 144 and the second semiconductor material layers 108 have relatively high etching selectivity (e.g. compare to the first semiconductor material layers 106 and the second semiconductor material layers 108), the dielectric sacrificial features 144 may be fully removed without removing the second semiconductor material layers 108 too much.

Next, gate structures 190, including 190-1, 190-2, 190-3, and 190-4, are formed the gate trenches 182 and the gate gaps 188, and the resulting structure is shown in FIGS. 2S-1, 2S-2, 2S-3, 2S-4, 2S-5, 2S-6, 2S-7, and 2S-8 in accordance with some embodiments. In some embodiments, the gate structures 190 wrap around the channel layers 108-1′, 108-2′, 108-3′, and 108-4′ and extends lengthwise in Y direction.

In addition, the gate structures 190-1 and 190-2 are separated by the isolation feature 176-1″, and the gate structures 190-3 and 190-4 are separated by the isolation feature 176-2″. Since the isolation features 176-1″ and 176-2″ are configured to isolate the neighboring gate structures 190, the top surfaces of the gate structures 190 are substantially level with the top surfaces of the isolation features 176-1″ and 176-2″ in accordance with some embodiments. Therefore, although the isolation features 176-1″ and 176-2″ have narrow top portions by performing the trimming process 186, the height of the isolation features 176-1″ and 176-2″ should not be too small, or the gate structures 190 may also need to have relatively small heights. In some embodiments, the height H₅ of the gate structures 190 over the topmost channel layers (i.e. channel layers 108-1′_T, 108-2′_T, 108-3′_T, and 108-4′_T) is in a range from about 13 nm to about 15 nm (i.e. the distance between the top surface of the gate structures 190 and the top surfaces of the channel layers 108-1′_T, 108-2′_T, 108-3′_T, and 108-4′_T).

In some embodiments, the gate structures 190 include top portion formed between the gate spacers 134 and inner portions formed between the inner spacers 150. In some embodiments, the width W_{MGT} of the top portions formed between the gate spacers 134 is in a range from about 15 nm to about 17 nm. In some embodiments, the width W_{MGB} of the inner portions formed between the inner spacers 150 is in a range from about 15 nm to about 17 nm. As shown in FIG. 2S-1, the top surface of the base structure 104B is higher than the top surface of the isolation structure 116, and therefore the interface between the gate structure 190 and the base structure 104B is higher than the interface between the gate structure 190 and the isolation structure 116 in accordance with some embodiments. In some embodiments, the height difference between the interface between the gate structure 190 and the base structure 104B and the interface between the gate structure 190 and the isolation structure 116 is in a range from about 4 nm to about 12 nm.

In some embodiments, each of the gate structures 190 includes an interfacial layer 192, a gate dielectric layer 194, and a gate electrode layer 196. The interfacial layer 192 may be used to improve the interfaces between the channel layers 108-1′, 108-2′, 108-3′, and 108-4′ and dielectric layers formed afterwards. In addition, the interfacial layer 192 may be able to help suppressing the mobility degradation of charge carries in the channel layers 108-1′, 108-2′, 108-3′, and 108-4′ that serve as channel regions of the transistors. In some embodiments, the interfacial layer 192 is an oxide layer formed by performing a thermal process. In some embodiments, portions of the cap layer 120 are oxidized to form the interfacial layer 192. In some embodiments, the interfacial layer 192 has a thickness in a range from about 0.5 nm to about 1.5 nm.

After the interfacial layer 192 is formed, the gate dielectric layer 194 is conformally formed to cover the interfacial layers 192 and the bottom surface and the sidewalls of the gate trenches 182 and the gate gaps 188 in accordance with some embodiments. In addition, the gate dielectric layer 194 covers sidewalls of the core materials 180-1′ and 180-2′, the shell layers 178-1″ and 178-2″, and the extending portions 123 in accordance with some embodiments. In some embodiments, the gate dielectric layer 194 also covers (e.g. interface) the dielectric layer 122 and the cap layer 120 under the isolation features 176-1″ and 176-2″.

In some embodiments, the gate dielectric layer 194 is made of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, La₂O₃—Al₂O₃ or LaO, other applicable high-k dielectric materials, or a combination thereof. In some embodiments, the gate dielectric layer 194 is formed using CVD, ALD, other applicable methods, or a combination thereof. In some embodiments, the gate dielectric layer 194 has a thickness in a range from about 1 nm to about 2 nm.

After the gate dielectric layer 194 is formed, the gate electrode layer 196 is formed over the gate dielectric layer 194 in accordance with some embodiments. In some embodiments, the gate electrode layer 196 includes multiple layers. In some embodiments, the gate electrode layer 196 includes one or more work function metal layers. In some embodiments, the work function metal layers are made of titanium nitride, tantalum nitride, tungsten nitride, tantalum, or the like. In some embodiments, the gate electrode layer 196 includes a gate filling layer formed over the work functional layers. In some embodiments, the gate filling layer is made of a conductive material, such as tungsten, titanium, tantalum, cobalt, copper, ruthenium, or the like. In some embodiments, the gate filling layer is formed using CVD, ALD, electroplating, another applicable method, or a combination thereof.

In some embodiments, a polishing process, such as a CMP process, is performed after depositing the gate dielectric layer 194 and the gate electrode layer 196 to remove excessing gate dielectric layer 194 and the gate electrode layer 196 over the isolation features 176-1″ and 176-2″, the gate spacers 134, the contact etch stop layer 154, and the mask layer 158. In addition, the polishing process may be performed until exposing the top surfaces of the isolation features 176-1″ and 176-2″, so that the top portions of the gate spacers 134, the contact etch stop layer 154 are partially removed and the mask layers 158 are completely removed during the polishing process.

Although not clearly shown in the figures, the gate structures 190-1 and 190-2 may include different material layers (e.g. different work function metal layers) and the gate structures 190-3 and 190-4 may include different material layers (e.g. different work function metal layers). In addition, the gate structures 190-1 and 190-2 are electrically isolated from each other by the isolation feature 176-1″, and the gate structures 190-3 and 190-4 are electrically isolated from each other by the isolation feature 176-2″ in accordance with some embodiments. In some embodiments, the gate structure 190-2 is spaced apart from gate structure 190-1 with a first distance. The gate structure 190-3 is spaced apart from gate structure 190-4 with a second distance. The first distance can be different from the second distance.

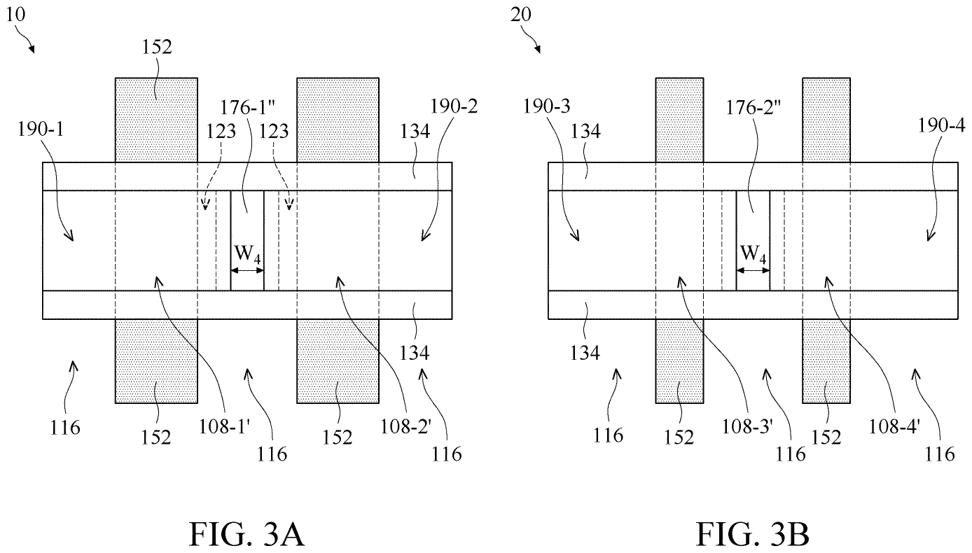

Next, an etch stop layer 200 and a dielectric layer 202 are formed over the gate structures 190, the gate spacers 134, the contact etch stop layer 154, and the interlayer dielectric layer 156, and contacts 204 and 206 are formed to connect to the gate structures 190 and the source/drain structures 152, respectively, in accordance with some embodiments. The resulting semiconductor structure 100 is shown in FIGS. 2T-1, 2T-2, 2T-3, 2T-4, 2T-5, 2T-6, 2T-7, and 2T-8 in accordance with some embodiments. FIGS. 3A and 3B illustrate layout of the semiconductor structure 100 in the first region 10 and the second region 20, respectively, in accordance with some embodiments.

More specifically, the etch stop layer 200 is formed over the gate structures 190 and the isolation features 176-1″ and 176-2″, as shown in FIGS. 2T-1 and 2T-2 in accordance with some embodiments. In addition, the etch stop layer 200 is also formed over the gate spacer 134, the contact etch stop layer 154, and the interlayer dielectric layer 156, as shown in FIGS. 2T-3, 2T-4, 2T-5, 2T-6, 2T-7, and 2T-8 in accordance with some embodiments. After the etch stop layer 200 is formed, the dielectric layer 202 is formed over the etch stop layer 200 in accordance with some embodiments.

In some embodiments, the etch stop layer 200 is made of a dielectric material, such as silicon nitride, silicon oxide, silicon oxynitride, another suitable dielectric material, or a combination thereof. The dielectric material for the etch stop layers 200 may be conformally deposited over the semiconductor structure by performing CVD, ALD, other application methods, or a combination thereof. The dielectric layer 202 may include multilayers made of multiple dielectric materials, such as silicon oxide, silicon nitride, silicon oxynitride, phosphosilicate glass (PSG), borophosphosilicate glass (BPSG), or other applicable low-k dielectric materials. The dielectric layer 202 may be formed by chemical vapor deposition (CVD), physical vapor deposition, (PVD), atomic layer deposition (ALD), or other applicable processes.

After the etch stop layer 200 and the dielectric layer 202 are formed, the contacts 204 are formed over the gate structures 190 and the contacts 206 are formed over the source/drain structures 152, as shown in FIGS. 2T-1, 2T-2, 2T-3, 2T-4, 2T-5, 2T-6, 2T-7, 2T-8, 3A, and 3B in accordance with some embodiments. More specifically, the contacts 204 are formed through the etch stop layer 200 and the dielectric layer 202 and land on the top surface of the gate structures 190-1 and 190-4, as shown in FIGS. 2T-1, 2T-2, 2T-7, and 2T-8 in accordance with some embodiments. As described previously, since the isolation features 176-1″ and 176-2″ have narrower top portions, the gate structures 190 can have a wider top portion. Therefore, the contacts 204 can have a larger formation window over the gate structures 190.

The formation of the contacts 204 may include forming contact trenches through the etch stop layer 200 and the dielectric layer 202 to partially expose the gate structures 190 (i.e. the gate structures 190-1 and 190-4) and then forming the contacts 204 in the contact trenches over the top surface of the gate structures 190. In some embodiments, the contacts 204 are made of a conductive material including aluminum (Al), copper (Cu), tungsten (W), titanium (Ti), tantalum (Ta), titanium nitride (TiN), cobalt, tantalum nitride (TaN), nickel silicide (NiS), cobalt silicide (CoSi), copper silicide, tantalum carbide (TaC), tantalum silicide nitride (TaSiN), tantalum carbide nitride (TaCN), titanium aluminide (TiAl), titanium aluminum nitride (TiAlN), other applicable conductive materials, or a combination thereof.

The contacts 204 may further include a liner and/or a barrier layer. For example, a liner (not shown) may be formed on the sidewalls and bottom of the contact trench. The liner may be made of silicon nitride, although any other applicable dielectric may be used as an alternative. The liner may be formed using a plasma enhanced chemical vapor deposition (PECVD) process, although other applicable processes, such as physical vapor deposition or a thermal process, may be used as an alternative. The barrier layer (not shown) may be formed over the liner (if present) and may cover the sidewalls and bottom of the opening. The barrier layer may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes. The barrier layer may be made of tantalum nitride, although other materials, such as tantalum, titanium, titanium nitride, or the like, may also be used.

In some embodiments, the contacts 206 are formed through the dielectric layer 202, the etch stop layer 200, the interlayer dielectric layer 156, and the contact etch stop layer 154 and land on the source/drain structures 152, as shown in FIGS. 2T-3, 2T-4, 2T-5, and 2T-6 in accordance with some embodiments. In addition, silicide layers are formed over the source/drain structures 152 before the contacts 206 are formed in accordance with some embodiments. In some embodiments, at least one of the contacts 206 has a width (in Y direction) greater than a width of the source/drain structure 152 thereunder, as shown in FIGS. 2T-5 and 2T-6.

The contacts 206 may be formed by forming contact trenches through the dielectric layer 202, the etch stop layer 200, the interlayer dielectric layer 156, and the contact etch stop layer 154 to expose the source/drain structures 152. Afterwards, the silicide layers 205 may be formed over the exposed portions of the source/drain structures 152, and the contacts 206 may be formed in the contact trenches over the silicide layers 205. The silicide layers 205 may be formed by forming a metal layer over the top surface of the source/drain structures 152 and annealing the metal layer so the metal layer reacts with the source/drain structures 152 to form the silicide layers 205. The unreacted metal layer may be removed after the silicide layers 205 are formed.

In some embodiments, the contacts 206 are made of a conductive material including aluminum (Al), copper (Cu), tungsten (W), titanium (Ti), tantalum (Ta), titanium nitride (TiN), cobalt, tantalum nitride (TaN), nickel silicide (NiS), cobalt silicide (CoSi), copper silicide, tantalum carbide (TaC), tantalum silicide nitride (TaSiN), tantalum carbide nitride (TaCN), titanium aluminide (TiAl), titanium aluminum nitride (TiAlN), other applicable conductive materials, or a combination thereof.

The contacts 206 may further include a liner and/or a barrier layer. For example, a liner (not shown) may be formed on the sidewalls and bottom of the contact trench. The liner may be made of silicon nitride, although any other applicable dielectric may be used as an alternative. The liner may be formed using a plasma enhanced chemical vapor deposition (PECVD) process, although other applicable processes, such as physical vapor deposition or a thermal process, may be used as an alternative. The barrier layer (not shown) may be formed over the liner (if present) and may cover the sidewalls and bottom of the opening. The barrier layer may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes. The barrier layer may be made of tantalum nitride, although other materials, such as tantalum, titanium, titanium nitride, or the like, may also be used.

As described above, the semiconductor structure 100 includes the first region 10 and the second region 20, and the fin structures 104-1 and 104-2 in the first region 10 are wider than the fin structure 104-3 and 104-4 in the second region 20 in accordance with some embodiments. In addition, the gate structures 190 are formed around the fin structures 104 and isolation features 176-1″ and 176-2″ are formed to isolation the gate structures 190. Furthermore, since the sizes and shapes of the isolation features 176-1″ and 176-2″ are formed and adjusted by performing multiple etching and trimming processes, the resulting isolation features 176-1″ and 176-2″ can be incorporated into various layouts and application. In addition, the isolation features 176-1″ and 176-2″ can have narrower top widths and wider bottom widths as designed in accordance with some embodiments. In some embodiments, the isolation features 176-1″ and 176-2″ have curved sidewalls.

In the first region 10, the semiconductor structure 100 includes channel layers 108-1′ and 108-2′, the gate structures 190-1 and 190-2 wrapping around the channel layers 108-1′ and 108-2′, and the isolation feature 176-1″ separating the gate structure 190-1 and 190-2, as shown in FIGS. 2T-1, 2T-3, 2T-5, 2T-7, and 3A in accordance with some embodiments. In some embodiments, the interface between the isolation feature 176-1″ and the gate structures 190-1 and 190-2 have curved profiles.

In addition, the width W₄ of the top surface of the core material 180-1′ of the isolation feature 176-1″ is smaller than the width W₅ of the bottom surface of the core material 180-1′, as shown in FIG. 2T-1 in accordance with some embodiments. In some embodiments, the difference between the distance D₅ between the channel layers 108-1′_T and 108-2′_T and the width W₄ of the top surface of the core material 180-1′ of the isolation feature 176-1″ is in a range from about 15 nm to about 25 nm. That is, the width W₄ of the top surface of the core material 180-1′ of the isolation feature 176-1″ is much smaller than the distance D₅ between the channel layers 108-1′_T and 108-2′_T, and therefore there will be more space to form the contacts 204 over the gate structures 190 in accordance with some embodiments. In some embodiments, the distance D₅ between the channel layers 108-1′_T and 108-2′_T is in a range from about 35 nm to about 45 nm. In some embodiments, the channel layers 108-1′_T and 108-2′_T are separated from the isolation feature 176-1″ by the gate structures 190-1 and 190-2, respectively.

Furthermore, the width of the channel layer 108-1′_T is smaller than the width of the channel layers 108-1′_M and 108-1′_B, and therefore the distance between the channel layer 108-1′_T (i.e. the topmost one of the channel layers 108-1′) and the sidewall of the isolation feature 176-1″ is greater than the distance between the channel layer 108-1′_M and 108-1′B (i.e. the middle one and the bottommost one of the channel layers 108-1′) and the sidewall of the isolation feature 176-1″ in accordance with some embodiments. In some embodiments, the distance between the channel layer 108-1′_T and the sidewall of the isolation feature 176-1″ facing the channel layer 108-1′_T in the Y direction is greater than the distance between the channel layer 108-1′_B and the sidewall of the isolation feature 176-1″ facing the channel layer 108-1′_B in Y direction.

The structures of channel layers 108-2′ may be the same as, or similar to, the channel layers 108-1′ described above and are not repeated herein.

FIG. 2T-9 illustrates an enlarge cross-sectional view of the semiconductor structure 100 in the region R of FIG. 2T-1 in accordance with some embodiments. As described previously, the extending portions 123 are laterally sandwiched between the sidewalls of the shell layers 178-1″ of the isolation feature 176-1″ and the channel layers 108-1′_M and 108-1′_B. By forming the extending portions 123 connecting the isolation feature 176-1″ and the channel layers 108-1′, the resulting device may have improved Cgd.

In some embodiments, some portions 194P of the gate dielectric layer 194 extend into the shell layer 178-1″ but do not reach the core material 180-1′, as shown in FIG. 2T-9. That is, the portions of the shell layer 178-1″ laterally sandwiched by the portion 194P of gate dielectric layer 194 and the core material 180-1′ is thinner than the portions of the shell layer 178-1″ laterally sandwiched by the extending portions 123 and the core material 180-1′ in accordance with some embodiments. In some embodiments, the portions of the shell layer 178-1″ attached to the extending portions 123 are thicker than the portions of the shell layer 178-1″ attached to the gate dielectric layer 194. In some embodiments, the lateral dimension D₆ of the sidewall of the channel layer 108-1′_B (108-1′_M) and the outer sidewall of the portion 194P of the gate dielectric layer 194 is in a range of about 3 nm to about 4 nm.

In some embodiments, each of the extending portions 123 has curved top surfaces and curved bottom surfaces in a cross-sectional view, as shown in FIG. 2T-9. In addition, the first edge of the curved top surface of the extending portion 123 (i.e. the edge attaching the interfacial layer 192) is lower than the second edge of the curved top surface of the extending portion 123 (i.e. the edge attaching the shell layer 178-1″) in accordance with some embodiments. That is, the thickness of the extending portion 123 gradually increase from the side attaching to the channel layer 108-1′ to the side attaching to the isolation feature 176-1″ in accordance with some embodiments. In addition, the first edge of the curved top surface of the extending portion 123 may be lower than or substantially level with the top surface of the channel layer 108-1′ attached thereto. In some embodiments, the height difference D₇ (e.g. shown in FIG. 2T-9) of the first edge of the curved top surface of the extending portion 123 and the top surface of the channel layer 108-1′ attached thereto is no greater than 1 nm. In some embodiments, the thickness D₈ (e.g. shown in FIG. 2T-9) of the extending portion 123 (e.g. the smallest thickness) is in a range from about 3.8 nm to about 4.5 nm. In some embodiments, the dimension of at least one of the extending portions 123 is smaller than the dimension of the channel layers 108-1′ in Z direction.

By adjusting the shape and the size of the extending portions 123, the DIBL of the resulting device may be reduced. In some embodiments, the top surface of the topmost one of the extending portions 123 is lower than the top surface of the shell layer 178-1″.

In the second region 20, the semiconductor structure 100 includes channel layers 108-3′ and 108-4′, the gate structures 190-3 and 190-4 wrapping around the channel layers 108-3′ and 108-4′, and the isolation feature 176-2″ separating the gate structure 190-3 and 190-4, as shown in FIGS. 2T-2, 2T-4, 2T-6, 2T-8, and 3B in accordance with some embodiments.

In addition, the width W₄ of the top surface of the core material 180-2″ of the isolation feature 176-2″ is smaller than the width W₅ of the bottom surface of the core material 180-2″, as shown in FIG. 2T-2 in accordance with some embodiments. The width W₄ of the top surface of the core material 180-2″ of the isolation feature 176-2″ is much smaller than the distance D₅ between the channel layers 108-3′_T and 108-4′_T, and therefore there will be more space to form the contacts 204 over the gate structures 190 in accordance with some embodiments. Furthermore, the width of the channel layer 108-3′_T is smaller than the width of the channel layers 108-3′_M and 108-3′_B, and therefore the distance between the channel layer 108-3′_T (i.e. the topmost one of the channel layers 108-3′) and the sidewall of the isolation feature 176-2″ is greater than the distance between the channel layer 108-3′_M and 108-3′B (i.e. the middle one and the bottommost one of the channel layers 108-3′) and the sidewall of the isolation feature 176-2″ in accordance with some embodiments.

As described above, since the channel layers 108-3′ and 108-4′ have relatively small widths, the shell layer 178-2″ and the dielectric layer 122 originally sandwiched between the channel layers 108-3′ and 108-4′ will be removed during the etching process 186. Therefore, extending portions are not formed in the second region 20, and at least four sides of the channel layers 108-3′ and 108-4′ are surrounded by the gate structures 190-3 and 190-4 in accordance with some embodiments.

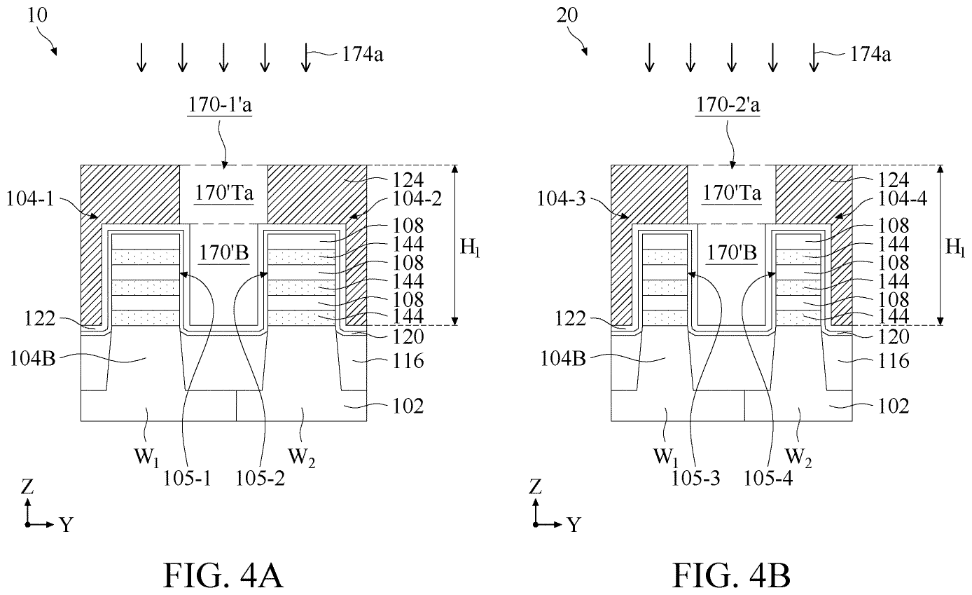

FIGS. 4A and 4B illustrate cross-sectional views of the intermediate stages of manufacturing the semiconductor structure 100 in accordance with some other embodiments. More specifically, the processes shown in FIGS. 1A, 1B, 2A-1 to 2M-1, 2 A-2 to 2M-2, 2A-3 to 2M-3, 2A-4 to 2M-4, 2A-5 to 2M-5, 2A-6 to 2M-6, 2J-7 to 2M-7, and 2J-8 to 2M-8 and described above may be performed to form the trenches 170-1 and 170-2 in the dummy gate electrodes 124, and a trimming process 174a is performed to form enlarged trenches 170-1′a and 170-2′a, as shown in FIGS. 4A and 4B in accordance with some embodiments. The trimming process 174a may be the same as the trimming process 174 described previously, except the sidewalls of top portion 170′Ta of the enlarged trenches 170-1′a and 170-2′a are substantially aligned with the sidewalls of the fin structures 104-1, 104-2, 104-3, and 104-4, respectively, in accordance with some embodiments. After the enlarged trenches 170-1′a and 170-2′a are formed, the processes shown in FIG. 2O-1 to 2T-1, 2O-2 to 2T-2, 2O-3 to 2T-3, 2O-4 to 2T-4, 2O-5 to 2T-5, 2O-6 to 2T-6, 2O-7 to 2T-7, and 2O-8 to 2T-8 and described above may be performed to form the semiconductor structure 100.

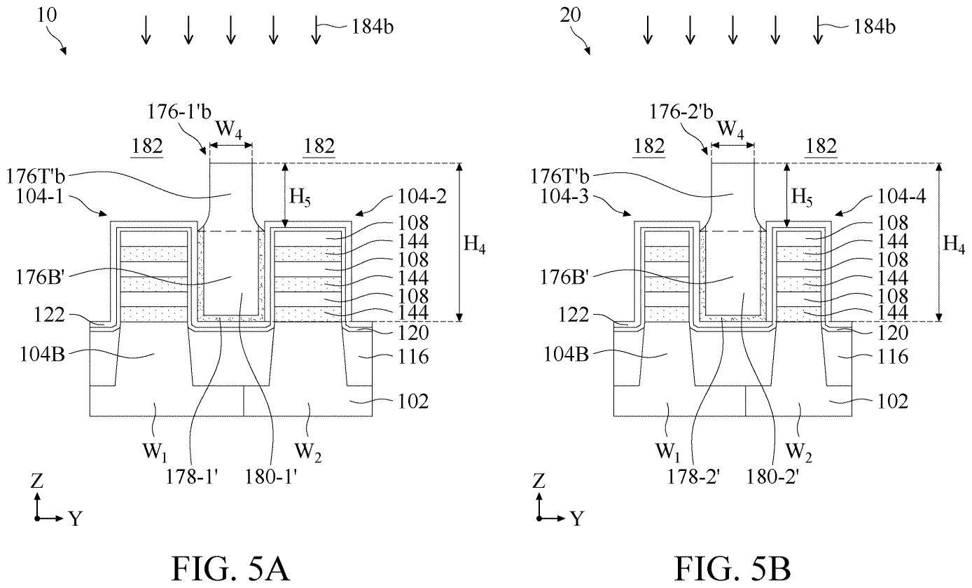

FIGS. 5A and 5B illustrate cross-sectional views of the intermediate stages of manufacturing the semiconductor structure 100 in accordance with some other embodiments. More specifically, the processes shown in FIGS. 1A, 1B, 2A-1 to 2P-1, 2 A-2 to 2P-2, 2A-3 to 2P-3, 2A-4 to 2P-4, 2A-5 to 2P-5, 2A-6 to 2P-6, 2J-7 to 2P-7, and 2J-8 to 2P-8 and described above may be performed to form the isolation features 176-1 and 176-2, and a trimming process 184b is performed to form isolation features 176-1″b and 176-2″b, as shown in FIGS. 5A and 5B in accordance with some embodiments. The trimming process 184b may be the same as, or similar to, the trimming process 184 described previously, except the bottom edges of the sidewalls of top portion 176′Tb of the isolation features 176-1″b and 176-2″b are substantially level with the top surfaces of the fin structures 104-1, 104-2, 104-3, and 104-4 in accordance with some embodiments. After the trimming process 184b is performed, the processes shown in FIGS. 2R-1 to 2T-1, 2R-2 to 2T-2, 2R-3 to 2T-3, 2R-4 to 2T-4, 2R-5 to 2T-5, 2R-6 to 2T-6, 2R-7 to 2T-7, and 2R-8 to 2T-8 and described above may be performed to form the semiconductor structure 100.

FIGS. 6A-1, 6A-2, 6B-1, and 6B-2 illustrate cross-sectional views of intermediate stages of manufacturing a semiconductor structure 100c in accordance with some embodiments. The semiconductor structure 100c may be similar to the semiconductor structure 100 described previously, except its isolation features have greater thicknesses in accordance with some embodiments. Other processes and materials for forming the semiconductor structure 100c may be similar to, or the same as, those for forming the semiconductor structure 100 described previously and are not repeated herein.

More specifically, the processes shown in FIGS. 1A, 1B, 2A-1 to 2L-1, 2 A-2 to 2L-2, 2A-3 to 2L-3, 2A-4 to 2L-4, 2A-5 to 2L-5, 2A-6 to 2L-6, 2J-7 to 2L-7, and 2J-8 to 2L-8 are performed to form the mask structure 160 with the openings 162, and an etching process 172c is performed to form trenches 170-1c and 170-2c, in the dummy gate electrodes 124, and the mask structure 160 is then removed, as shown in FIGS. 6A-1 and 6A-2 in accordance with some embodiments. The trenches 170-1c and 170-2c shown in FIGS. 6A-1 and 6A-2 are similar to the trenches 170-1 and 170-2 shown in FIGS. 2M-1 and 2M-2, except the trenches 170-1c and 170-2c extends through the dielectric layers 122 and the cap layers 120 in accordance with some embodiments. In addition, the trenches 170-1c and 170-2c further extend into the isolation structure 116 in accordance with some embodiments. That is, the bottom surfaces of the trenches 170-1c and 170-2c are lower than the top surface of the isolation structure 116 in accordance with some embodiments.

Afterwards, the processes shown in FIGS. 2N-1 to 2T-1, 2N-2 to 2T-2, 2N-3 to 2T-3, 2N-4 to 2T-4, 2N-5 to 2T-5, 2N-6 to 2T-6, 2N-7 to 2T-7, and 2N-8 to 2T-8 and described above are performed to form the semiconductor structure 100c, as shown in FIGS. 6B-1 and 6B-2 in accordance with some embodiments.

More specifically, the semiconductor structure 100c includes isolation features 176-1″c and 176-2″c formed in the trenches 170-1c and 170-2c, so that the bottom portions of the isolation features 176-1″c and 176-2″c extend through the dielectric layers 122 and the cap layers 120 and extend into the isolation structure 116 in accordance with some embodiments. In some embodiments, the bottommost surfaces of the isolation features 176-1″cand 176-2″care lower than the topmost surface of the isolation structure 116. In some embodiments, the bottommost surfaces of the isolation features 176-1″cand 176-2″care lower than the top surface of the base structures 104B. In some embodiments, the bottommost surfaces of the isolation features 176-1″cand 176-2″care lower than the bottommost surfaces of the gate structures 190.

In addition, the isolation features 176-1″cand 176-2″cinclude the shell layers 178-1″c and 178-2″c, and the bottommost surfaces of the shell layers 178-1″c and 178-2″c are lower than the topmost surface of the isolation structure 116 in accordance with some embodiments. In some embodiments, the interfaces between the isolation structure 116 and the shell layers 178-1″c and 178-2″c of the isolation features 176-1″c and 176-2″c are lower than the bottom surfaces of the gate structures 190.

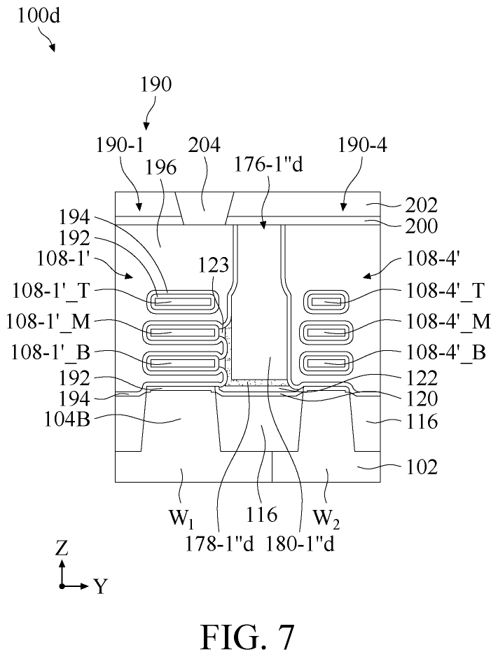

FIG. 7 illustrates a cross-sectional view of a semiconductor structure 100d in accordance with some embodiments. The semiconductor structure 100d may be similar to the semiconductor structure 100 described previously, except the channel layers 108-1′ and the channel layers 108-4′ are formed at opposite sides of an isolation feature 176-1″d in accordance with some embodiments. Processes and materials for forming the semiconductor structure 100d may be similar to, or the same as, those for forming the semiconductor structure 100 described previously and are not repeated herein.

More specifically, the channel layers 108-1′ with greater widths and the channel layers 108-4′ with smaller widths are formed adjacent to each other, and the gate structure 190-1 and 190-4 are formed around the channel layers 108-1′ and 108-4′, respectively, in accordance with some embodiments. Then, the isolation feature 176-1″d is formed between the gate structures 190-1 and 190-4 to electrically isolated the gate structures 190-1 and 190-4 in accordance with some embodiments. In some embodiments, the width of the channel layer 108-1′T is greater than the width of the channel layer 108-4′T in Y direction. In some embodiments, the width of the channel layer 108-1′M is greater than the width of the channel layer 108-4′M in Y direction. In some embodiments, the width of the channel layer 108-1′B is greater than the width of the channel layer 108-4′B in Y direction.

As described previously, when the channel layers 108-1′ have relatively larger widths, the extending portions 123 will be formed between the channel layers 108-1′ and the sidewalls of the isolation structure 176-1″c facing the channel layers 108-1′ in accordance with some embodiments. In some embodiments, the isolation feature 176-1″d includes a core material 180-1″d and a shell layer 178-1″d, and the shell layer 178-1″d is located under the bottom surface of the core material 180-1″d and on the sidewall of the lower portion of the core material 180-1″d facing the channel layers 108-1′.

On the other hand, when the channel layers 108-4′ have relatively smaller widths, the extending portions 123 will not be formed between the channel layers 108-4′ and the sidewalls of the isolation structure 176-1″c facing the channel layers 108-4′ in accordance with some embodiments. Accordingly, four sidewalls of each of the channel layers 108-4′ are wrapped by the gate structure 190-4 in accordance with some embodiments. In addition, the shell layer 178-1″d does not extend to the sidewall of the core material 180-1″d facing the channel layers 108-4′.

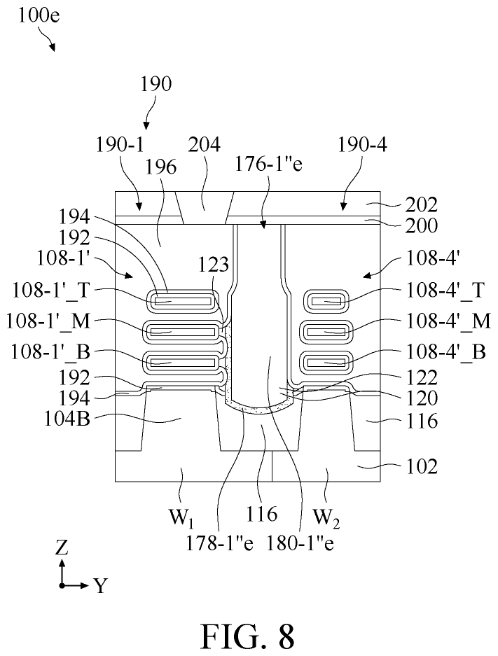

FIG. 8 illustrates a cross-sectional view of a semiconductor structure 100e in accordance with some embodiments. The semiconductor structure 100e may be similar to the semiconductor structure 100d described previously, except its isolation feature 176-1″e extends into the isolation structure 116 (similar to isolation features 176-1″c and 176-2c of the semiconductor structure 100c) in accordance with some embodiments. Processes and materials for forming the semiconductor structure 100e may be similar to, or the same as, those for forming the semiconductor structures 100c and 100d described previously and are not repeated herein.

More specifically, the semiconductor structure 100e includes the channel layers 108-1′ with greater widths and the channel layers 108-4′ with smaller widths, the gate structure 190-1 and 190-4, and the isolation feature 176-1″e between the gate structures 190-1 and 190-4 in accordance with some embodiments.

In some embodiments, the isolation feature 176-1″e includes a core material 180-1″e and a shell layer 178-1″e, and the shell layer 178-1″e is located under the bottom surface of the core material 180-1″e and on the sidewall of the lower portion of the core material 180-1″e facing the channel layers 108-1′ but not on the sidewall of the core material 180-1″e facing the channel layers 108-4′. In addition, the bottom surface of the shell layer 178-1″e is lower than the top surface of the isolation structure 116 and the bottom surface of the gate structures 190-1 and 190-4 in accordance with some embodiments.

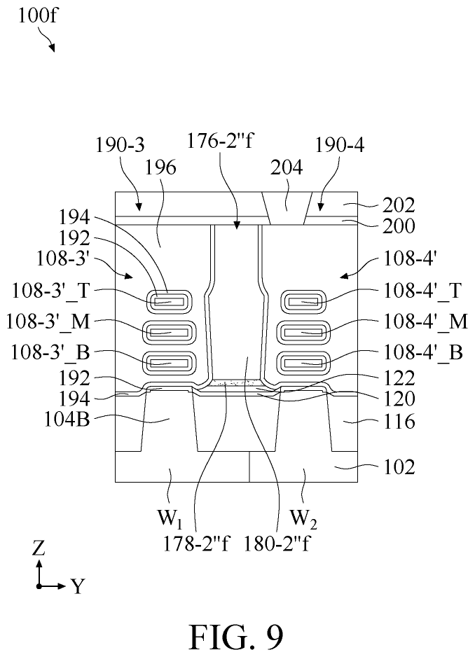

FIG. 9 illustrates a cross-sectional view of a semiconductor structure 100f in accordance with some embodiments. The semiconductor structure 100f may be similar to the semiconductor structure 100 described previously, except its isolation feature 176-1″f has slope sidewalls at its bottom portion in accordance with some embodiments. Processes and materials for forming the semiconductor structure 100f may be similar to, or the same as, those for forming the semiconductor structure 100 described previously and are not repeated herein.

More specifically, the isolation feature 176-2″f includes a shell layer 178-2″f and a core material 180-2″f formed over the shell layer 178-2″f, and a bottom portion of the core material 180-2″f has slope sidewalls in accordance with some embodiments. In some embodiments, the width of the bottom portion of the core material 180-2″f gradually decreases from its top portion to its bottom portion. As shown in FIG. 9, the core material 180-2″f has a top width at its top surface, a bottom width at its bottom surface, and a middle width located between the top surface and the bottom surface, and the top width is smaller than the bottom width, and the bottom width is smaller than the middle width in accordance with some embodiments. In some embodiments, the gate structures 190-3 and 190-4 cover the slope sidewalls of the isolation feature 176-2″f.

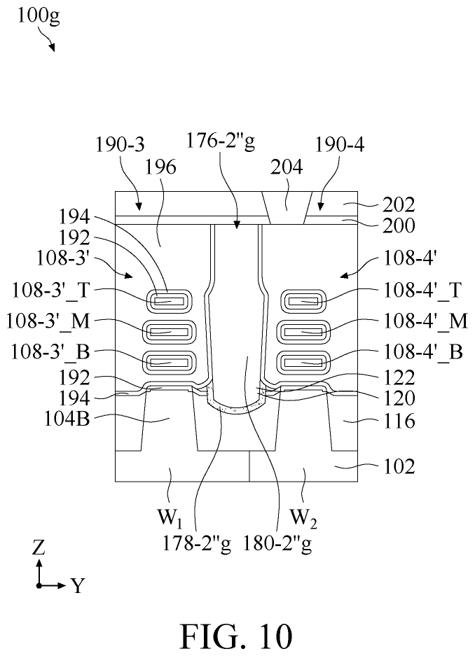

FIG. 10 illustrates a cross-sectional view of a semiconductor structure 100g in accordance with some embodiments. The semiconductor structure 100g may be similar to the semiconductor structure 100f described previously, except the its isolation feature 176-2″g extends into the isolation structure 116 (similar to the isolation feature 176-1″c and 176-2″c of the semiconductor structure 100c) in accordance with some embodiments. Processes and materials for forming the semiconductor structure 100g may be similar to, or the same as, those for forming the semiconductor structures 100c and 100f described previously and are not repeated herein.

More specifically, the isolation feature 176-2″g includes a shell layer 178-2″g and a core material 180-2″g formed over the shell layer 178-2″g, and a bottom portion of the core material 180-2″g has slope sidewalls extending into the isolation structure 116 in accordance with some embodiments. In some embodiments, the width of the bottom portion of the core material 180-2″g gradually decreases from its top portion to its bottom portion. As shown in FIG. 10, the gate structures 190-3 and 190-4 cover the upper portions of the slope sidewalls of the isolation feature 176-2″g and the shell layer 178-2″g covers the lower portions of the slope sidewalls of the isolation feature 176-2″g in accordance with some embodiments. In addition, the shell layer 178-2″g extends into the isolation structure 116 in accordance with some embodiments.

Generally, channel layers 108-1′ to 108-4′ (e.g. nanostructures) are form by forming a semiconductor stack including the first semiconductor material layers 106 and the second semiconductor material layers 108 alternately stacked. The first semiconductor material layers 106 serve as sacrificial layers during the manufacturing processes, and the second semiconductor material layers 108 serve as the channel layers in the resulting transistors. However, during the manufacturing processes, such as thermal processes, Ge in the first semiconductor material layers 106 may diffuse into the second semiconductor material layers 108, which may result in undermining the performance of the resulting devices. Accordingly, in the embodiments described above, the first semiconductor material layers 106 are replaced with dielectric sacrificial features 144 before the source/drain structures 152 are formed, so that the issues of Ge diffusion may be reduced or avoided.

In addition, the isolation features (e.g. the isolation features 176-1″, 176-2″, 176-1″c, 176-2″c, 176-1″d, 176-1″e, 176-2″f, and 176-2″g) are formed to separate the gate structures 190 in accordance with some embodiments. Since the isolation features have smaller top widths, the gate structures (e.g. gate structures 190) formed adjacent to the isolation features can have larger top surfaces. Therefore, there will be more spaces over the gate structures for forming the contacts (e.g. contacts 204).

In addition, the extending portions (e.g. the extending portions 123) are formed at some of the isolation features in accordance with some embodiments. The extending portions connecting the channel layers and the isolation feature may be benefit for reduction of Cgd by due to metal gate endcap reduction.

It should be appreciated that the elements shown in the semiconductor structures 100, 100c, 100d, 100e, 100f, and 100g may be combined and/or exchanged. In addition, it should be noted that same elements in FIGS. 1A to 10 may be designated by the same numerals and may include materials that are the same or similar and may be formed by processes that are the same or similar; therefore such redundant details are omitted in the interests of brevity. In addition, although FIGS. 1A to 10 are described in relation to the method, it will be appreciated that the structures disclosed in FIGS. 1A to 10 are not limited to the method but may stand alone as structures independent of the method. Similarly, the methods shown in FIGS. 1A to 10 are not limited to the disclosed structures but may stand alone independent of the structures. Furthermore, the channel layers (e.g. the nanostructures) described above may include nanowires, nanosheets, or other applicable nanostructures in accordance with some embodiments.

Also, while the disclosed methods are illustrated and described above as a series of acts or events, it should be appreciated that the illustrated ordering of such acts or events may be altered in some other embodiments. For example, some acts may occur in a different order and/or concurrently with other acts or events apart from those illustrated and/or described above. In addition, not all illustrated acts may be required to implement one or more aspects or embodiments of the description above. Furthermore, one or more of the acts depicted above may be carried out as one or more separate acts and/or phases.

Furthermore, the terms “approximately,” “substantially,” “substantial” and “about” used above account for small variations and may be varied in different technologies and be within the deviation range understood by the skilled in the art. For example, when used in conjunction with an event or circumstance, the terms can refer to instances in which the event or circumstance occurs precisely as well as instances in which the event or circumstance occurs in a close approximation.

Embodiments for forming semiconductor structures may be provided. The semiconductor structure may include first channel layers, second channel layers, a first gate structure wrapping around the first channel layers, a second gate structure wrapping around the second channel layers, and an isolation feature sandwiched between the first gate structure and the second gate structure. In addition, the isolation feature has a narrower top surface and a wider bottom surface, so that the first gate structure and the second gate structure formed adjacent to the isolation feature can have greater top surfaces for contacts formed thereon.

Semiconductor structures and method for forming the same are provided. The semiconductor structure includes a substrate and a first channel layer and a second channel layer extending along a first direction. In addition, the first channel layer and the second channel layer are over the substrate. The semiconductor structure further includes an isolation structure over the substrate, and the isolation structure is located between the first channel layer and the second channel layer in a top view. The semiconductor structure further includes a first gate structure extending along a second direction over the first channel layer and the isolation structure, and the second direction is different from the first direction. The semiconductor structure further includes a second gate structure extending along the second direction over the second channel layer and the isolation structure and an isolation feature laterally sandwiched between the first gate structure and the second gate structure and extending over the isolation structure. In addition, the isolation feature has a top width and a bottom width that is greater than the top width, and an interface between the isolation feature and the first gate structure comprises a curved profile.

Semiconductor structures and method for forming the same are provided. The semiconductor structure includes a substrate and a first transistor over the substrate. The first transistor includes a first base structure, first channel layers extending lengthwise along a first direction over the first base structure, and a first gate structure wrapping around the first channel layers and extending lengthwise along a second direction. In addition, the second direction is different from the first direction. The semiconductor structure further includes a second transistor over the substrate. The second transistor includes a second base structure, second channel layers extending lengthwise along the first direction over the second base structure, and a second gate structure wrapping around the second channel layers and extending lengthwise along the second direction. The semiconductor structure further includes an isolation structure over the substrate and between the first base structure and the second base structure. In addition, the isolation structure interfaces a sidewall of the first base structure and a sidewall of the second base structure. The semiconductor structure further includes a first isolation feature sandwiched between the first gate structure and the second gate structure to electrically isolate the first gate structure and the second gate structure. In addition, a distance between a topmost one of the first channel layers and a first sidewall of the first isolation feature in the second direction is greater than a distance between a bottommost one of the first channel layers and the first sidewall of the first isolation feature in the second direction.

Semiconductor structures and method for forming the same are provided. The method includes alternately stacking channel layers and semiconductor sacrificial layers to form a semiconductor stack over a substrate and patterning the semiconductor stack to form a first fin structure and a second fin structure. The method further includes forming a dummy gate electrode across the first fin structure and the second fin structure and replacing the semiconductor sacrificial layers by dielectric sacrificial layers. The method further includes forming a first trench having a first width in the dummy gate electrode between the first fin structure and the second fin structure and enlarging a top portion of the first trench to a second width that is greater than the first width. The method further includes forming isolation materials in the first trench and removing the dummy gate electrode. The method further includes partially removing the isolation materials to form an isolation feature, and a top surface of the isolation feature has a third width that is smaller than the first width. The method further includes removing the dielectric sacrificial layers and forming a first gate structure at a first side of the isolation feature and a second gate structure at a second side of the isolation feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
first channel layers and second channel layers over the substrate;
an isolation structure below the first channel layers and the second channel layers, wherein the isolation structure has a curved top surface;
a first gate structure wrapping around the first channel layers;
a second gate structure wrapping around the second channel layers; and
an isolation feature sandwiched between the first gate structure and the second gate structure,
wherein the isolation feature has a top portion and a bottom portion, and sidewalls of the top portion and the bottom portion form a curved sidewall profile in a cross-sectional view, and the bottom portion of the isolation feature extends into the isolation structure.

2. The semiconductor structure as claimed in claim 1, wherein the isolation feature comprises a core material and a shell layer, and the shell layer surrounds a bottom portion of the core material but not a top portion of the core material.

3. The semiconductor structure as claimed in claim 2, wherein a top surface of the shell layer is lower than a top surface of a topmost one of the first channel layers.

4. The semiconductor structure as claimed in claim 1, wherein the bottom portion is wider than the top portion in the cross-sectional view.

5. The semiconductor structure as claimed in claim 1, further comprising an extending portion laterally sandwiched between the isolation feature and one of the first channel layers.

6. The semiconductor structure as claimed in claim 5, wherein the extending portion has a curved top surface and a curved bottom surface in the cross-sectional view.

7. The semiconductor structure as claimed in claim 5, wherein a thickness of the extending portion gradually increases from a side attaching to the first channel layer to a side attaching to the isolation feature.

8. A semiconductor structure, comprising:
a substrate;
a first base structure extending lengthwise in a first direction;
first channel layers over the first base structure;
a first gate structure wrapping around the first channel layers and extending lengthwise along a second direction, wherein the second direction is different from the first direction;
a first source/drain structure connected to the first channel layers in the first direction;
a second base structure extending lengthwise in the first direction and spaced apart from the first base structure in the second direction;
second channel layers over the second base structure;
a second gate structure wrapping around the second channel layers and extending lengthwise along the second direction;
a second source/drain structure connected to the second channel layers in the first direction;
an isolation structure formed between the first base structure and the second base structure, wherein a portion of the first source/drain structure overhangs the isolation structure; and
an isolation feature sandwiched between the first gate structure and the second gate structure, wherein the isolation feature comprises:
a core material; and
a shell layer at least under the core material,
wherein a first portion of the core material interfaces with the first gate structure.

9. The semiconductor structure as claimed in claim 8, wherein the first gate structure comprises an interfacial layer, a gate dielectric layer over the interfacial layer, and a gate electrode layer over the gate dielectric layer, and the first portion of the core material interfaces with the gate dielectric layer.

10. The semiconductor structure as claimed in claim 9, wherein the shell layer is partially covered by the gate dielectric layer.

11. The semiconductor structure as claimed in claim 8, wherein a top surface of the first gate structure is substantially level with a top surface of the isolation feature.

12. The semiconductor structure as claimed in claim 8, wherein the isolation feature is formed over the isolation structure.

13. The semiconductor structure as claimed in claim 12, further comprising:
a cap layer; and
a dielectric layer over the cap layer,
wherein the cap layer and the dielectric layer are vertically sandwiched between the isolation feature and the isolation structure.

14. A semiconductor structure, comprising:
a substrate;
a first transistor over the substrate, wherein the first transistor comprises:
a first base structure;
first channel layers over the first base structure;
a first gate structure wrapping around the first channel layers; and
a first gate spacer on a sidewall of the first gate structure;
a second transistor over the substrate, wherein the second transistor comprises:
a second base structure;
second channel layers over the second base structure; and
a second gate structure wrapping around the second channel layers;
a first isolation feature separating the first gate structure and the second gate structure, wherein the first isolation feature is in contact with the first gate spacer; and
a first extending portion laterally protruding from the first isolation feature and attaching to a bottommost one of the first channel layers.

15. The semiconductor structure as claimed in claim 14, wherein a thickness of the first extending portion in a first direction is smaller than a thickness of the bottommost one of the first channel layers in the first direction.

16. The semiconductor structure as claimed in claim 14, wherein a width of the bottommost one of the first channel layers is greater than a width of a topmost one of the first channel layers.

17. The semiconductor structure as claimed in claim 14, wherein a topmost one of the first channel layers is separated from the first isolation feature by the first gate structure.

18. The semiconductor structure as claimed in claim 14, further comprising:
a third transistor over the substrate, wherein the third transistor comprises:
a third base structure;
third channel layers over the third base structure; and
a third gate structure wrapping around the third channel layers;
a fourth transistor over the substrate, wherein the fourth transistor comprises:
a fourth base structure;
fourth channel layers over the fourth base structure; and
a fourth gate structure wrapping around the fourth channel layers; and
a second isolation feature separating the third gate structure and the fourth gate structure,
wherein a shape of the first isolation feature is different from a shape of the second isolation feature.

19. The semiconductor structure as claimed in claim 18, wherein a width of the third channel layers is smaller than a width of the first channel layers.

20. The semiconductor structure as claimed in claim 18, wherein the first isolation feature comprises a first core material and a first shell layer surrounding a bottom portion of the first core material, the second isolation feature comprises a second core material and a second shell layer under a bottom surface of the second core material, and a top portion of the first shell layer is higher than a top portion of the second shell layer.
